(19) United States
(12) Patent Application Publication
(10) Pub. No.: US 2004/0004559 A1
(43) Pub. Date: Jan. 8, 2004

(54) Keyboard device with preselect feedback

(76) Inventor: Rodger H. Rast, Gold River, CA (US)

Correspondence Address: Rastar Corporation, 11230 Gold Express Drive, Gold River, CA, 95670, US

(21) Appl. No.: 10/612,777

(22) Filed: Jul. 1, 2003

Related U.S. Application Data
(60) Provisional application No. 60/394,160, filed on Jul. 1, 2002.

(51) Int. Cl. H03M 11/00; H03K 17/94

(52) U.S. Cl. 341/34; 341/22

(57) ABSTRACT

A system allowing persons to operate their computer comfortably while lying in bed. The system has a user friendly keyboard, that provides preselection feedback indicating prior to a keystroke being entered, thus allowing the individual to verify the correct key before pressing down the key. Additional aspects of the system include the user of display goggles with panning control, and a see-through mode. Numerous additional system and methods are described.

### CROSS-REFERENCE TO RELATED APPLICATIONS

This application claims priority from U.S. provisional application serial No. 60/394,160 filed on Jul. 1, 2002.

### STATEMENT OF FEDERALLY SPONSORED RESEARCH OR DEVELOPMENT

Not Applicable

### REFERENCE TO A MICROFICHE APPENDIX

Not Applicable

### BACKGROUND OF THE INVENTION

1. Field of the Invention

This invention pertains generally to keyboard entry and more particularly to a method and system for utilizing a computer from a lying position.

2. Description of the Background Art

Many patients are restricted to lying on their backs, while others such as those suffering from low back problems, or neck problems, often find sitting at a desk using a conventional computer system very painful.

Those restricted to a bed find the use of a computer very tiring, and uncomfortable, as they are required to be in a seated position with their arms up on some table ir similar in order to proper use a keyboard.

It will be appreciated therefore that a need exists for a system and method for entering data to a computer when in a lying down position or otherwise being unable to utilize a conventional keyboard. The present invention, solves this problem and many others. Furthermore, a number of related problems and situations are solved by the numerous aspects described herein.

### SUMMARY OF THE INVENTION

The system allows a bedridden person to manually access a computer through a keyboard device. An individual need not see the computer keyboard at all and may be lying completely in a flat out position with their head directed toward the ceiling. The present invention therefore opens the world of computing to a number of people and facilitates computer use for many others that find working at a desk painful, or otherwise problematic.

Furthermore, the present invention may be incorporated in conventional devices to speed learning, or to allow those with minimal keyboarding skills to effectively use a keyboard.

1.0 KBLay—Keyboard for Those Lying Down

Incorporated herein by reference, application entitled: “A System and Method For Selective Control of Acoustic Isolation in Headsets” Ser. No. 09/841,713 filed Apr. 24, 2001, and provisional application serial No. 60/199,283 filed Apr. 24, 2000, which are included herein by reference.

1.1 Description of Embodiments

System preferably comprises: (1) a special dual or triple-sense keyboard, (2) video goggles, (3) optional trackball, (4) computer system. The computer is conventional and operates in a typical manner. One or more additional programs are run on the computer however to facilitate the operation of the system.

Video Display:

Video goggles/glasses are worn by the patient to view the computer display. These glasses/goggles have embedded display reticles and may additionally contain small speakers or headphone elements for listening to the sound. The user's head can lie in a natural relaxed position, as they are not required to crane their neck to see a display. It will be appreciated that video goggles and similar are readily available.

Enhanced Headmounted Display:

Wearing goggles, however, is a little disconcerting to many users as they cannot see the action about themselves, without taking off the goggles which is often difficult due to the wiring. It would be troublesome for an individual to be taking on an off a pair of goggles, while iris printing devices and other see through displays may not provide sufficient “presence” (contrast with background and brightness) to be comfortable for normal use. Therefore an aspect of the invention is a goggle that includes a means for one-touch see through capability, two embodiments are described.

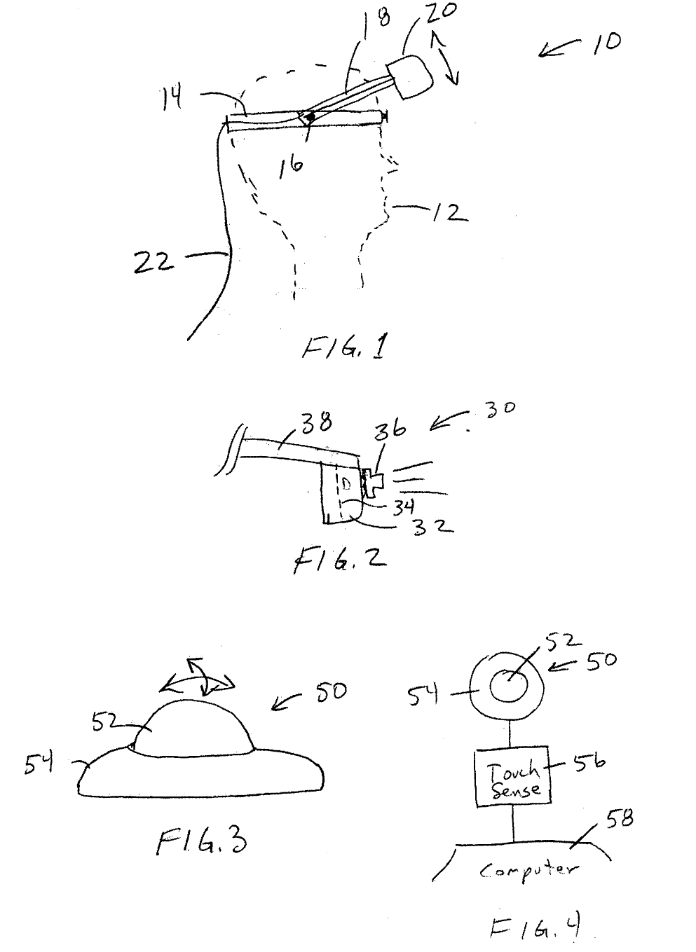

FIG. 1 depicts a flip up goggle system 10 retained on individual 12 by headband 14 with hinge 16 from which arms 18 connected to goggle 20 may be swung away to allow viewing.

FIG. 2 depicts another system 30 of getting a view, a goggle 32 with a display 34 is fitted with one or two forward looking cameras 36, wherein the user can select a video feed from the computer, television, or select a direct feed from the room by activating the camera(s).

Therefore, one aspect of the invention is the inclusion within video display goggles of one or two forward directed imagers, wherein under software, or user control the images from the imager(s) are directed onto the viewing screen within the goggles to allow the user to view the external environment without removing the goggles. Preferably, an option of the system allows the user to select the amount of external view to be mixed with a computer centric view. Furthermore, the software can cause the goggles to enter full or partial external viewing in response to the position of the users head, use head control being described later.

The goggles can provide responsivity to external sounds, or motions, in a manner similar to that described in the environmentally responsive headsets as described in the incorporated application.

Trackball Control:

A trackball is preferably attached to either side of the keyboard to provide cursor control. The trackball according to this invention includes a means for sensing contact from a user and differentiating this contact from the form of contact with sheets and the like.

FIG. 3 depicts a trackball 50 with rotatable element 52 and wide weighted base 54 beneath which is a material (i.e. velcro, textured rubber, latex etc) which does not slide easily over sheets. By way of example the trackball can be constructed with an electro sense exterior structure that determines if induced motion is caused by the user. FIG. 4 depicts trackball 50 with a sense circuit 56 for detecting the nature of the registered movement, prior to passing data to computer 58. Motion which is not induced by contact with the individual does not effect the positioning of the cursor. It will be appreciated that human touch can be registered by sensing RF coupled to the device (i.e. from lights), changes in capacitance, changes in inductance, and so forth.

This form of sensing is useful so that movement of the trackball which is not associated with touch by the user can be ignored. For example a user that may be covered by blankets that contact the trackball. It would be disruptive for every minor movement of the trackball to elicit a screen cursor transition.

Capacitive switches operate in a similar manner, wherein upon being contacted by the user's skin they body of the user acts as an antenna coupling electricity across the capacitance. Preferably the trackball contains a pressure tranducer for measuring the downward force on the trackball. Movement of the ball under low force conditions cause the cursor to move conventionally, however movement of the ball when a given level of pressure has been exceeded causes panning of the screen to allow the user to alter their view or to switch to the other document on the table of the desktop.

Alternately, various pointer control devices can be used. Preferably the trackball contains two additional windowing buttons, one allows toggling through each running application, while the other allows toggling through the windows of the current application. A user at a desk often references paper based information as they are working at a computer. However the user of this system would receive all data as files or as scanned images. The buttons allow the user to quickly and non-distractingly flip from one image to the next; akin to having the image next to the computer and shifting one's glance.

Sensing Head Motion to Control Views:

FIG. 5 depicts an alternative 70 to a trackball, or an option in addition to a trackball, a head motion detection sensor, (i.e. acceleration, inertial navigation sensor, and/or compass) is preferably built into the goggles.

Displays 72, 74 are shown connected to a display controller 76, that is connected to computer 80 in conjunction with a motion sensor, depicted is an inertial nav system 78 that is very sensitive to even small movements.

When the computer if first put into the proper mode, then movement of the user's head to either side, or up and down is interpreted by the programming of the invention to allow selection of which document to view. The traditional view being noted by an X 84 shown in the middle of a field of displays 82 from which the user can view by simply moving their head. Although the head motion selection of display could be maintained at all times, it is preferably selected by a mode so that the user has control over whether the function operates all the time or only in response to a user mode change. To make the change preferably a multiwindowed operating system is utilized wherein the programming generates API calls, or system calls, to change the display in response to head movement. It will be appreciated that implemented this functionality will be within the skills of one of ordinary skill and will not be described in detail.

When the user opens a document they are shown a desktop display with the primary document in the center and they can place the newly opened document anywhere on this simulated desktop. Distinct head movements allow selection of which document is to be viewed, this is similar to one viewing paper documents. Therefore, the head movements may be sensed within the system to allow the user to switch between different desktops. For example a “text document 1” may be shown on center screen with a “spreadsheet document 2” to the right of center, and a “graphic image 3” shown to the left of center. The switching can be automatic based on sensing user head position changes, or the switch performed only after the feature is activated by pressing, or holding down, a given key to allow for the view selection. The automatic mode allows the user to extend their view thereby stretching out their screen to 2×, 3×, 4×, . . . 9× its normal size, and so forth. The number of possible screens is only limited by the needs of the user.

One of the windows preferably contains controls for various systems, such as heating, lighting, the telephone, the TV, the bed and so forth. Wherein the user need only slightly turn their heads to interact with these controls.

Head position may be registered using a tilt sensor, acceleration sensor, inertial navigation sensor, compass in combination with a tilt sensor, and so forth while a solid state compass may be utilized to register absolute position.

Split Keyboard:

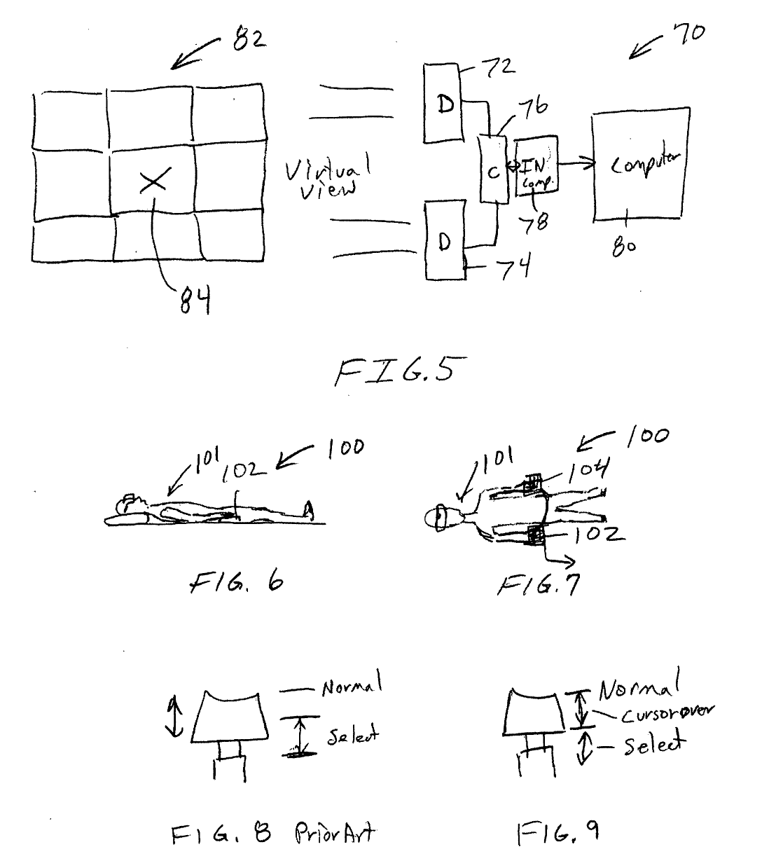

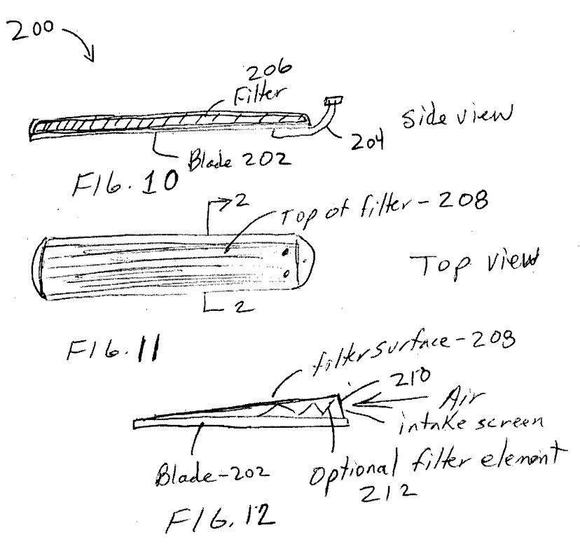

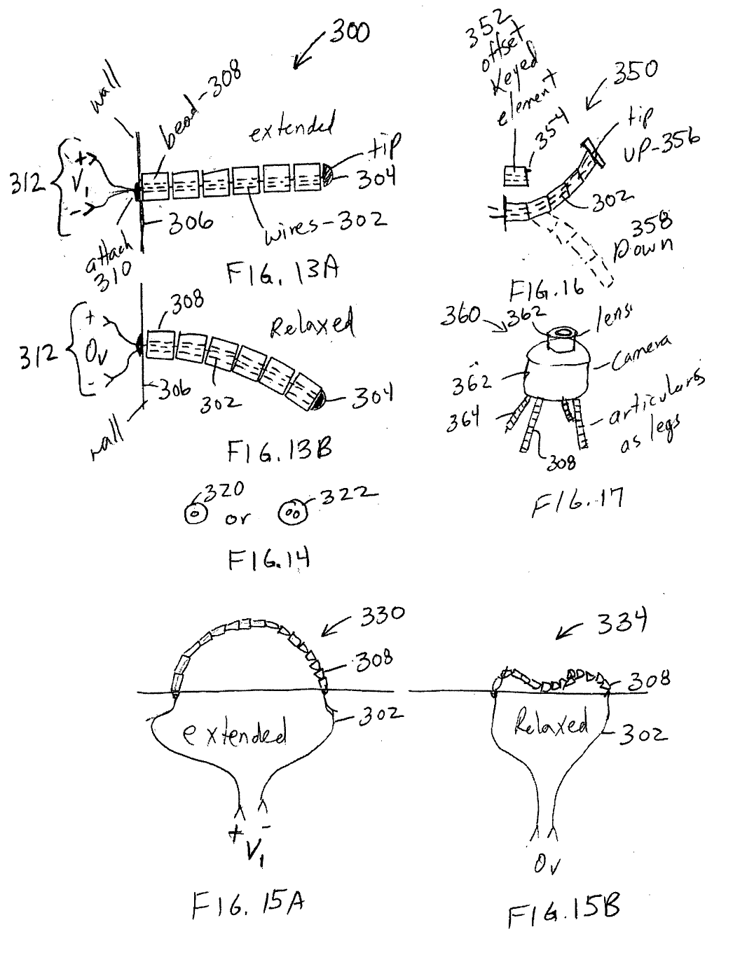

FIGS. 6 and 7 depict bedridden use 100 of a split keyboard 102, 104 according to the invention, by an individual 101. The keyboard comprises two separating half sections 102, 104 that may be placed on either side of the patient while they are laying in bed. It will be appreciated that a keyboard is still the fastest method of entering with accuracy, or for performing other operations.

However, a traditional keyboard split in to the two halves does not solve the user's problems. As the patient cannot easily see the keyboard halves 102, 104 while using the keyboard in this position. Using a keyboard that can not be readily seen poses difficulties for even those skilled in the use of a keyboard. Therefore the keyboard of the invention provides the ability to sense the location of the user's fingers and to graphically represent a keyboard on the video display wherein the current finger locations are shown.

Pre-Threshold Key Sensing Keyboard and System:

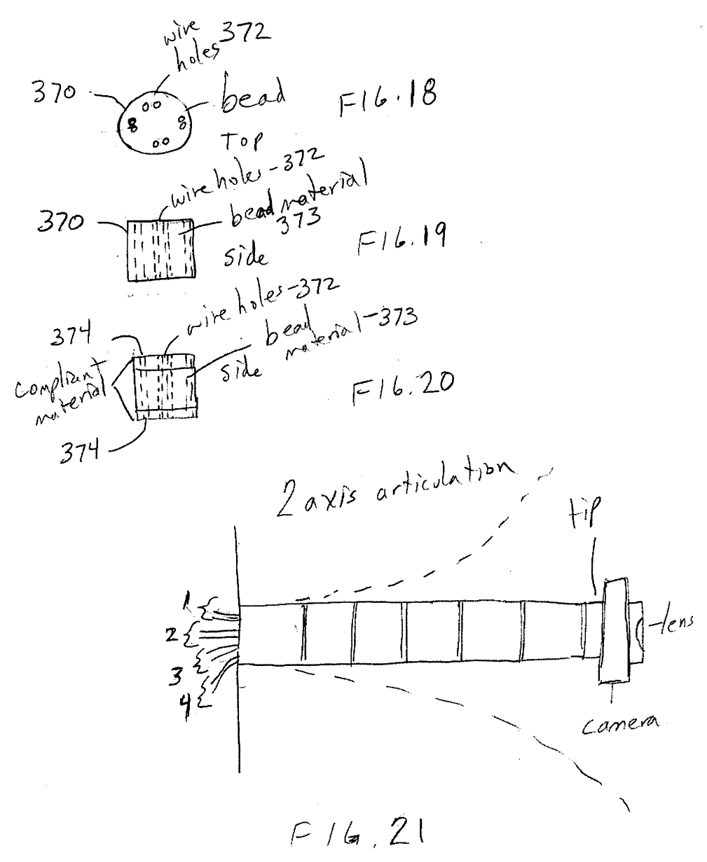

The computer industry has long ago settled on tactile keyboards wherein the user depresses the keys over a distance to activate the keystroke. On these keyboards the keys are set to generally snap down to provide optimal feedback. This style of tactile feedback has become an industry standard. However the keys on such a keyboard are by themselves only capable of sensing two states, active and non-active, as seen in FIG. 8.

FIG. 8 depicts a key in the normal (unpressed) state, wherein when the key reaches a threshold or beyond the action of the key occurs. Therefore the position of the user's hands can not be determined until the user presses a key, then if wrong they must find the backspace key. The keyboard according to the present invention provides at least dual-sense or preferably a triple-sense capability.

FIG. 9 depicts a dual sense key, wherein as depressing a key even a small amount can be sensed as what we will term “cursor over”, or alternately referred to as “preselect”, in response to which the user is provided feedback, if it is they they want then they press it rest of the way. The key can be implemented readily by providing a lower threshold for keyover sense than for selectin a key.

A triple sense keyboard according to the invention can discern which of the keys is being pressed the most by the user. In this way the unit can display a single key feedback to eliminate confusion. Also, in the bed-ridden situation it can be preferable to detect finger heat, inductance, or capacitance etc, to be sure that the key is not being triggered into a “cursor over” state by the sheets of the bed.

One embodiment of triple-sensing determines the active/inactive state of each key as does a typical keyboard, but it can measure the depression of the key prior to it reaching the “pressed” threshold and preferably also can sense the fingers of the user touching the keyboard to qualify all inputs. This may be overkill for most situations but provides a generally optimum arrangement for the application.

Each keycap can be built with a calibrated force/temperature sensor molded within the keycap plastic, or the depression of the magnetic plunger can be sensed in an analog. Therefore the second sense of the keycap is force, it senses even minor forces being placed on the keycap by the user. The third sense may be that of temperature, the keycap can quickly sense the heat of each finger of the user even if they are hovering over a key and applying no pressure. (The force sense would be adequate but the temp sense can be alternatively or additionally employed for added response.)

Feedback is preferably provided to the user within the application, as this is their focus. For example, consider a word processor, wherein the user is looking at the cursor as they enter text on a line. The “cursor over feature” of the keyboard preferably ascertains which key is being “prepressed” the most (but not having reached the threshold for selection), and the key is displayed differently from a selected character, such as in a different color reverse video, enlarged, or somehow displayed wherein the user can verify that their hands are pressing the desired key before actually clicking the key to enter the keystroke.

Another method of display, is to show a small image of the keyboard on the video display with the keys shown in color in response to force placed upon them, and additionally other sensed parameters. Pressure and/or heat on any of they actual keys causes the associated key on the display to change color. For example, registration of mild pressure and/or heat may be registered as yellow while medium pressure/heat registered as green and higher pressures registered as red. Actual activation could be shown as the key in a reverse video mode.

Piezoelectric transducers may embedded within the keytops to sense changes in pressure. Recently, buttons have been created using piezo materials that generate their own voltage output in response to touch. These may be readily incorporated into circuits for the system.

A less preferred method of constructing the keyboard would be with one or more additional contact switches which are set to indicate less than the full travel of the key. In addition existing forms of keyboards such as sense the amount of travel being above a given threshold can be configured readily for communicating linear information in relation to keys that are being depressed by an amount that is less than the predetermined threshold associated with a conventional keypress.

Keyboard keytops can be sensed by picking up the exterior environment, i.e. pulse a high-impedance “antenna” at each key—a single source through high-resistance. Then measure the result and look for a change brought about by fingers on the keys. (e.g. find the keyboard codes being sent to determine how to communicate the “force” on the keys.)

Keycap Display:

If the force on all keytops is to be represented a separate module may be created, or software, that allows the user to simultaneous view the pattern of finger pressure on the keys in relation to the keyboard layout. Simple to construct is a PCB with SMT LEDs under a display bezel that has a keyboard layout shown on it. An LCD, or electronic ink display are obviously good choices and consume less power. One screen of the “desktop” could provide this feature through a visor display.

A Choice Keyboard System:

The keycap display is augmented or replaced using the computer software. Example is a word-processing program receiving keystrokes through an operating system. Light pressure on the keyboard (less than required to register keystroke) is measured at the keyboard and the key with highest force is transmitted to computer, the key is shown as a character on the screen in a different way, such as a color change, until the key is actually pressed. If pressure is lessoned on the key then that preselect character disappears, and is replaced with another character if it is in the preselect modes. The regular (over-threshold) keypress then causes a normal key entry. The person can thereby get feedback on the keys prior to pressing them, this would be useful to everyone, but especially useful for those learning the keyboard and for those that are restricted to a bed and are using a keyboard that can not be seen.

Described further, the operating system of the computer is preferably configured to receive the key closest toward being pressed, that is the key that has not yet been pressed but is subject to the greatest depression or force. This almost-pressed key may then be passed to the application which can display the “almost” keystroke at the cursor position in a mode, such as in another color, so the user recognizes that the character or number shown is the one that the user is putting the most force on at the time. This allows the user to “preview” their keystrokes. The cursor would not advance until a bonafide, over a predetermined threshold keystroke had been performed. This mode of use allows a bed ridden person with no computer skills to use a keyboard and develop those skills without ever needing to see the keyboard.

Augmenting Tones to aid Visually Impaired:

To aid the visually impaired—each key is provided with a specific tonal pattern, or voiced sound, by the present system of the invention. Preferably a sound similar to the letter itself. When key pressed completely then letter sound may be played.

Method of Cursor Control:

The cursor in the system may also be controlled according to a multikey down approach (since certain embodiments/aspects of this application (KBL) have the capability to register multiple keys) for controlling the cursor. Even though the first key down is registered, if a subsequent key is pressed and both held, then the special function is accessed. The number of keys can determine the speed of the action. The cursor maps out to the keyboard—with “G” and “H” ky being considered the center of the keyboard. Multiple keys on top row center (e.g. “R”,“T”,“Y”,“U”,“I”) is causes the cursor to move upward; top right (i.e. “U”,“I”,“O”,“P”,“{”) causes keyboard to move upwardly and to the right, and so forth. The number of keys being held down determines the rate at which the movement is to occur. For example, pressing a pair of keys causes the cursor to move at a rate equivalent to one character per second, while pressing three keys may equate to 10 characters per second, and four keys could jump the cursor by pages, or to the top or bottom. Pressing the space bar and a key provides for scrolling of the screen.

2.0 Fan with Integral Filter

To reduce airborne dust in location where a fan is operating. Fans in common use, such as celing fans, may be configured according to the invention to provide filtering of the air. The present invention is particularly well suited for use on fans having a large fan size and moderate rate of rotation.

Anyone who has ever cleaned a ceiling fan will appreciate that the leading edges of the fan blades readily collect a layer of dust as the blade impacts the airborn dust. The present invention turns that drawback into a advantage by providing a filter coupled to one or more of the fan blades, preferably all of the blades, wherein the air and dust particles are driven through the filter by the speed of the fan, trapping the dust within the filter element. The filter element may be integral to the blade or located either above or below the blade. The filter may be removed for periodic cleaning and returned to service. A large volume of air circulates through the fan wherein the dust, both inherent and stirred up the fan, are collected by the filter.

FIG. 10, FIG. 11, and FIG. 12 exemplify an embodiment of the invention 200 comprising a single fan blade 202 with attachment arm 204, and a filter element 206 retained with the fan blade, such as on top of blade 202. Preferably filter 206 element may be removed for cleaning, such as removing a slidable filter element or removing the entire unit from the blade. FIG. 11 depicts a top view of the fan blade 202, wherein filter 206 is seen to preferably span a major portion of the top surface 208. FIG. 12 depicts the side cross section view of the filter element 206 atop the fan 202 wherein an intake 210 of the filter is seen at the leading edge of the blade into which air is driven by the motion of the fan, and an angled top section filter through which the air exits. The filter is shown configured with additional baffles 212 for providing increased filtering. It should be appreciated that small particle filters, such as HEPA filters may be incorporated to filter out alergens and other small particles in addition to the dust being filtered. Preferably the use of small particle filters is preceded by filters for larger particles so that the small particle filters are not clogged up with larger particles, such as dust.

The filter may be implemented in a variety of shapes, such as symmetrical about the center of the blade. The fan may be operated in either direction, however, to prevent discharging the contents of the filter on entering reverse it is preferred that the filters be cleaned prior to reversing the fan. The filter elements may be reversed themselves prior to reversing the fan, wherein they may be reoriented 180 degrees on the same side of the fan or connected on the opposite face of the fan blade.

The fan blade may be constructed with an integral filter element, or the filter may be adapted for attachment to either or boh sides of the fan blade, using conventional mounting techniques, such as fasteners, flanges engaging a slot, snap fit over the periphery of the fan, and so forth.

It will also be appreciated that the filter element may facilitate additional features, for example, scents may be applied to the filter to add fragrance to the room. The scents may be added periodically by a dripper style reservoir wherein the effect can be made to last for a period of time. Furthermore a water reservoir could be utilized to maintain the filter grid in a moist state wherein the air passing through the fan filter is both cleaned and moisturized.

Controlling Articulated Elements

This aspect of the invention provides a simple inexpensive articulator for providing mechanical urging or movement in an electrically controlled system.

The motion of the articulator is provided by a series of elongated segments through which one or more sections of what is commonly referred to as “muscle wire” is passed, although other shape memory material may be alternatively utilized, such as newly available polymeric forms of muscle wire. The muscle wire is so known because it contracts when a current is passed through it. The present invention uses this property of the material for creating a simple articulator whose position may be controlled in response to the current flow through the muscle wire.

FIG. 13A depicts a horizontal beam articulator 300 wherein a wire loop 302 is retained between a tip 304 and a wall 306 passing though a series of (six shown) bead like cylindrical sections 308. The muscle wire preferably forms a loop wherein current may be applied from the attached end 306, such as attachment point 310. The muscle wire is either insulated or the beads are configured with separate apertures wherein the two sections of muscle wire running the length of the beads stay out of electrical contact with one another. Two ends of the muscle wire are shown attached going through a wall section, wherein a loop of the wire extends through the beads to a tip. The tip may be formed in any desired shape for the application. The wires may be affixed at the tip, or simply routed in an in an out path through the tip, such as like the two holes in a button.

Wires are shown extending from attach point 310 wherein a current may be applied 312. A voltage V1 is shown which has contracted the muscle wire in FIG. 13A to cause the articulator to extend to perpendicular from the wall. It should be appreciated that the under-tension state is dependent on the shape of the beads. It will be noted that when no current flows the articulator is in a down, relaxed, position as shown in FIG. 13B, because the muscle wire extends allowing the beads to separate and droop. Upon the application of current the articulator becomes erect in a horizontal position. Depending on current flow intermediate states may be created, and the articulator may be moved at a desired rate through its range of motion for creating a number of various effects.

FIG. 14 depicts how the muscle wire loop may be passed through a single aperture within each segment 320 or through separate apertures 322 (which can simplify insulating the wires from one another).

A number of configurations may be created using the articulator beams driven by the muscle wire. Another example is shown in FIG. 15A wherein an articulated vertical loop is achieved when the muscle wire is powered and which collapses as shown in FIG. 15B when current is relaxed. Intermediate current values of course being able to render intermediate states therein.

FIG. 16 depicts a articulator 350 which extends the range of motion by proper bead selection. An offset bead segment 352 is shown that is configured for a fixed orientation toward one another, in other words, they cannot rotate in relation to one another. The non-rotation may be accomplished by using a key 354 that engages between the beads, or by using separate wire passing through widely separated holes. It will be noted that the range of motion can be increased to provide an up flexure 356 that extends beyond horizontal while retaining appreciable the same down condition 358.

FIG. 17 illustrates a imaging device 360 with body 362 and lens 363 being supported by a series of muscle wire articulator legs 364 comprising beads 308 threaded with a loop of muscle wire and preferably connected at a non-movable base point connected to a camera imaging system. The legs are shown in an erect condition wherein the camera is focused upwardly, by altering the current in the legs the camera may be tilted by any desired amount in either movement axis.

FIG. 18 and FIG. 19 illustrate a bead 370 that provides for multiple loops of muscle wire to be passed through sets of holes 372, shown as four loops for X and Y control. To maximize accuracy and flexure, it is preferably that at least portions of the beads be compliant, allowing it to be compressed to a limited extent. FIG. 20 depicts a bead of bead material 373 and compliant ends 374, such as formed from silicon, or other polymeric material. Or it may comprise a bead section that is fabricated entirely from compliant material.

A two axis articulator 376 is shown in FIG. 21 extending from a wall surface 377 having four loops 378 of muscle wires extending through a series of compliant beads 373, 374. To illustrate an application, an imager 380 with lens 382 is shown attached to the tip of the articulator, atlhough the movement may be used in a variety of applications for moving articles, selective blocking, or various other mechanical control applications.

It will be appreciated that sufficient current through all four loops (1-4) can extend the beads of the articulator to a horizontal position. By applying different current levels to the separate horizontal loops the articular can be moved or positioned in the horizontal axis, while the vertical axis is controlled by altering the relative current in the top and bottom loop of muscle wire. It will be appreciated that a fairly substantial range of angular motion may be obtained using this method.

Although holes in the core of the “beads” are shown, the muscle wire may be routed in channels, or other retention mechanisms, about the exterior of the beads. To simplify description, the segments of the articulator are described as “beads” since they can resemble beads as one would find on a string, however, the shape of these segments will be typically determined by the application, for example the exterior of the segments may be configured for performing functions themselves or having elements attached to them such as sensors and the like.

The present invention may be implemented in a variety of alternative ways without departing from the teachings of the present invention, and many configurations are not shown but can be created from modifications of the configurations shown. For example beads may be mechanically configured to rotate as engaged with one another wherein compressive force can create a spiral movement at the tip. Similarly a number of changes in bead engagement structures may be utilized to create a number of desired movement patterns and so forth.

Enhanced Consumer Packaging

This aspect of the invention is directed at reducing wasted freezer space, refrigerator space, cooler space, or shelf space taken up containers that are only partially full. The carton is created with separable sections that may be removed as the contents of the carton are depleted. The invention may be utilized on vertically oriented containers and horizontally oriented containers. The invention is particularly well suited for use with frozen foods, or other consumable items stored where space is at a premium.

Sections of the container are preferably removed by pulling a pull tab, wherein a string embedded within the cardboard, or attached to the backside of the cardboard (such as using a nylon mesh material glued over the string), and the string. These types of pull strings are well known in the art, such as for opening the top of a cylindrical container of oatmeal. The present invention provides pull strings at intervals along the product container, wherein the user may reduce the size of the package, and corresponding air volume if the food item is not sealed in a separate bag inside. The present invention may be utilized with single layer containers, or double layer containers.

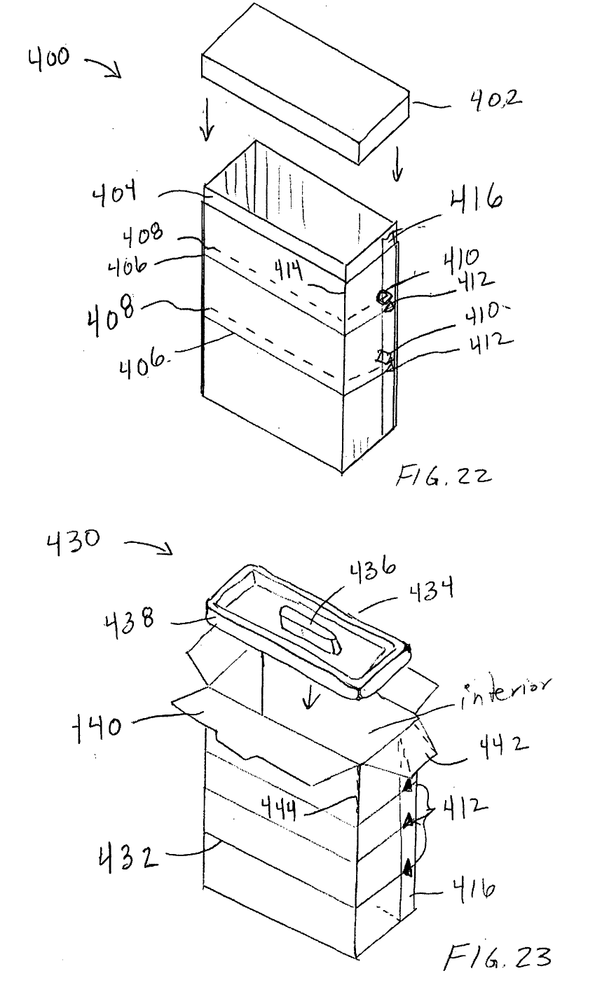

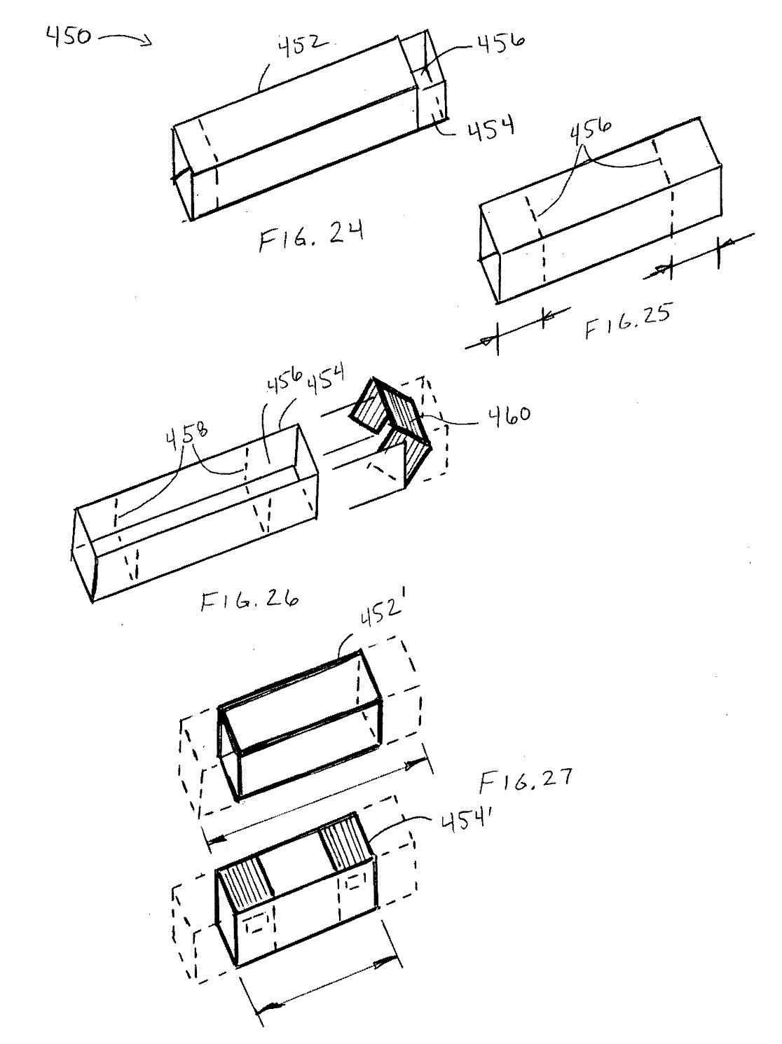

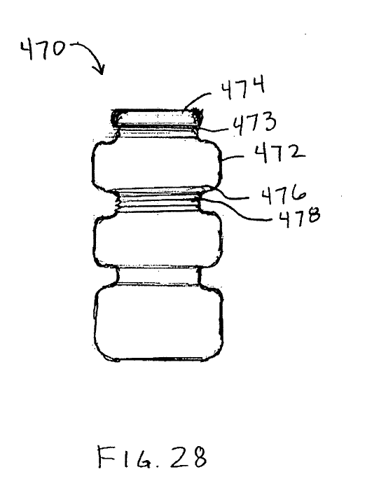

FIG. 22 exemplifies a double wall package 400, with lid 402 configured to fit in a recess 404 on the outer portion of the box 400. To facilitate engaging the lid, the box may be formed with inner and outer layers of cardboard, or other inexpensive package material are utilized. Pull strings 406, 408 on a double wall package are preferably configured concentrically, wherein after pulling the string to cut through the outer package layer a connector 410 is engaged between the end of the first pull string 406 and an inner pull string 408 (or alternatively the outer section may be bonded to the pull string for the inner section). Access to pull strings is facilitated with pull tabs 412. Wherein the user continues to pull around one more time to remove the correct inner portion. It will be appreciated that a stepped exterior is thereby provided over which the cardboard lid of the container (preferably removed by way of a single pull tab at the top of the container) may be slidably engaged to seal the box. It will be appreciated that the package may be configured with any desired number of pull-tabs and strings depending on the cost and market factors.

A single wall box may be utilized if the corners 414 of the box are scored for easy separation or compression to form a taper over which, or into which the lid fits.

A tab secure device 416 is shown as a band of material that overlies the pull tabs on the exterior of the container and is fastened securely under the package. The top of the tab secure device is accessible to the user, after opening the package, in this way no problems can arise with the tabs being inadvertantly partially pulled during shipment or while on the store shelf. The secure tab is shown loosely connected under the lid for removal the the user.

FIG. 23 depicts the use of a single layer container 430 having a single wall of cardboard wherein the pull string 432 allows removal of succeeding sections starting from the top of the container. The lid 434, shown with an optional handle 436, is used for closing the single wall box, and may be configured with a lip 438 to overlap the exterior of the box and may be fabricated from plastics, cardboard and so forth. Alternatively, lid 434 may be configured for insertion within the box. The use of an insertable lid portion allows the exterior of the box to be manufactured having conventionally folded flaps 440, under which the lid is retained above the ingredients of the box. The insertable lid is preferably fabricated from plastic wherein it may be configured with a handle as shown to facilitate removal from the insides of the container.

Pull tabs 412 are shown with the tab secure element 416 shown covering the pull tabs and fastened 442 to the upper flap wherein the flap must be opened prior to accesing the tab secure strip prior to using the pull tabs for reducing package size. This reduces the opportunity for package mishandling because the pull tab is not accessible until the package is opened. Perforating the edges of the carton, or otherwise providing compliance, allows a cardboard lid portion, such as a removed upper portion with flaps, to be slid over the lower section thus eliminating the need for a separate lid 434.

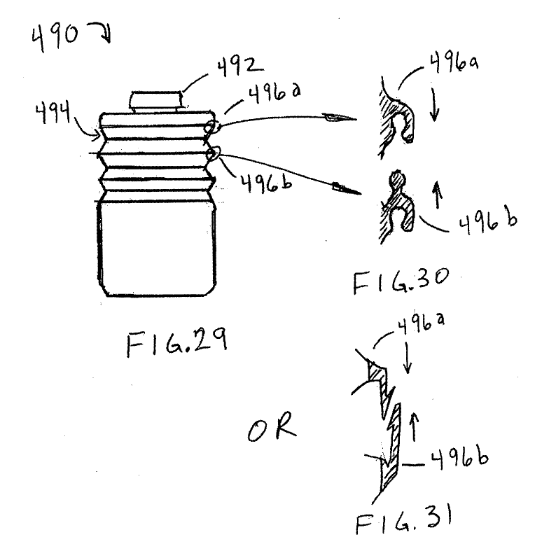

FIG. 24 illustrates another embodiment 450 of the invention on an elongated box having an exterior sleeve 452 into which a container 454 with storage area 456 is slid to close the package. The present invention can be practiced as by adding perforations 456 for reducing the size of the sleeve 452, as shown in FIG. 25.

Container 454 is similarly perforated as depicted in FIG. 26 up the sides and may be creased along the bottom to facilitate the fold, depending on material selection. The end portion 460 of container 454 may then be tipped up into the center of the open area 456 to reduce the size of the container. The completed configuration with both ends folded in is shown in FIG. 27 wherein reduced length sleeve 452′ is shown separated from slidably engaged shortened container 454′. It will be appreciated that typically one side would be folded at a time as package contents are consumed.

FIG. 28 depicts another form of container 470 having container segments 472, which taper to a neck 473, the top taper shown with a lid 474 attached, such as by snap-fit, or threaded. Between segments the necked down region is configured with a pull-tab 476 to separate the sections, reliefs to reduce strength allowing the sections to be torn apart, or other means of allowing the section to be separated. Once separated, lid 474 can be applied to the new top of the package, such as on threaded neck 478.

FIG. 29 illustrates another example container 490 in a compressible format with lid 492 attached to a dispensing/pouring spout from container 490.

As the contents are removed from the container it may be compressed like an accordian to eliminate wasted space. However, as a significant material thickness is required for the container to remain compressed once pressed into shape, the interface between adjacent pleats is shown configured with snap-together fasteners 496a, 496b which retain the container at the selected extension while minimizing material use. FIG. 30 details a snap point retention mechanism with fasteners 496a, 496b having rounded couplings, which may be readily decoupled if desired. FIG. 31 illustrates a coupling with sharp projections that are not readily disconnected. Either set of couple can be configured as discrete fasteners, or a fastening ring surrounding the container.

The present invention reduces wasted storage space, and provides an immediate visual indication of the amount of contents remaining within each package.

5. Unlawful Use Indicator

Containers, such as boxes, are often created for a specific use, for example boxes provided by the United States Postal service for Priority Mail, or Express Mail. These boxes are intended to be used on conjunction with a particular service for which they are marked, and it is unlawful to use them for other purposes. However, people often pick up these boxes, turn them inside out and use them as part of their stationary supplies.

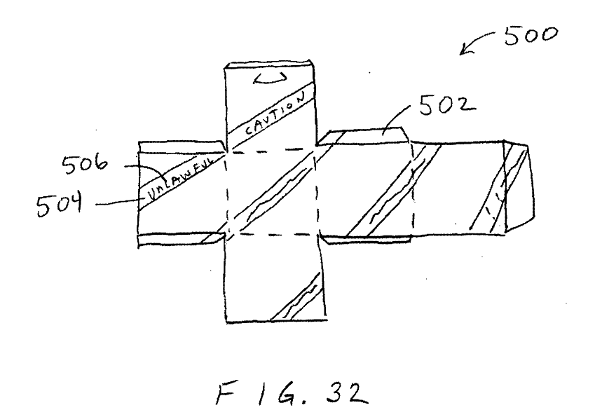

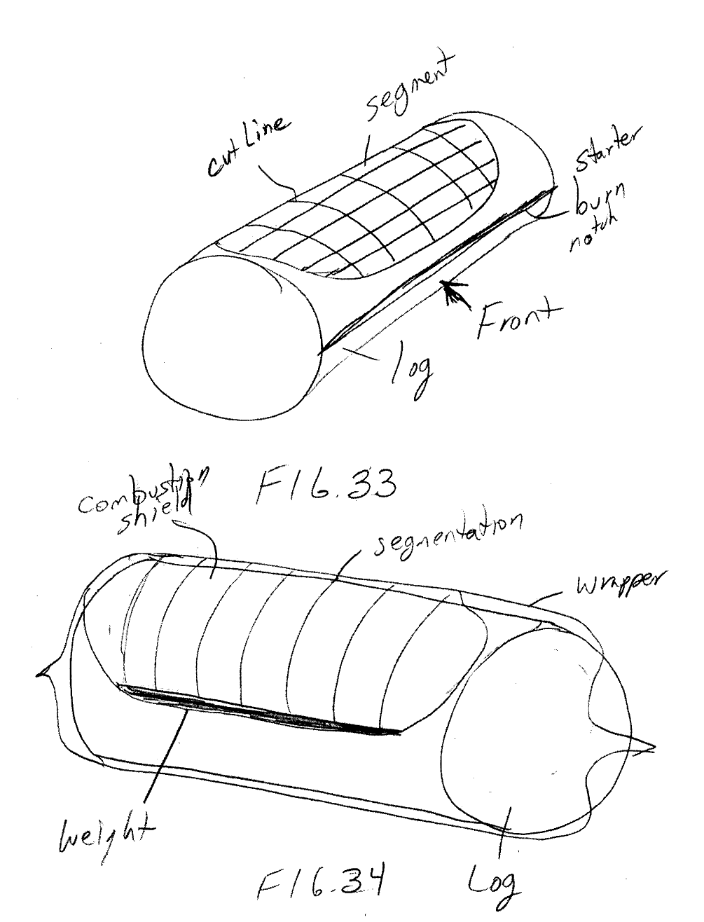

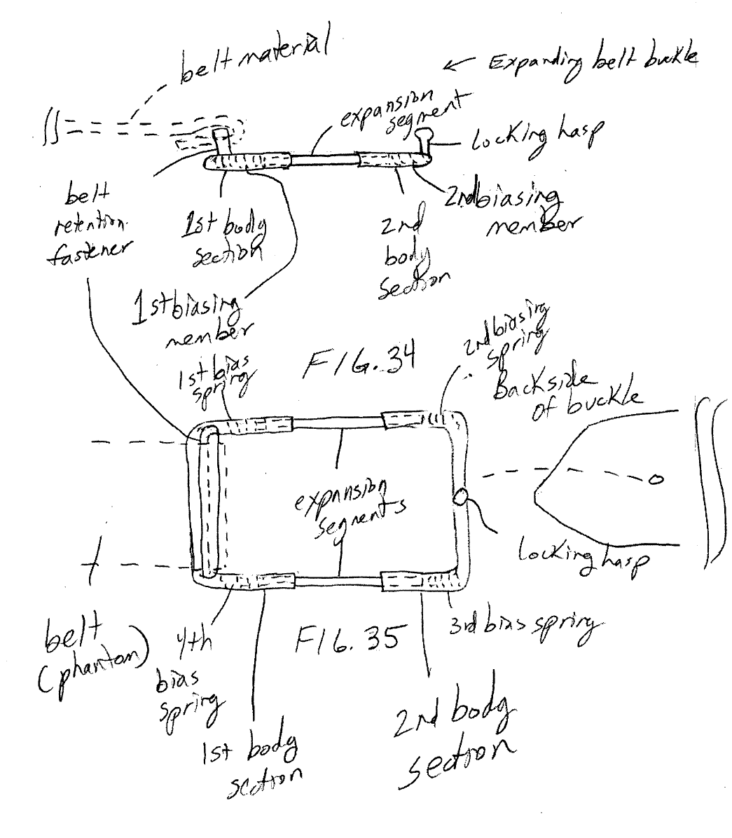

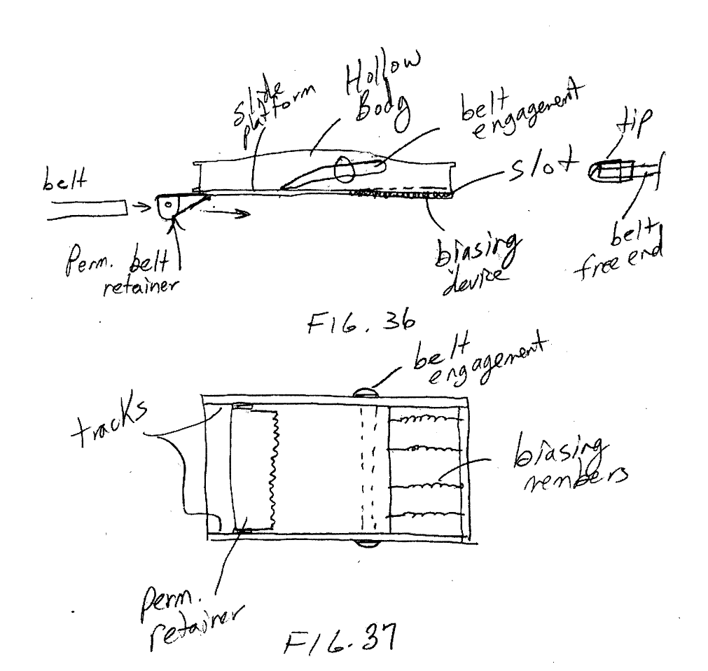

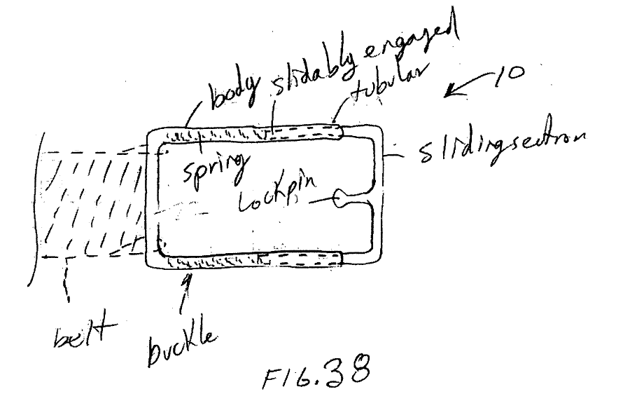

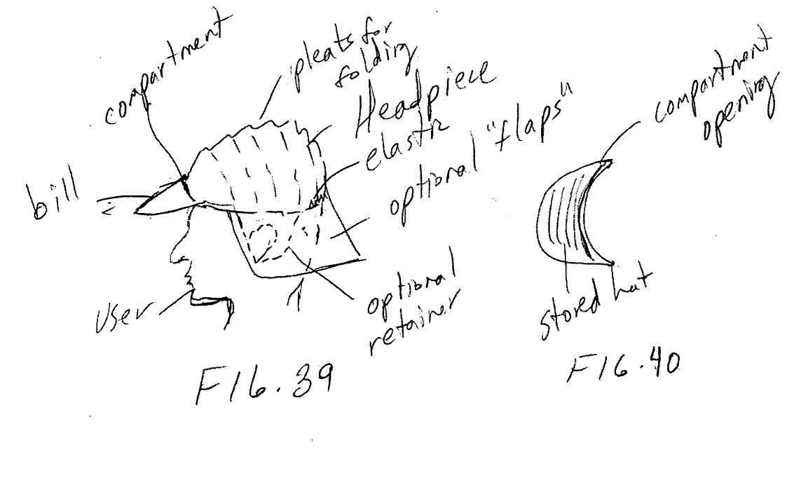

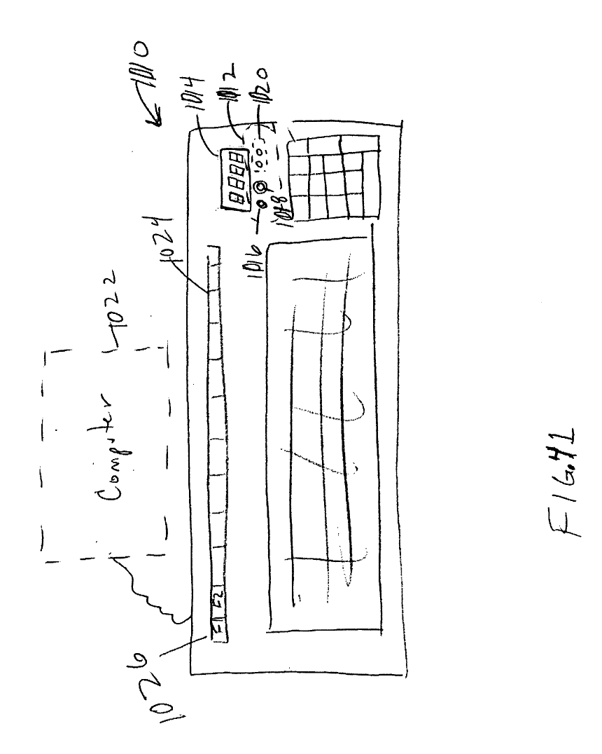

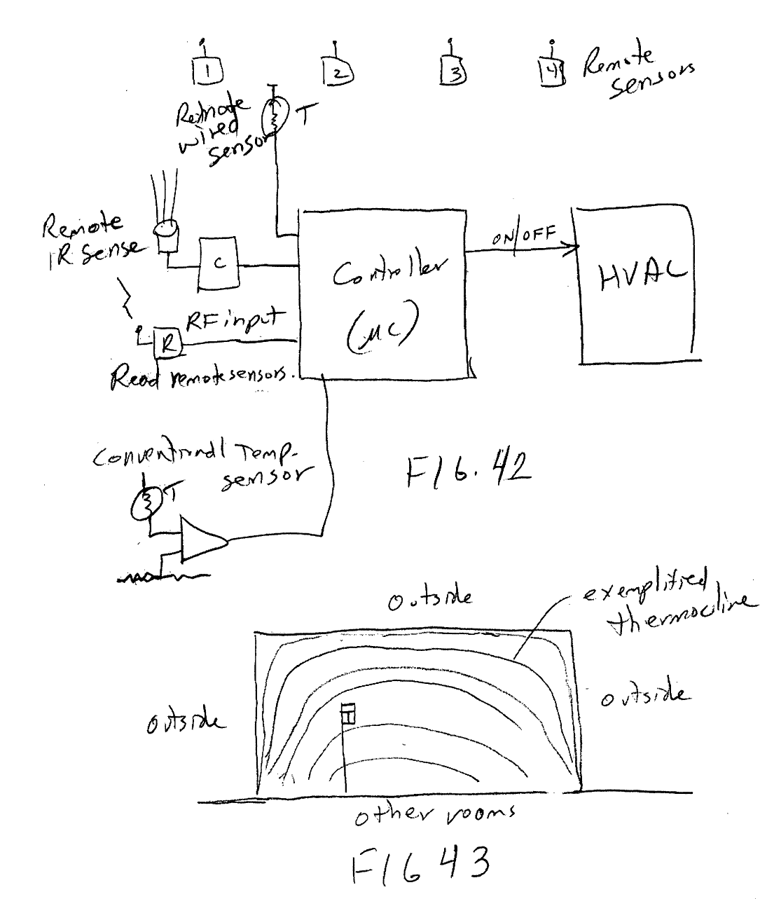

FIG. 32 depicts the interior sides of a box 500 prior to folding and fastening of tabs 502 to form the completed box. To prevent users from misusing the materials, the cardboard from which the boxes are cut should can be printed with a warning, shown as a stripe 504 with text 506, about the intended use of the material.

Adding this “unlawful use identia” to the inside layer of express mail and priority mail boxes prevents, or deters, their use inside out. Preferably a water resistant ink is used for the indicia wherein it will still be visible despite wetting or spray painting over the exterior. The indicia may even be of a non marking surface (plastic or teflon) so that liquids applied to cover it will bead up wherein even the color of the mark is still visible.

In this way inproper use is flagged and action may be taken. The number of boxes of lost per year should be significantly reduced by utilizing this method.

6. BRCFireLog—Manufacturing Methods

This incorporates by reference the patent application entitled “Apparatus And Methods Of Providing Enhanced Consumable Products” Ser. No. 10/016,852 filed Dec. 13, 2001 and provisional patent application entitled “Consumption Rate Adjustable Firelog Products” serial No. 60/256,887 filed Dec. 15, 2000, which are included herein by reference.

Methods of manufacturing a burn rate adjustable firelog are described. The burn rate adjustable firelog may be manufactured largely by any convenient process for creating a firelog, with a few minor modifications. The noncombustible shield material which may be provided on the log itself, or as part of a tray or more preferably attached to the wrapper for the firelog. The noncombustible material may be fabricated from metals, such as a sheet or foil of aluminum, or other material that will not be readily burned up during combustion of the firelog.

The shield may be formed by adhering it to, or incorporating it within a portion of the wrapper. Preferably the shield is glued to the inner or outer surface of the wrapper, preferably while the wrapper is still in a planar form and prior to the wrapper being wrapped and sealed about the firelog. The shield may be bonded to the wrapper with any convenient process including the use of adhesives, fasteners, stitching, interlocking reliefs or cutouts, and so forth. The shield may be created as a separate piece of material used for covering a portion of the firelog surface. The shield may be incorporated within the portions of the material of the wrapper, or a fireproofing/fireretardant material added as a layer to the wrapper of the log material itself. It will be appreciated that similar techniques are applicable to adding the burn shield directly to the firelog as for adding the burn shield to the wrapper.

7. BRCFireLog—Combustion Shields

This incorporates by reference the patent application entitled “Apparatus And Methods Of Providing Enhanced Consumable Products” Ser. No. 10/016,852 filed Dec. 13, 2001 and provisional patent application entitled “Consumption Rate Adjustable Firelog Products” serial No. 60/256,887 filed Dec. 15, 2000, which are included herein by reference.

This aspect facilitates the control of the burning process using the combustion shields. The combustion shield for a manufactured log product can be produced in a variety of styles, shapes, and configurations to alter the burning process in slightly different ways. A number of embodiments are described for the burn shields and manufacturing methods associated with them.

Segmented Combustion Shield:

The combustion shield may be attached to the wrapper, firelog, or an intermediate layer in a single piece, or may be segmented into sections for application thereupon. The user of sections can alter the burning as the amount of space between segments determines the rate at which the peripheral segments will begin falling away to expose a larger portion of the log to the combustion process.

Manufacturing—although individual segments may be adhered to the log, wrapper, or intermediate; it may be preferable to divide a larger piece into segments. (A) On-log shield cutting—For example to attach a large section of combustion shield to the surface of the log and then use a cutting device, such as a laser, cutting wheel, or mechanical cutting head to segment the material, whereupon the log may be wrapped. The direction of the combustion shield being shown on the wrapper. The small amount by which the log itself is cut into (typically 1/32″ to 1/16″) does not pose a problem.

(B) Additive shield—Attaching and segmenting a combustion shield upon a wrapper poses a slightly more difficult problem if the combustion shield comprises material cut from a sheet, such as a metallic foil. However, this may be handled in a number of ways.

The combustion shield may be applied to the wrapper as layers within a printing process, such as screen printing or similar, wherein the separation between the segments is easily accomplished. Sheet wrappers may be produced which have the combustion shield and only need be run through the wrapping machine conventionally. It will be appreciated that a number of fire retardant materials exist which may be applied to the wrapper (or firelog surface) in layers.

A machine may be configured for applying rows of combustion shield segments to the log wrappers at the proper spacing. The segments are preferably layers with adhesive, or it is applied to the wrapper itself, just prior to application.

(C) Using a backing—The combustion shield may be added to a backing and then cut, or cut for adherence to a backing, whereupon the segments and backing are applied after which the backing may be removed, or remain on the log or wrapper if it is flammable.

The above processes may be utilized with full coverage and/or partial coverage combustion shields (such as having a pattern of apertures to allow slight burning at portions of the shield).

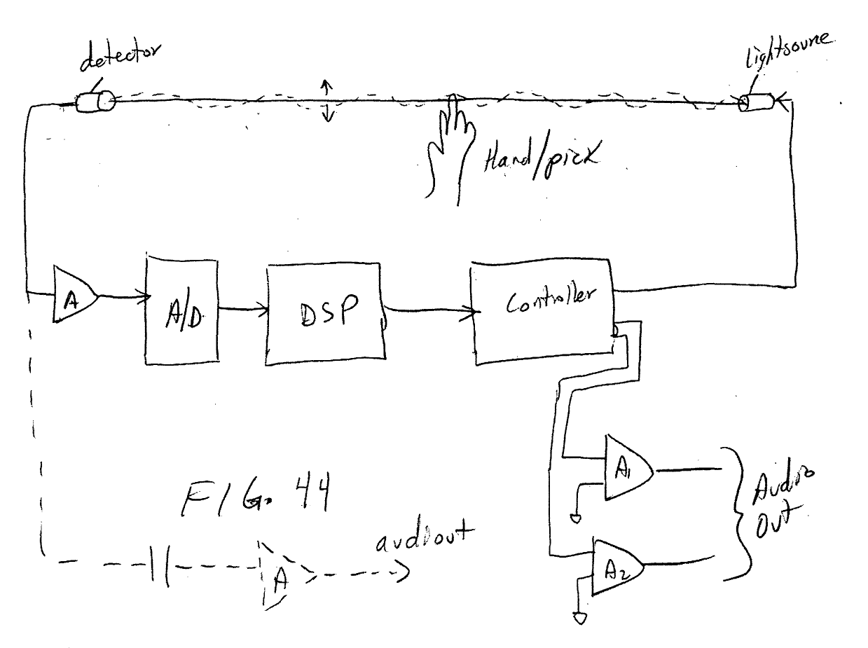

FIG. 33 illustrates a segmented shield as attached to a log surface, it will be appreciated that the shield may be of any desired size and pattern of segmentation and that it may alternatively be applied to a log wrapper, or intermediary layer, without departing from the teachings of the present invention.

The segments are shown in substantially rectangular, however, it will be appreciated that the segments may be vertical or horizontal strips or other shapes, such as circles, although the gaps between each segment become larger. There can be an advantage to using horizontal strip combustion shields as these retain the integrity of the manufactured firelog structure for a longer period of time. It will be noted that often a firelog placed on a grate with large spacing can readily break up during the combustion process as the materials soften.

Offset or Weighted Shield

A means may be provided for increasing the tendency of a top mounted (set for standard burn rate) combustion shield to fall away from the log. To facilitate the combustion shield falling away when mounted atop the log, it may be preferable to either:

Offset the material of the shield wherein as the wrapper burns away from the shield in the case of a wrapper mounted combustion shield, or the portions of the log burn away near the edges of the shield, that the shield may fall away.

Add a heavier section of shield to the rear portion of the shield wherein once the periphery of the wrapper has burned away the shield under the weight force is drawn off toward the rear of the log. The weight may comprise additional shield material, or other non-combustible material being added. FIG. 34 depicts this aspect with a vertically cut combustion shield that allows the entire strips to fall to the rear during the burning process.

Shape the log so that it slopes away toward the back thereby descreasing the static friction between the log and the segments, particularly within a wrapper mounted combustion shield.

Fire-Resistant Shield that Burns Away Slowly:

The combustion shield may be manufactured from a fire-resistant material that over a period of 1-3 hours burns away to then expose the underlying log surface. Foe example, the combustion shield may be formed from natural fiber materials, or other known materials, or combinations, which have fire-retardent properties.

This aspect of the invention may be combined with any of the embodiment for the combustion shields as described herein or the other applications included by reference.

Permanent Combustion Shield:

A combustion shield may be manufactured as an extrusion whose cross section matches that of a given firelog, preferably it is fabricated with slots or apertures wherein portions of the log surface beneath the shield can slowly burn to expose additional log surface during the burning process.

If the user wants to extend burn length, they insert the log into the combustion shield prior to lighting the manufactured firelog product. The shield is most easily formed from a metal, such as tin, steel, or aluminum, and may be reused over and over again. Drawbacks are that user must buy a combustion shield unit, store it, retrieve the dirty thing from the ashes, and it does not burn away at the edges.

8. Adjustable Belt—New Embodiments

This incorporates by reference patent application entitled “Apparatus And Methods Of Providing Enhanced Consumable Products” Ser. No. 10/016,852 filed Dec. 13, 2001 and provisional patent application entitled “Compliant Garment Belt Buckle” serial No. 60/302,897 filed Jul. 2, 2001, which are included herein by reference.

Aspect provides additional methods of implementing an adjustable belt buckle according to the invention.

This buckle has a fixed hasp, instead of the hinged hasp as shown in the referenced application. The use of the fixed hasp pin to lock in the belt opposite the fixed attachment with the belt material allows the width of the buckle itself to change size in response to the applied tension. It will be appreciated that combinations of the aforementioned methods may be practiced in this and the referenced application, for example a compliant attachment point to the belt may be retained while using this extendable buckle section in combination to increase the compliance of the belt.

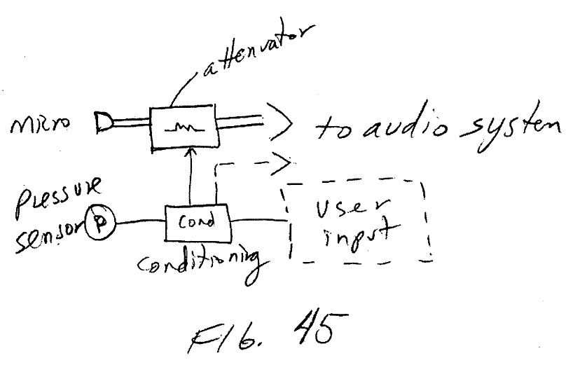

FIG. 34 and FIG. 35 depict an expanding buckle with first and second body sections between which is slidably engaged expansion segments that are biased by biasing members toward retracting into the body sections. The expanding buckle is configured with a permanent retention fastener on a proximal end shown with a loop of belt material (shown in phantom) attached thereto. The free end of the belt is retained within the buckle using a locking hasp on the distal end of the expansion buckle. The biasing member may be any compliant member, such as springs and so forth.

In use the expansion pressure on the belt will overcome the bias force allowing the first and second body members to separate thereby increasing the belt diameter which eases the tension and discomfort of the belt, without the need to use stretchy belt material, which is out of vogue.

It will be appreciated that the embodiment shown provides a dual expansion buckle which retains symmetry during expansion, however, any number of expansion sections may be utilized without departing from the teachings of the present invention. A single set of expansion sections may be provided which lowers the cost of manufacturing the belt buckle.

It should be appreciated that the decorative facings of various designs may be utilized to reduce the visibility of the expansion mechanism.

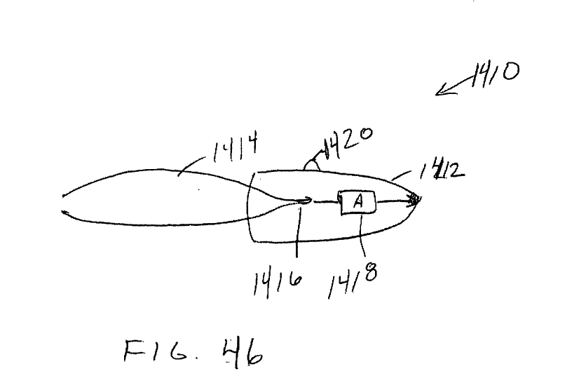

FIG. 36 and FIG. 37 depict a box end, military style, belt buckle which has been designed with an expansion mechanism according to the present invention. The rear of the hollow body is configured with a track into which a slide platform is engaged and upon which the permanent belt retainer is engaged. The permanent belt retainer typically provides a lever style locking mechanism, wherein the cut end of a belt is inserted and the locking mechanism closed to permanently retain the belt end (alhtoug it could be removed for cleaning and so forth it is not normally removed during normal use). The slide platform is biased in a direction to reduce the circumferance of the belt wherein as pressure exceeds the biasing force the belt expands to increase user comfort. The biasing members may comprise any convenient material that is capable of exerting a biasing force, such as springs, rubber material, and so forth. It should be appreciated that the biasing forces could be applied to alternatively “push” the slider, as opposed to “pulling” the slider under the bias force. A number of biasing schemes and expansion configurations may be adapted without departing from the teachings of the present invention.

FIG. 38 exemplifies a single expansion buckle with a single pair of springs within a body section.

It should further be appreciated that a number of expansion mechanisms that would be known to one or ordinary skill in the art may be substituted on the buckle itself without departing from the teachings of the present invention.

9. Compact Rainhat Having a Front Visor

The forms of inexpensive, disposable, rain protection that are currently available generally wrap around the head in similar manner to a shawl. It will be appreciated that many people, in particular men, do not find this style of rain protection visually appealing and thereby would rather suffer from having their head doused by the rain. These persons, however, can not readily utilize conventional rain hats due to their size and the resultant hat-head appearance that occurs after use.

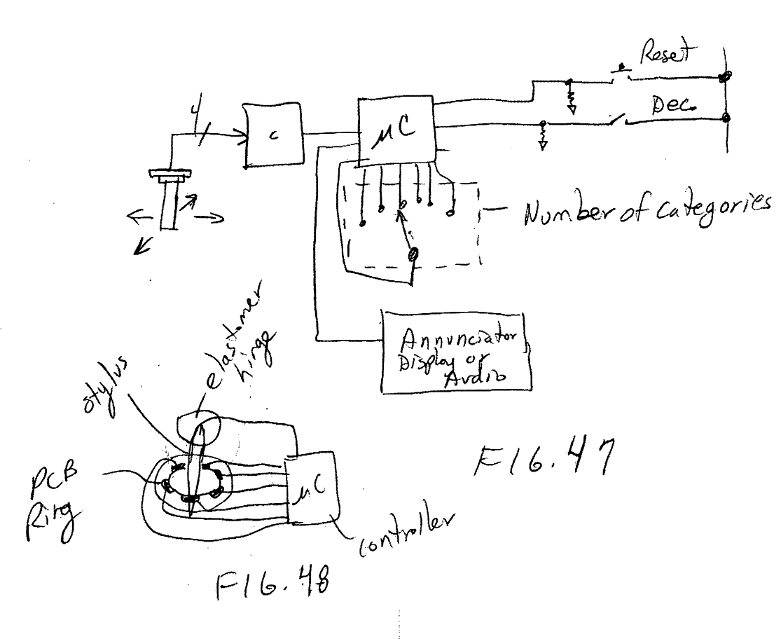

FIG. 39 depicts a stiff visor, such as plastic is adapted with a storage compartment (compliant plastic over or retained on the visor—such as thick bag material) into which the remainder of the hat may be folded and inserted. The compartment may have a zip lock style closure. Other items may be stored in the closure, such as ID, a key, or similar, while the hat is in use (for example during a run). The storage compartment may be configured for above or under the visor, or both.

The remainder of the hat is similar to a baseball cap but formed from pleated sheet plastic, similar to a plastic grocery although preferably thicker, with an elastic portion at the rear so that the unit may fit any sized head. Optionally the unit may be provided elastic ear retention loops to increase retention in windy weather, and optional rain flaps, may be integrated with the unit or provided for attachment on the interior of the hat, such as with snaps should the need arise. FIG. 40 depicts the rain hat stowed within the visor compartment.

This hat is attractive for even a man to wear and it keeps water away from the eyes and may be easily retained for use in windy conditions and so forth. It makes a good emergency rain hat as it is easily stored for use, and is inexpensive to manufacture.

TimeMux—on PC with Keyboard, or Other Hotkeys

This invention incorporates by reference patent application entitled “Apparatus And Methods Of Providing Enhanced Control For Consumers” Ser. No. 10/039,709 filed Jan. 4, 2002 and provisional patent applications entitled “A Clock for Tracking Time Accorded a Plurality of Tasks”. serial Nos. 60/259,955 and 60/301,193 filed Jan. 5, 2001 and Jun. 26, 2001.

The use of a separate TMux device provides a number of advantages, however, it is difficult to transfer the data from the device to a tracking program. The present invention provides the very rapid time tracking control of the TMux device but adapted for use with a PC, PDA, or similar computer enabled device.

A TMux keyboard that provides the time tracking functions, and optionally a display, directly on the keyboard. The data being tracked may be automatically entered into a time tracking program on the computer. The features and controls are similar to those depicted in the embodiments within the above referenced patent application, however they are implemented within a keyboard connected to a computer. It will be appreciated that the task data may be stored in either the keyboard or within the computer itself. The time for a given task or all tasks may be displayed on a display on the keyboard or displayed on the monitor associated with the computer either constantly or upon user selection. Additional keys on the keyboard along with the existing keys may be utilized for controlling task selection, time resetting, up down control of times, and other desired functions.

Preferably software within computer is configured to either maintain the task times or to interface with the keyboard which is tracking task times. This software may be implemented as a separate routine or as part of an existing application. In one implementation the task time data is retained in within TMux software and then periodically or at user request may be communicated to a conventional time tracking program, such as timeslips. It will be appreciated, that in similar manner as described for the other embodiments, the control of task timing is readily achieved within the need of switching programs and entering text strings and so forth, while the data is readily available for use by the more sophisticated programs.

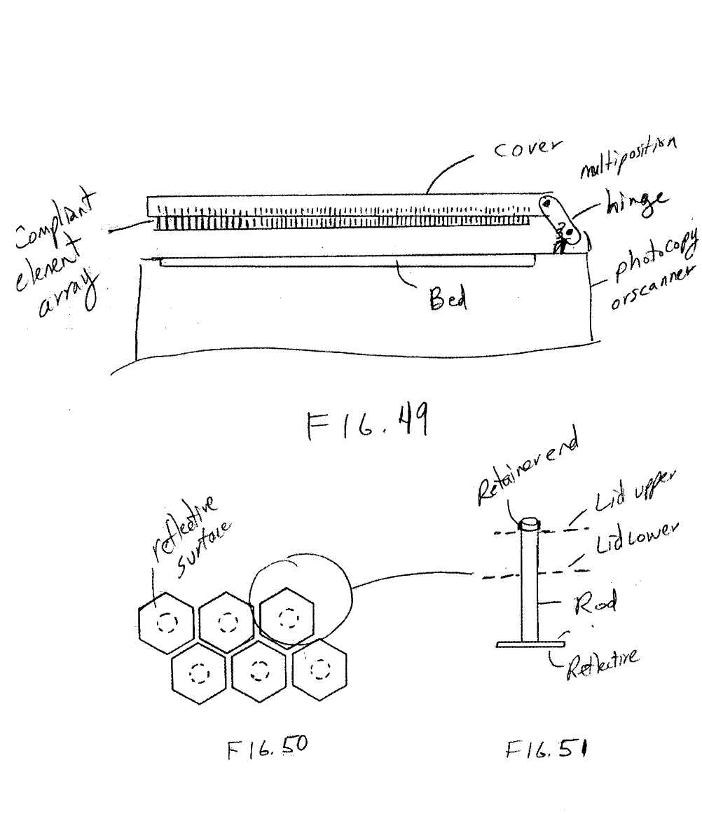

FIG. 41 depicts a keyboard 1010 with Task Multiplexor controls. A set of additional keys 1012 is exemplified and an optional display 1014. By way of example and not of limitation the controls comprise task select button 1016, a recessed task time reset button 1018, and a pair of up/down buttons 1020 to adjust the time of a specific task. Pressing the task selection button preferably generates a control key string to the computer 1022 which is captured by a TSR form of application which captures the command and generates a display of task legends across the monitor to facilitate user task selection. The correct task may then be selected by pressing a function key, number key, and so forth. It will be appreciated that the task select button may sequentially allow selection of different tasks, and that task selection may be performed in a number of alternative ways without departing from the present invention.

The task timing invention may be less preferably implemented on existing computer system as an additional application, a pop-up interface associated with a conventional program, or it may be integrated within a conventional billing applications to speed the control the task timing. Configuring software in the way provides a simplified “rapitrack” interface that allows the user to more readily control task timing and displays of timing.

It will be appreciated that conventional billing routines require the user to enter information about a new task prior to accruing time to it. Furthermore, in order to switch tasks the user must find and select the present billing category and stop the time accrual and then select the new task, or create a new billing slip for the new category. The present invention eschews the need to define the task or enter any information about the task, and the user can select a new task and stop the old task with a single click.

The task mux software may be adapted to output the current task time on the display at all times. Selecting a new task may be as easy as hitting the appropriate function key to start a different or new task into timing mode. Striking a task display key, such as the Fl key 1026, can signal the program to generate information about the tasks currently running, such as the number, legend, days accumulated time, and total accumulated time. The user can change the displayed legends such as by pressing a define key prior to hitting the task select key, wherein they can enter text which is captured as the legend information. Two consecutive presses of the Fl key can be used to bring up timing control parameters or interfacing parameters for use with a billing system.

When provided as a separate application the software would include a mapping function wherein the task times can be mapped to billing categories and sheets within a billing application. If however, the program is provided as a front end, or integrated within an existing application, it can seemlessly pass the data to a billing sheet.

11. Temp Diff Sensing Thermostat

To accurately control the temperature within environments having heating, or air conditioning systems. Most persons have noted that the most comfortable setting of a thermostat for a heating and air conditioning system (HVAC) depends on the outside temperature, and the exposure to sun. This dependence is due to the thermocline that exists between the thermostat temperature sensor to the boundaries of the area being thermally controlled. In the winter time the exterior of the home is cooler than the temperature at the thermostat and a negative thermocline exists where temperature drops from the thermostat temp. sensor to the extremities of the room, or home whose temperature is being controlled. To the converse, when it is hot outside, a positive thermocline exists wherein the average room temperature is above that read at the thermostat.

The present system adjusts the thermostat to compensate for the external temperature, and preferably also for radiation energy that is entering the environment being controlled.

The external temperature and radiation input may be sensed in any convenient manner, for example, pyroelectric detectors, remote temperature sensors, laser sensors, infrared detectors, non-contact temperature sensors and so forth.

The control system operates to control the HVAC so that the temperature of the environment is set to some average temperature along the thermocline that exists between the thermostat and the outside environment as sensed. Furthermore, it is prefeable that the user be allowed to set their preferences as to “where” along the thermocline this point should be set; this location being a comfort setting. In use the HVAC controller compensates for outside conditions to maintain an optimally conditioned environment without the need of the person changing the thermostat setting periodically.

The sensor should also take into account the black body radiation which occurs into or out of the environment. It will be appreciated that at night radiation energy leaves the environment through windows and so forth increasing the thermocline which exists from thermostat to environment boundary, while in the day (particular if sun shining in) the thermocline is more positive than indicated by remote temperature sensing alone.

FIG. 42 represents a control system having conventional sensing element tied to a controller. Additionally a number of sensors are shown, including a wired remote temperature sensor, an infrared sensor, and RF remote sensors. The controller uses the reading from remote sensors to determine the thermocline and turn on and off the HVAC to maintain the temperature at a given position along the thermocline instead of at the thermostat. It will be appreciated that a single outdoor temperature sensor may be utilized for simple thermocline sensing wherein adding additional sensors, including both temperature and infrared contribution, allows the controller to map the thermocline, and black body radiation, so that the temperature may be more accurately controlled.

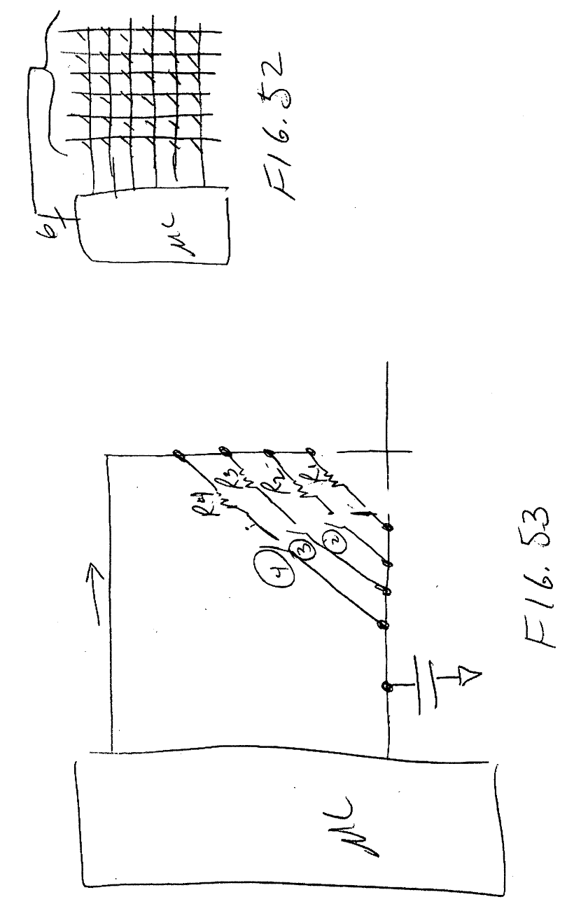

FIG. 43 represent a thermocline that may exist in a given room shown with a thermostat mounted on an interior wall. Each line in the drawing is an equal temperature line. The temperature from the thermostat to the outside environment follows positive curve if outside temp higher than inside, and/or infrared being received from outside at sufficient levels. In contrast, low outside temps yeild a negative thermocline.

12. Fiber Guitar

To create a stringed instrument having an accurate electronic output of string vibrations for driving electronic amplifiers and the like.

Various techniques have been utilized to sense the action of the strings on a stringed instrument. Such as pickups attached near the ends of the strings. Another recent method involves IR detectors adjacent the string that sense movement. [Article: “Rockin' Photonics” from Popular Science (2001?)]. These techniques, however, often prove inaccurate or expensive to implement.

The present invention provides the stringed instrument with a string wherein all or a portion of the cross-section of the string is optically transmissive. The system then generates a light at one end of the string and registers the light being detected at the far end to determine the vibration, harmonics, and amplitude for the string. It is known in the art that deflecting optical fibers alters the attenuation, the resonant wavelength, and other characteristics.

The system detects the attenuation changes, as well as preferably these additional metrics of the signal, to detect precisely the dynamic state of the string. The changes are then amplified to drive the external equipment.

The system can be used with guitars and other stringed instruments. The system replaces the use of other forms of pickups which may become less accurate in response to position changes, dirt, and so forth. The present invention is sealed and can accurately sense string action no matter what the conditions are.

To detect the nuances of string activity a digital signal processor, or neural network element, may be utilized to extract and correlate these low level parameters for use in the generating an accurate signal representing the string action.

It will further be appreciated that the bending of the fiber optic can alter the profile of attenuation in relation to light frequency. For example, in coupling a multifrequencly illumination source having a known frequency/amplitude signature into a vibrating fiber optic, the registered signature at the other end is responsive to the action of the fiber optic, the frequency of oscillation, subharminics and so forth. This characterization may be utilized in similar manner to a chemical spectrometer for detecting the true actions of the string.

FIG. 44 depicts a block diagram for a single string, the instrument is not shown but the string is attached to the instrument and configured with an optical source at a first end of the string and an optical detector at the second end. The detecting analog light signal is amplified and converted to a digital signal in an A/D converter and then processed by a DSP chip to characterize the optical information such as frequency, amplitude, and harmonics. The optical information is converted in the DSP or in a controller to audio information which drives output amplifiers. A controller is shown controlling the light to the optical fiber and receiving the optical data from the DSP however, it will be appreciated that a sufficiently powerful DSP chip can perform all the needed functions to convert from optical to audio.

In its simplest form the circuit may simply rely on the optical attenuation along the fiber, wherein the AC signal from the optical detector may be directly amplified, as represented by the dashed lines.

Additional Aspects:

+Allow illuminating the guitar string, with or without the above fiber optic sensing, with visible light so that the string glows. This makes it easier to use in dim light situations.

+Selective illumination of strings following a “training pattern” such as following a tablature encoded pattern that the user is attempting to learn. Additionally, it is preferably that the fret positions have indicators (i.e. organic LEDs on a poly panel, elnk along the neck, or other forms of indicative displays. The strings color and fret position indication are coupled to a controller system which has been loaded with playing data, such as from MIDI, Tablature, conventionally scored music, and so forth. In response to the the timing and playing pattern within the play data the proper locations to create the given musical piece are indicated sequentially wherein the user can create the given musical piece.

+elnk on the stringed instrument to show positioning—a section of elnk attached to the face of the instrument for indicating sequential play directions, fret positioning, finger positioning on the strings above the housing of the instrument and so forth.

+elnk musical instrument string—A cylindrical section of electronic ink and surrounding inner and outer electrodes may be configured within a string. A polymeric circuit preferably is connected to the elnk, such as a D Flip flop chain for selectively activating areas of the elnk in response to data along a serial signal line. The exterior color of the string may therefore be modulated to show correct finger positioning. It will be appreciated that polymeric LEDs may be fabricated within the tube as an alternative to elnk, however, the power requirements are far higher.

Squeeze-Me Microphone

Increase the control of music or system parameters in response to the pressure applied on the microphone by the musician.

Microphone with a “squeeze” intensity sensor (Pressure transducer, or similar) on the exterior or a trigger and so forth, wherein the sound being generated may be altered in response to the amount of pressure being applied. For example, the microphone itself may intensify, or attenuate the sound based on how hard the person is squeezing the microphone. The squeeze-signal may be sent back to a mixer that utilizes the data to control the mixing or it may be performed within the microphone itself.

Squeeze sensor may be trigger or similar control accessible to the user.

Other controllable elements within the microphone may be selected, by pressing buttons, triggers and so forth. For example: MP3 player with sound elements recorded, each sequential press activates the next sound byte. A sound effects generator may be alternatively included.

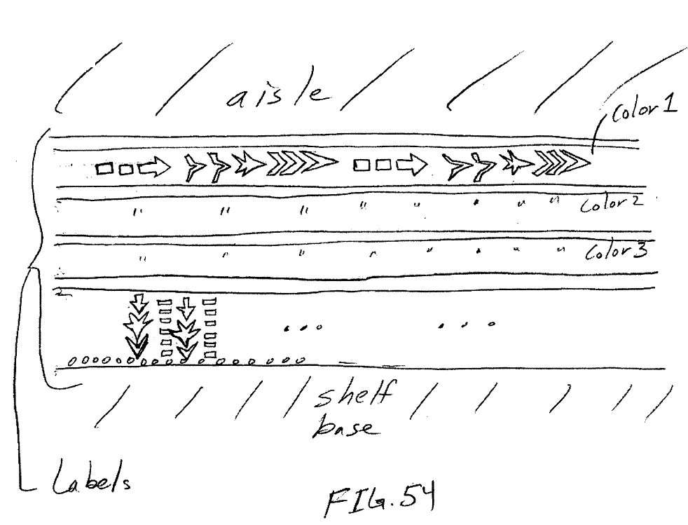

FIG. 45 represent a microphone connected to a programmable attenuator that is controlled by a conditioning circuit connected to a pressure transducer. The pressure applied to the transducer is registered and modulates the attenuation of the microphone. It is preferably the a very low pass filter by providing within the conditioning circuit so that noise, hand vibrations and so forth, are not coupling into the audio path.

Additionally inputs may be providing within a user input device that allows the user to select how the microphone output is to be controlled by the pressure signal. signal conditioning circuits may be added to allow the user the system to control the microphone Alternatively the pressure signal itself may be sent to the audio system with or without being used for modulating microphone intensity, wherein a remote control panel may use the pressure signal as they see fit for modulating aspects of the audio, lighting and so forth for the performance.

Additionally a sound generation device (e.g. MP3 player, sound effects generator, audio recorder, and so forth), or a modulation device (warble effect, box effect, echo effect, and so forth), may be included within the microphone unit and controlled as to the intensity by the registered pressure wherein the microphone output is modulated accordingly using analog circuits or DSP circuits. The use of DSP circuits allows for providing a number of both sound effects and various modulation effects, which can be user selected, such as with selection controls on the microphone.

Additional Aspects:

+May include a laser pointer, and so forth within the microphone.

+Optionally implemented as a shell for an existing microphone. The microphone attached to or slips into the control unit which operates to modulate the response of the microphone output.

14. AccuTweeze Automatic & Alternate sense

This incorporates by reference patent application entitled “Apparatus And Methods Of Providing Enhanced Control For Consumers” Ser. No. 10/039,709 filed Jan. 4, 2002 and provisional patent application entitled “Tweezing Device with Interposing Projection Feedback” serial No. 60/260,106 filed Jan. 6, 2001.

To eliminate the need of the user quickly yanking the hair. It takes rapid movement to yank the hair, and this is unpleasant. A solenoid, or other electromechanical actuator, mounted to the tweezers that can be triggered by the user when a hair has been grasped. The tweezer can be made to actuate upon detecting a hair, but it is contemplated that it is best to provide user control so that areas of skin or other areas are not inadvertantly plucked.

FIG. 46 exemplifies a power tweezer 1410 incorporating the sensing apparatus of the present invention. A housing 1412 preferably contains the electronics, although they may be retained in a separate housing connected to the tweezer head. The tweezers 1414 enter the housing and terminate at end point 1416 which is shown connected to an actuator 1418 connected to the housing. Activation of the actuator pulls the tweezer head rapidly into housing 1412 and plucks the hair that has preferably been located using the sensing mechanisms previously described.

Although the actuator may be engaged automatically when a hair, or other desired object, is properly sensed, it is preferable to include an input 1420 that allows the user to decide when the “pluck” operation is to take place. Input 1420 may comprise a push-button switch that activates the actuator, such as by allowing power to flow to a solenoid, muscle wire actuator, or other form of actuator.

Alternatively, the device may rely on compressed air, such as from a small external compressor to pull a vacuum that drives a pneumatic cylinder. The same compressor may be used with a filter and attachment for removing material from the pores.

A tweezer for performing powered removal of selected elements between the pincers, tweezer head, as described herein.

AccuTweeze Alternative Sense Head:

To provide sensing of the presence of small objects between the jaws of the tweezer, without the need to route fiber optics in both directions along the tweezers.

A number of embodiments are described in addition to those within the application as currently filed.

Single Row of Optical Fiber:

The detection described in the application may be alternatively implemented using a single row of optical fiber which is positioned on a first jaw member and directed to reflect light from the second jaw member, which is so positioned and adapted with an optically reflective surface.

The optical fibers may be arranged as coupled to LED light sources (or other light sources) alternated with optodetectors. (i) All sources may be activated simultaneously, wherein the light detected on the adjacent fibers connected to the detectors could read the intensity. (ii) Preferably, only one light source (or only one within a given span of fibers) is activated at a time while the reflected light is registered on all the detectors (or all those in a given span such as 3 on either side of the output fiber. In this way the reflected light as sourced from EACH fiber can be unambiguously registered, with a view towards providing an enhanced ability to discern various conditions between the jaws.

Preferably, however, each fiber is connected to an LED that may be used as either a light source, or as a detector. It will be appreciated that any conventional LED can be used as an optical detector, however, the signal response is not as good as that provided by an optical element designed specifically as an optical detector. So the source/detector combination may utilize a single LED coupled with each fiber, wherein the LED can be driven to source optical energy or used in a detector mode to sense the level of optical energy. Another option is that of including both an LED and detector in close proximity for coupling to the same optical fiber. This mode allows for reducing the number of elements required for a given resolution.

Optical Sensors Built into Jaw(s):

The optical sensing may be alternatively performed using sensors mounted in the jaws of the tweezers, for instance optical sensors, and optional pressure sensors. The sensors may be fabricated using conventional semiconductor fabrication techniques, or they may be fabricated from polymeric material, or the like, and/or using MEMs technology.

For example, LEDs and optodetectors may be fabricated on two separate die for positioning on each opposing jaw member, or fabricated on a single die for positioning on one jaw member and for directing a beam off of a reflecting portion of the alternative jaw member

It will be appreciated that LEDs may be fabricated on silicon circuits, on polymer circuits, such as so called “organic LEDs”, and in additional configurations.

The circuitry retained on one jaw member preferably comprises only the optical source, optical detector, and optionally simple conditioning circuitry such as amplifiers if the signal-to-noise ration would be otherwise compromised en route to a separate circuit. The separate circuit may be mounted in any desired location, however, proximal to the “Y” of the tweezer, or the handle is preferable as this is out of the way, and is convenient for the mounting of controls.

Pressure Sensing Built into the Head:

Having the sensor bank at the head allows optional pressure sensors to be incorporated for detecting the amount of pressure being applied between the jaws, and optionally with sufficient resolution on the pressure registration, to detect the pressure from the object between the jaws. For example a bank of 16 pressure sensors across the surface of the jaws allows the unit to better detect what is retained between the jaws, and how many items. The sensing of pressure can be used to alter the indications to the user, or for triggering an automatic plucking cycle, if the unit is configured with an actuator.

A tweezer having sensors elements within the jaws for sensing obstructions therebetween, as described herein.

15. Counter Pen

Simplifies the manual counting of elements, particularly those for which multiple categories exist.

Many office situations require personnel to count a series of elements, such as found on a sheet of paper, a form, a book, a screen, or other generally planar display. Counting according to a single category may be performed by hand, counting out load for each element, it becomes increasingly difficult to accurately count elements according to a series of categories. For example the number of claims and independent claims still pending within a patent application. A large number of instances arise wherein counting according to multiple categories is facilitated.

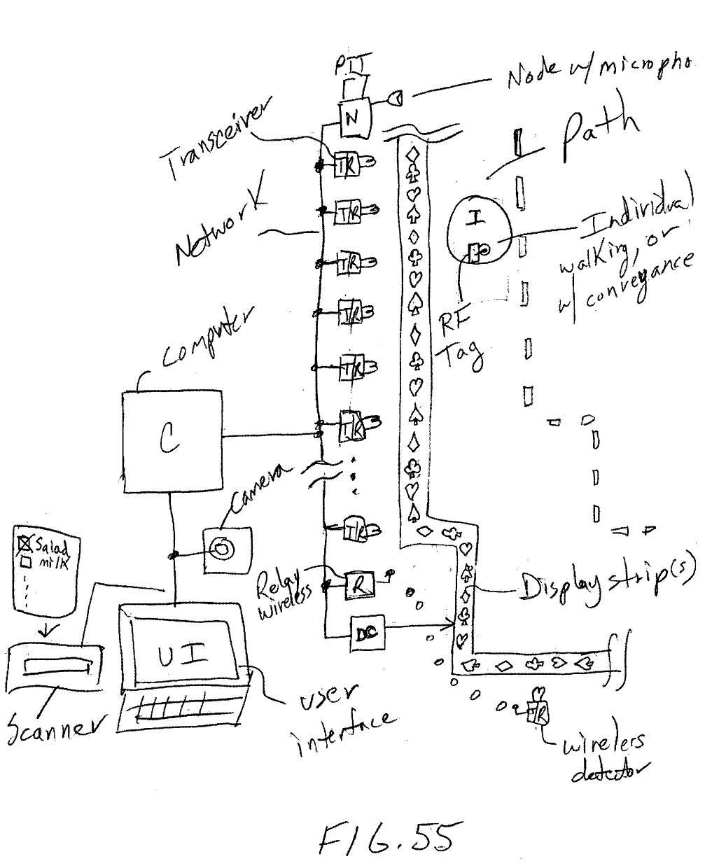

FIG. 47 and FIG. 48 depicts a counter tip pen/pencil/stylus, counter device for mounting on same, or a separate counting device. Present invention 1500 can count multiple counter categories in response to a touch, or other registered input, registered at a counting tip.

Preferably a tip 1502 registers a touch to increment the count. The direction of force being preferably registered by to determine which counter is to be incremented. Tip may have multiple projective tips, a center core with outer ring, or ring portions, or a single tip that can respond to direction forces (Like the joystick controllers). Typically from one to eight directions, preferably with two to six count categories

Annunciator—audio or visual display of the count.

Display—conventional LCD display(s)

Multiple displays—according to the categories of the counting.

Shared displays—wherein more than one category of counting is displayed on a single display. For example, sequentially, or in response to user inputs. User may press a button for displaying count, then press a direction to indicate which count is desired.

Electronic ink display: can display count as a series of dots (i.e. tens, ones etc. along side, or as a numeric value). Count can be updated continuously or in response to user input: for example by rotating a portion of the housing to register the count on the elnk exterior of the pen, wherein each count may be displayed at the direction for which it was registered. The following are a few examples of displays:

elnk with barrel screed: involved a weighted electrode screed that has a vertical row of electrodes (in line with pen length) which are positioned beneath a section of electronic ink on the barrel of the pen. The electronic ink has a conductive grid on opposing sides wherein the entire area may be set or reset. The count may be displayed per category by rotating the pen or “swirling it” (similar movement to the mechanical self winding watches wherein a weight was pivoted from an axis to drive a winding mechanism). The display is reset and as the screed rotates about the barrel the electrodes activated and deactivated to “print” a dot matrix pattern on the exterior of the pen. It will be appreciated that the processor controlling the printing via the screed must register the position of the screed at all times to control what is printed on the exterior of the barrel. The count should line up with the position at which the count was registered.

Single element displays—LEDs (or other single element displays) counting in a number base, such as base 10, wherein each element sequentially displays count at that place. For example 2 LEDs, or a single bi-color LED. By way of example, consider the bicolor LED the “tens” (10¹) being red and the green being ones. The count is output as a sequence of flashes, one for each 10 counts registered, followed by a display of the ones count (10⁰). For example 6 red flashes followed by 3 green flashes indicate a count of 63, for that count category.

Audio may be output instead of the flashes to consume less power. Furthermore, the audio may comprise a voiced count value (i.e. “sixty three”).

Process may be extended to any number of places, the counting may be any desired base, such as binary, octal, decimal, hexidecimal, and so forth.

Optional Inputs:

output count

subtract one from count (press then tap in dir. to subt. from that direction)

set number of directions to count according to . . .

FIG. 47 depicts an embodiment of the device using a keyboard pointer stick sensor which registers pressure in X-Y directions, and optionally a Z direction. The signals from the pressure sensor are conditioned and then input to a microcontroller which can interpret the pressure signal output to determine if the the user is actually executing a count and then determine which counter is associated with the direction of the deflection.

If a good match exists the unit generates an audio beep indicating that the count was registered. If the direction received is ambiguous, as to intensity or direction, then a “no good” audio signal is generated so the user knows to recount. Preferably the “good” tone generated has distinguishable characteristics depending on the count category, so the user gains confidence and can note if they inadvertantly counted some item in the wrong direction.

The count is incremented (or optionally decremented) in the chosen direction. If a display is connected it may be updated at the time the count is incremented or after all counting is performed. It will be appreciated that a number of different displays may be utilized. The controller is shown with a reset input connected to allow the count to be reset such as when starting a new count, and a switch to allow the unit to count down, or for correcting one or more mistakes in counting. A selector is shown allowing the user to set the number of count categories. Preferably the direction of the count categories should be indicated on the exterior of the unit, such as in color coded bands, so the user recognizes the direction necessary to input a count for each count category.

FIG. 48 is a second example of a device for registering a count directed toward a specific count category. A stylus, such as a conductive metal spike is attached with a blob of elastomer so that it may be moved toward the exterior of a sensing ring. The printed circuit board sense ring has conductive elements disbursed along it periphery which are connected to a microcontroller. As the stylus, which is connected to another lead on the uC makes contact with the edge of the ring a conduction path is established which is sensed by the uC that registers a count accordingly. Obviously, the uC performs rudimentary debouncing so that contact bounce is not registered as multiple counts. The unit preferably discriminates any counts that occur within less than 200 mS of one another as these are typically the result of contact bounce.

Additional Aspects:

+Protrusions from pen indicating the directions for which count categories exist. May be implemented as one of many slide-over unit, selected depending on the number of categories to be counted. It simplifies aligning the directions with the count category.

Counter SW for Phones/PDAs/Laptops

Included herein by reference: application herein entitled “Counter SW for Phones/PDAs/Laptops.”

Furthermore a related application entitled “Apparatus And Methods Of Providing Enhanced Control For Consumers” Ser. No. 10/039,709 filed Jan. 4, 2002 and provisional patent applications entitled “A Clock for Tracking Time Accorded a Plurality of Tasks” serial Nos. 60/259,955 and 60/301,193 filed Jan. 5, 2001 and Jun. 26, 2001 respectively, are included herein by reference.

This invention provides touch-screen tally functions on a programmable device. It will be appreciated that a number of devices may be adapted to provide for different functions by loading additional software or altering the resident software.

When activated the software brings up a number of categories on the screen, such as 4, 6, 10. The user may preferably define how many categories to track (i.e. 1 to 100). The user may tally items in any category by simply touching the category shown on the screen wherein the count inceases if the current mode is increment, or it decrements if otherwise. The user can reset any count, and preferably an option may be provided to add offsets to a count. The category shown in the screen preferably also displays the current count value. Each category field on the screen may be subdivided for entering single or multiple increment/decrement tallies. The user can preferably save the count values to a file. The data from the counting may be preferably formatted for import into conventional software applications, such as word processors, spreadsheets, and the like.

17. Tally Function for Calculators/Watches

Included herein by reference: application herein entitled “Counter SW for Phones/PDAs/Laptops.”

This invention is related to the applications herein entitled: “TimeMux—on PC with keyboard, or other hotkeys”, “Counter pen”, “Counter SW for phones/PDAs/Laptops”, and “Category counts for Copy machines”, which are included herein by reference.

Furthermore a related application entitled “Apparatus And Methods Of Providing Enhanced Control For Consumers” Ser. No. 10/039,709 filed Jan. 4, 2002 and provisional patent applications entitled “A Clock for Tracking Time Accorded a Plurality of Tasks” serial Nos. 60/259,955 and 60/301,193 filed Jan. 5, 2001 and Jun. 26, 2001 respectively, are included herein by reference.

To provide a convenient counting feature by category for portable devices, in particular claculators, watches, cell phones, PDAs, and the like. This allows the user to count a plurality of items readily while not being required to maintain a count, in particular a multiple category count within their heads. May be used around office settings, and for persons performing tallies or similar counting functions.

On entering the tally function (count by category mode) the device allows the user to count an occurrence of something, such as a dependent claim by simply pressing a single key corresponding to that category. Preferably the user can establish how many categories of items are to be counted, such as from 1—10 (example: category 1—independent claims, category 2—dependent claims). With each keypress the count value in that category is incremented by one. Optionally, extra inputs may be utilized for incrementing a count by a multiple, such as 5 or 10. Preferably the count according to each category is simultaneously displayed on a display screen and a tone is generated (such as a short beep) with each ×1 tally with preferably a different sound with a multiple tally.

Preferable controls include: reset a count, change from increment mode to decrement mode.

Optional features include: allowing the user to define the number of categories, initializing the count to a preset value, labeling a category count (i.e. key inputs, voice input, or stylus input), operating the category in addition to math functions wherein user can also perform a calculation and then add that count to any category.

Hardware:

A set of category tally keys and control inputs may be set aside or other inputs reused. The display is preferably capable of displaying a sufficient number of categories. The controller (microprocessing, microcontroller, DSP, etc.) may be configured to save a plurality of RAM or register locations for retaining the count values. After entering tally mode, if a tally key is pressed then the uC advances the count in the associated register/RAM location and updates the display. If the control is set in decrement mode then the tallys operate to decrement the register/RAM. The remainder of the implementation would be known to one of ordinary skill in the art.

18. Category Counts for Copy Machines

To simplify the tracking of copy counts according to a set of categories. User may define categories into which copy counts may be maintained, optionally the system may retrieve copy categories over the internet from a database, document file, file directory, and so forth. If a category is selected then each copy performed will be registered within that category, as well as preferably the type of copying performed (i.e. 1 side, 2 side, BW, color). Category selection may be according to one of any predetermined categories, which may be set externally or by the user. For example the categories may be associated with client accounts, docket numbers, persons using the machine, and so forth. This extra data allows a business to track their copy expenses and to properly charge clients, expense categories, departments, and so forth for copies.

Aspects of Invention:

+categories based on data from internet.

+can operate an as interface to network based application.

19. Copy Machine Tracking by User

Application described herein entitled “Category counts for Copy machines”, “Advanced Photocopy services”, and “Photocopy no-reset detection” are included herein by reference.

The use of a copy machine may be easily tracked on a user per user basis, while unauthorized copying is prevented.

A biometric reader device is integrated into the system to control access to the machine and for tracking use of the system. Prospective user presses finger on the scanner (or optionally the “Copy” key of similar) wherein their biometric data is looked up from within the machine, or optionally over the internet. If a match exists the user is cleared to use the machine. The authorization should take only from 1-3 seconds to perform. Each copy that is then made will be tracked according to that user. Furthermore, if a count category has been selected as described in related application herein “Category counts for Copy machines” which is included herein by reference. This feature operates best if a non-reset detection system as described in “Photocopy no-reset detection” are included wherein the category counts and user tracking does not reset while a user remains proximal to the system and is just between successive copies. Once finished the user can press the clear key to logout. Preferably when the biometric information is read the recent use of the system, such as copy count category selections, and other setting information will be stored in a stack so that the user can restore a prior function—as this is they way that copy machines are typically utilized.

It will be appreciated that access may be alternatively controlled by the use of other forms of identification such as key fobs, cards, number entry and so forth, without departing from the teachings of the present invention.

20. Advanced Photocopy Services

Present copy machine functions do not fulfill all the document processing needs. The following copy machine aspects can be implemented on a copy machine.

Imprinting additional items to each page:

The user can input a fixed or variable region to be added to each page photocopy image. Information about the region is read into the machine and stored in a memory, wherein after scanning the page to be copied the region is then either used to replace the data from the copy or to be summed with it, so that it is overprinted. The user can preferably decide whether it is to be overprinted or replace the scanned material.

One form of a stamp is a fixed stamp such as “[COPY]”.

The information may be a variable, such as a date, page number, docket number, wherein the machine converts a text variable into a graphic that is summed with, or overwrites the scanned page memory image. A fixed stamp may have a variable field as well, such as “[Received on %Date %]” wherein the date field is filled in by the machine, or similarly “Pg %P %” wherein the page number is filled in.

Users can preferably scan and store an image within the copy machine for use in overwriting or replacing a section of each, or selected, copy.

Preferably the stamping feature may be selectively applied to either the front or back of the page. Often users may want to print company information, page numbers, and so forth on the rear of the page. The user could select a preprogrammed “stamp” or enter a page or portion that is to be added to the rear of each single copied sheet.

The items being printed should include bar codes, wherein a user can enter a text, or numerical string and have the copy machine convert it to a bar code and print this on the facing or rear of the sheet. This can be even more useful in combination with the variables, where for example a bar coded date may be printed on each sheet copied along with any desired fixed information.

“Scrubbing” regions of scanned pages:

Similarly the “Stamp” may include regions to be scrubbed from the document. These regions may be programmed or the user may select preprogrammed regions, such as at the top or bottom of the page. The machine then erases the memory areas associated with that portion of the scanned image. The user may enter in their own custom areas by roughly drawing in the region on a sheet and then selecting the mode for entering a scrub area into the copy machine. The system then converts the image to a map, after straightening the vertical and horizontal lines. Optionally the copy machine prints out the straightened scrub region so the user can check it with the document to be scrubbed. The user can enter a number of scrub areas which may be combined with one another. When copying, the user can select a scrub region they have entered, or that has otherwise been defined, wherein the scanned text and image data from those areas will be eliminated from memory. This feature may be utilized in combination with the stamping feature, wherein printed material is added over the region scrubbed.

Furthmore the user can select the removal of a background color or grid, such as found on graph paper. The machine can detect the horizontal lines and vertical lines associated with the graph paper. As these lines are predictable, writing that cross horizontal and vertical lines is easily distinguished. The system them scrubs the image of the grid from the copied image, however, it checks for writing which is adjacent to the graph line. If the contrast is sufficient it can extract the written element that incurs over the graph line, otherwise it can attempt to close the character or fill it in as best it can. If it is handwriting this may be as easy as extending the line to cross past the graph line being extracted.

Removing Background Shading:

Often material is distributed as printed on a colored background. These sheets are notoriously difficult to photocopy. The following allows users to copy the contents on a document without regard to the paper color. A few methods are described for this:

The scan is performed in color and the contribution of colored backgrounds may be automatically dropped out, by registering the particular color that comprises a background and removing it from memory while increasing the contrast, if necessary of the text which overprinted the background. The a tone compensation may be applied so that the resultant background is white with the appropriately colored text, if machine supports a color output.

Scanning in black and white. It will be appreciated that a BW scan may be performed instead of color and the user just select that the backgound should be “untinted” wherein the low intensity background is compensated for in a tonal shift that results in pulling out just the darker intensity elements.

Survey response scanning of pages:

This feature is particularly well suited for copy machines that are connected over a network for communicating information with files on a server.

A copy machine with a feeder may also be utilized for scanning pages and extracting information about the content. For example scanning preprinted forms that have been marked up by a user, such as in responding to a survey and so forth.

The user may scan a blank form into the machine as a baseline. Sections of this form may then be identified as to the type of material contained in that regions, such as radio list (one check box in field), check list (any number of checkboxes), name, address, text entries, comments, and so forth.

A set of completed forms may then be scanned through the machine wherein the regions of the forms are converted to a more easily usable format, such as storing the contents, without the form elements, into a database. The checkboxes are easily interpreted if the user has entered what should be output for each checked checkbox. The system may also interpret name, address, and comments fields, however, the image for each of these should also be stored so that the optical character rendition of the written information may be checked. In this way the user can gather information from a large number of survey instruments and have these placed into a database for further work if necessary. Presently, order entry personnel must often read these forms line by line and enter text into the computer as to the information on the form. This mechanism eliminates the need to enter anything for easy interpreted fields, while the more difficult to interpret fields preferably generate an optical char generation output with an image, so that entry personel only need check the generator out with respect to the image, if correct then the image may be eliminated to free up room in the database.

21. Photocopy No-Reset Detection

To increase copy machine efficiency by not resetting user settings if the user is still at the machine, even if a copy has not been executed in the proscribed length of time.

Activity sensor—after entering a particular setting the user must readily use the feature prior to the photocopy machine resetting all settings. This is often a problem for users that must manipulate items between copies and so forth, or that are otherwise a little slow. The present invention senses the presence of the user near the front of the copy machine and retains the settings as long as the person remains in a sensed position.

Sensing may be performed using optical sensors, inductance sensing, infrared sensing, and any other convenient means of sensing that a user is near to the machine, such as still engaged in copy operations.

22. Scanning System Adapted for 3D Objects and Other Features

To allow for the scanning of 3D objects, and to improve the ability to scan other types of objects.

The present invention allows a copy machine, scanner, to provide enhanced copying of small 3D items. Two major embodiments are described herein. (1) A first embodiment uses a compliant array to conform to the 3D objects, thereby increasing the amount of light reflected back into the scanner to reduce the black areas around the article. (2) A second embodiment utilizes a lighted lid for backlighting the subject to reduce black areas. Preferably the lighted lid may be activated during a separate scanner pass to derive silhouettes for the 3D items wherein the front reflected image may be processed to set the silhouette, which is background to any desired color or shade while the sensitivity toward the reflected image may be optimized to boost the reflected rendition of the article.

Compliant Reflection Array:

The lid of the copy machine, or scanner, is configured with an articulated lid allowing it to be positioned at differing heights above the scanner bed surface. A number of techniques exist for performing this as scanners presently allow pages of an open book to be scanned. The lid of the scanner is configured with an array of elements which drop down from the lid of the scanner or copy machine to fill in the voids around the 3D articles, wherein the dark boundaries may be reduced or eliminated. It should be appreciated that this feature should also be beneficial when copying pages from an open book, in that the edges of the book do not match the scanner bed wherein dark bands typically appear.

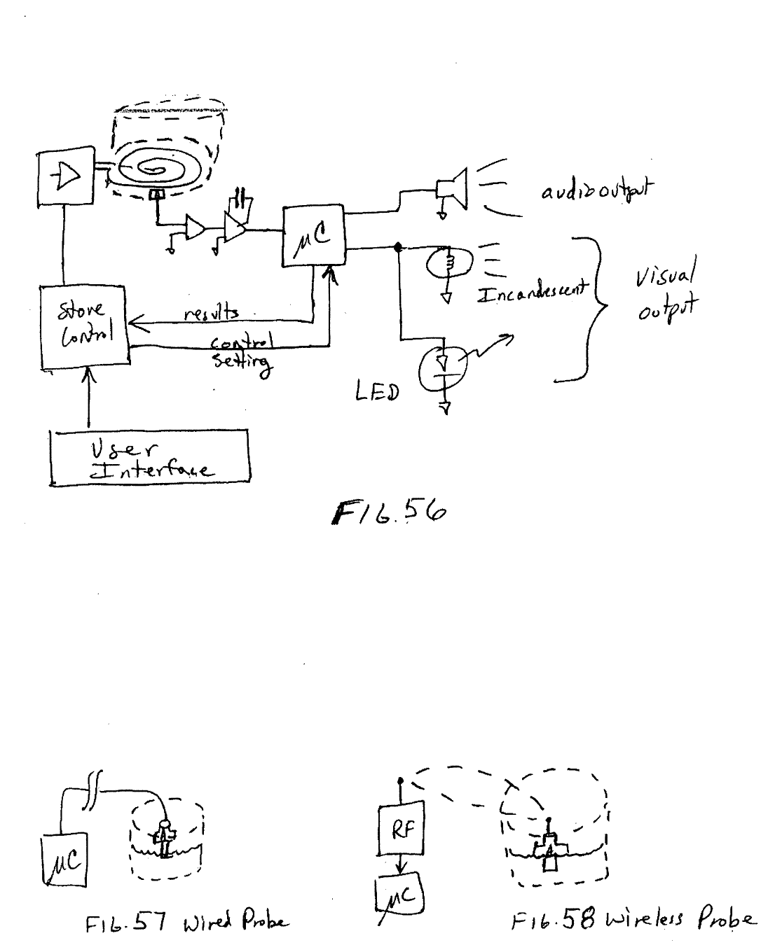

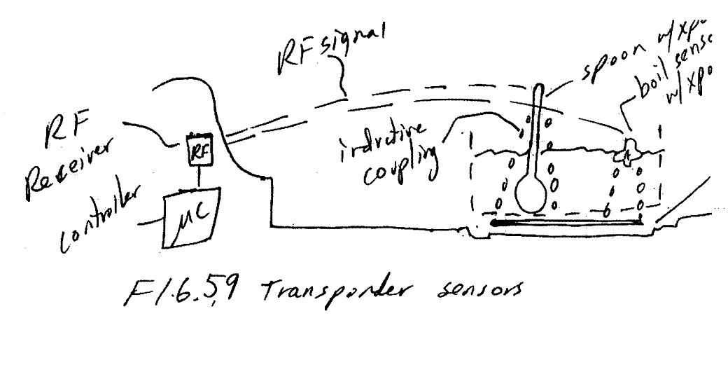

FIG. 49 exemplifies the lid of a copy machine having an array of compliant reflective elements on the underside of the lid. FIG. 50 depicts a small portion of the array, wherein a series of closely spaced hexagonal structures drop from the lid into voids over the bed portion. A single array element is shown in FIG. 51 with a reflective “plate” portion connected to a rod that terminates in a retainer end. The rod portions is preferably slidably engaged within a lid upper and lower aperture matrix, and springs or other downward biasing mechanisms may be optionally included so that the array elements will have fewer difficulties with dropping down into open spaces. Each reflective element may be pushed up easily into the lid by portions of the 3D elements, such as books or structures being photocopied. The face of the elements are shown as octagons however, they may be alternatively configured in any desired pattern that preferably fills a large portion of the area above the base.

When the copy machine, or scanner, is in normal use it is preferred that a sufficiently stiff opaque sheet extend over the array, wherein the array pattern then can not show up within the background of the photocopies, or scans.

Another optional aspect of the invention is to perform image processing on an image that was scanned using the compliant array, wherein compliant elements may be detected within the resultant image and converted to a desired background shade, for example white (no ink). The reflective portions of the elements may be further identified with stripes, indicias, optical frequency selective reflection material that may be detected by the scanner, or other means to increase the ability of the scanner or copied to discern the array elements so that the image processing software can eliminate their contribution to the image.

Another optional aspect of the invention is to provide backlighting within or behind the compliant array. It will be appreciated that the dark areas of an image show up with the bright light from the base shines out through an uncovered area of the bed and is not reflected back onto the scanner head as it makes its pass. Therefore by coupling external light from the opposing side of the unit onto the scanner head the dark areas may be filled in.

Lighted Background:

(2A) The array described above may be eliminated and the lid portion designed with the backlighted which may be selectively operated according to the user settings of the machine. In order to prevent the dark areas on uncovered regions of the scanner/photocopy machine, the light intensity generated from the lid needs to be close to that which would be reflected from the intense scanner light onto the scanner surface. This backlighting mode should be selectable, because backlighting through a document, particularly a thin single two sides sheet increase the amount of image bleed through from the reverse side of the document, currently this is even a problem for conventional machines as the light passes through thin sheets and picks up the material on the opposing side of the sheet as well as the front surface.

(2B) The intensity of the backlighting need not be particularly bright if it is not competing with the light generated from the scanner bed. The present system provides a few embodiments for handling this situation. (i) The scanner can execute a second scan over the material in during which only the backlighting is operating. Activation of backlighting with bed lighting off will cause a silhouette image to be registered on the light receptor bar for opaque 3D articles. The silhouette image is then used as a mask for determining what areas of the background are to be “dropped”, while the sensitivity and contrast used on the areas not being masked out can be increased to improve the final result toward that which would have resulted for a flat object. A similar technique allows for the elimination of bleedthrough, and can provide an additional copy machine or scanner feature. In this mode the backlighting is performed on a separate pass as above, however, the scanned image from the backlighting pass will actually have significantly increased ghosting, as the light registers is only the light passing through both sides of the paper. As the front image will contain a lower percentage of ghosting the signal processing routine can readily discern which image corresponds to the front of the sheet and which corresponds to the rear of the sheet. The front image is then accentuated and the ghost image dropped by the information received from the backlighting.

(2C) The backlighting may also be performed during the same scan pass by using a backlighting, such as UV, that is in a spectral range generally outside of that generated by the light from the bed. If the optical elements used in the scan bar have a wider spectral response and the contributions in different spectral regions registered separately, then a single array of elements may be utilized. However, in general a separate array of receptor elements would be added to the scan bar to perform this feature, wherein the backlighting may be directly registered on the same pass, however, over a different spectral range. The image data from the backlighting may be utilized to provide the same user features described above.

Increasing Effective Resolution:

The scanner bar may be mechanically oscillated according to a particular pattern so as to collect additional images having subpixel offsets. The image processor then can use artificial aperture techniques to combine the subpixel offset images to increase the resolution of the image. Resolution in any axis can be effectively doubled by doubling the subpixel offset images in the axis. Collection of four images can increase resolution nearly four-fold. Artificial aperture techniques are well known in the art. By way of example, the scanner bar can be oscillated in a circular pattern, or an up and down pattern, such as by using a piezoelectric driver elements, muscles wires, motor drives and the like. The image capture from the scan bar is synchronized with the translation of the scanner bar so that the images are at substantially fixed pixel offsets. The user can select this mode if high resolution images are desired. Alternatively the hardware cost of the scanner/copy machine may be reduced by reducing the number of photoreceptors in the scanner bar and relying on the artificial aperture technique to render the increased resolution necessary. This has become feasible as computational costs (cost per MIP) have plummeted.

23. Talking Tall

To provide a fun and easy, inexpensive, and easy to use height measuring device for home, school, nursery schools, day care centers, and so forth.

The height of individuals is measured in numerous circumstances and locations. Performing height measurements on children has always been very popular; children delight in hearing how much they've grown. Currently the height of children is measured at school and home by means of marking height against a wall and then measuring the height of the mark, or by marking on a wall mounted ruler and reading it off. While these methods are still effective, they require adult help for small children and lack entertainment value.

New laser and sonar style measurement products have recently been produced that can automatically make height measurements yet they are too expensive for general use at home or school.

Commercializing an automatic height gauge for general use and cost sensitive home and classroom use requires development of a design that is inexpensive, small, easy to use, light-weight, battery powered and sturdy. When considering the application areas for such an automatic height gauge, the prior art has numerous shortcomings.

In U.S. Pat. No. 4,518,052 of May 21, 1985 the automatic height measurement device of Li-Fu Chen employs a winding transmission cord that moves a sliding plate that is then sensed by a digital display that consequently reads out the height and/or weight. This design essentially forms a digitized weight/height scale as generally employed in medical offices. The design is heavy, large, expensive to produce, and it can require periodic adjustment as it contains abundant mechanical structures that interface to an infrared distance measurement unit coupled to a digital measurement and display means.

In U.S. Pat. No. 4,694,581 of Sep. 22, 1987 the “Height-measurement Device” of William P. Heinrich is an improvement of the mechanical measurement device wherein a graduated staff is fitted with a combination slider/horizontal bar that is lowered to the top of the persons head with the corresponding height being manually read from the graduated staff. This is a manual mode mechanical device with minimal entertainment value.

U.S. Pat. No. 4,896,432 dated Jan. 30, 1990 describes a “Stature Measurement” device invented by Dong M. Chang. This device attempts to improve the use of a tape-measure as a means of measuring height wherein tape is stretched between a base plate and a switch that rests on the head of the person who's height is to be measured. This measurement device is not automatic, it still requires reading from the tape measure. Additionally the device contains numerous related assemblies that increase cost, weight and packaging. The device produces a tone sequence when the horizontal plate is placed on top of the persons head. This tone alerts a second individual that they may now read the height value off of the tape measure.

In U.S. Pat. No. 5,272,517 of Dec. 21, 1993 the “Height measurement apparatus using a laser light beam” of Nobofumi Tokura employs a laser light beam mounted vertically and pointing downward, whereby distance is calculated when the laser-light is reflected by any surface that cuts the path of the beam. The beam is vibrated relative to the surface of the object and measurements are taken and averaged to generate a resultant height value. The object of the invention is to measure vertical features contained on printed circuit boards, although it could with modification be used for measuring the height of individuals. As a method of measuring height for individuals the device would be large, costly, and require periodic maintenance.

Ultrasonic height measurement devices exist in the marketplace.

Automatic human height gauge devices currently on the market and prior art patents do not suggest a design for a small, thin, light, portable, low-cost and entertaining device that will automatically measure and announce a person's height

A simple inexpensive device for annunciating the height of individuals in response to contacting the device at a location corresponding to the top the head of the individual. The unit is preferably packaged as a strip about six feet long, from 1-4 inches wide, that attaches to a wall. The upper half or more of the strip can sense pressure, such as from the end of a ruler placed on the head of the child or a childs hand pressing back from over their head onto the unit. The registered touch is converted to an audio or visually displayed reading.

Making the device cost effective is very important and the circuitry should also be rugged, lightweight, and flexible. The following describes an embodiment that provides these aspects, although it will be appreciated that one or ordinary skill in the art may use variations of this without departing from the teachings of the present invention.

Preferably the device is configured as a cardboard foldable (or similar inexpensive generally non-conductive material) strip upon which is mounted an electronic circuit and a set of contacts that are interconnected to the electronic circuit by way of conductive material attached to or printed on the cardbard material.

To accurately detect position, such as within ¼ inch, along a strip that is about three feet long requires at least 48 contacts points per foot, or a total of 144 points along a three foot span. This number of contacts would be difficult to directly register in view of not only the pin count of the device but the inexpensive wiring along the device.

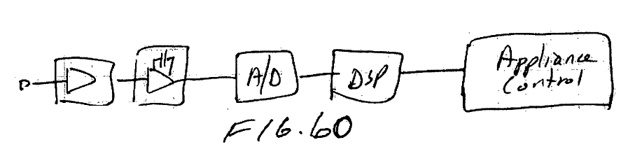

FIG. 52 depicts a position sensor created by using an X-Y matrix of switches, such as membrane switches, connected to the microprocessor. The matrix used need only be a 6-6 matrix, which would conventionally provide only 36 contact points, however, an additional 3 contact points are created across each matrix node.

FIG. 53 depicts one node of the matrix having four different resistance values connected along across the node. The four contact points are distinguished by the series resistance value, for example 10K, 20K, 40K, 80K. The uC can sense the resistance based on the time required for the capacitor to charge. Upon first contact the uC may only register the node (1 or 36) and then it can reset the capacitor on the X and send a pulse on the Y line, wherein the time required to register the signal on the uC is dependent on the RC time constant which is determined by the amount of resistance in association with the contact. If more than one contact is pressed then the parallel resistance combination is sensed and an error signal sent out. Therefore the present strip allows registering the height within ¼ inch using only 12 pins of the microcontroller.

This technique may be varied in a number of ways as to array count and configuration without departing from the invention. The resistors are also preferably screen printed on the strip of material comprising the device while the contacts are glued, or otherwise fastened.

The height may be annunciated one or more of a number of ways. For example, audio output wherein the uC converts the registered height to a series of audio strings such as “3”, “feet”, “4”, “and”, “½”, “inches”, “clapping sounds”. A conventional display, such as LCD, may also be utilized to announce (indicate) the height of the person. An electronic ink display may also be used to show height, and this may be made very inexpensively while being made flexible to conform to the strip and robust.

The unit is preferably powered by a coin cell lithium battery, however, other power sources, such as other batteries, solor, and so forth may be utilized without departing from the invention.

The unit preferably has a push-button on switch and automatically turns off the power if the unit is not used for a period of time.

Additional Aspects:

+Allow same strip for different height ranges. This can be selected by cutting corners or strips of the material which breaks a conductive path as sensed by the unit. For example, cutting the lower foot from a six foot strip allows it to register height from 2′ to 5′, wherein a conductive path routed down to the lower portion of the strip is broken upon cutting so that the unit recognizes what height it is being used for and generates the correct heights.

+Difference measurements—activating a selector, such as pressing a contact button, allows heights to be compared between individuals. The unit should require at least 2 S between registering different heights to allow persons to change position. A comparison value may be selected and all values compared to it. For example after measuring the height of a first person, then press the compare button and all measurements thereafter will note the height and the difference in height with the first person. A reset button can be included to reverse this selection.

+Average of measurements—a button is pressed wherein the uC computes a running average as people's height is measured.

+volume control—a conventional volume control may be used, however, this is an inflexible and costly component. One or more conductive loops may be used are routed through (i.e. conductive traces on the backside of material) printed sections to the processor. IF the default volume level is too high the user can trim these portions to reduce the volume to a more desireable level. (not generally reversible).

Juke Box Shuttle by Audio Qualities

To allow selecting music or videos by referencing the characteristics of the selections. These characteristics may be determined by the system itself or as defined within a database for the audio or video items.

User can select their music choices based on the qualities of the audio stored within a selectable repository, such as juke box, disk drive, MP3 player, and so forth.

The system is preferably configured to characterize each selectable item which may be accessed by the storage system. It will be appreciated that the mode of material is readily discerned, such as CD, MP3 audio, video etc. by examining the formating of the material, wherein the user can select from these choiced. Furthermore the invention utilizes software programming that depending on the format reads portions of the material to determine characteristics such as the amount of action, the extent of lyrics, or voice and so forth. It will be appreciated that using digital signal processing routines, and/or neural processing systems, that a number of characteristics of the data may be readily discerned for use in the present system upon which user selection criterion may be based.

The user may optionally control the settings that discern between different types of material. For example, what one user wants selected when they select a class such as rock will be different from a second user that may consider rock to be pop-rock instead of heavy-metal.

The selection may be used for finding elements of serial content, such as audio or video. For example, the user may want to advance to the next action scene in a movie. It will be appreciated that “action” may be detected in video frames according to the rate at which the picture changes from frame to frame.

A processing element can read the items that are available on the system while the software runs a characterization routine to map information about the material. The mapping may be stored as a set of indexes into the material, which may be predetermined or set by the user. A set of parameters are preferably generated based on the characteristics of the material, wherein these parameters are compared against predetermined, or user set, thresholds according to a plurality of content categories. The mapping itself may be stored as an content addressable index to the material, for example allowing the user to just see action sequences without the need to later scan through the material characterizing it on the fly.

The system preferably allows for reading external characteristization information for the material, which can automatically override the user determined metric at the option of the user.

Aspects of Invention:

+Remote control x-y control allows moving over a “audio qualities” map. As they move across the “map” the qualities may be annunciated, such as through a graphic or text display, or using audio such as verbalized text strings.

For example: An x-y map may be configured with intensity on the Y axis and amount of vocals on the X axis. This would provide a good metric as to the type of music. The user could control the type of music in the similar manner as they control the tone and balance of an audio system.

Claims:

A apparatus for selecting audio or video compositions for play based on the characteristics of the media as described herein.

ECeptor

In our world today the majority of critical information about our environment is received visually. We find the bank, our office, or the bathroom by using visual reception of the surrounding environment. We know what street it is by reading the sign, we stay on the sidewalk because we can see its path. The nature of our environment, with its reliance on visual cues, has left visually handicapped persons trapped in a world with little of the critical environmental information that sighted persons take for granted. Sighted persons may gain a glimmer of this lack of information when visiting a foreign land whose language they can not comprehend. They can still see the roads and sidewalks, but many of signs have no meaning as they are written in a foreign language.

There has been some progress made in designing equipment for the visually handicapped which provides distance feedback of the surrounding environment however no practical system or method has come forth that provides environmental information about the surroundings. Environmental information for instance could tell us what the name of the cross street is, it can lead us to the bathroom of a large office complex, it would tell us what floor we are on and where the office is we are seeking.

As can be seen, therefore, the development of a system and method for communicating indirect information about the surrounding environment would aid the visually handicapped and may be used by others such as visitors to a foreign country to better interpret the surroundings and ease traveling.

The System and Method for Communicating Indirect Information about the Surrounding Environment in accordance with the present invention satisfies that need, as well as others, and overcomes deficiencies in previously known techniques.

The present invention is a system and method for providing information about a person's surroundings. The system comprises an Environmental Receptor Unit (ECeptor unit) and a multitude of Environmental Identification Units (Eidus). The ECeptor unit may be held or otherwise retained by the person seeking the environmental information. The ECeptor unit is an electronic device containing a user interface, an audio output jack (or speaker), an RF transmitter with a narrowly focused transmission pattern, and one or more RF receivers. Each Eidu is a tiny RF transponder encoded with a particular set of environmental information. In large quantities it is anticipated that simple Eidus can be produced for a small fraction of a dollar a piece.

A variety of Eidus can be produced, the simplest using received RF energy “Ping” to generate an RF response “Pong”. Additionally Eidus with more complex functionality and/or longer range may be powered by batteries, solar cells, or provided with power.

An Eidu is coded with environmental information; for instance an Eidu may be coded with “Men's Bathroom”. When struck by the coded RF beam (referred to herein as “a ping”) from an ECeptor, the Eidu having picked up the energy from the beam retransmits at a shifted frequency (referred to herein as “a pong”). The retransmitted signal (pong) contains a digital bit packet that is received by the ECeptor. The ECeptor converts the received information into a form compatible with the user. A visually impaired user would most likely have an Audio ECeptor that converts the digital information into the audio phrase “Men's Bathroom” that would be heard over a small earpiece speaker unit. A person with an ECepto can sweep the beam (a set of Pings) to receive Pongs within his/her surroundings. The person then roughly knows the direction of the Eidu, and its associated environmental feature, by the time relation of the Pong to the direction the ECeptor was pointing during the sweep. The user can then point the ECeptor in that direction and home in on the Pongs to find the environmental feature.

An ECeptor can also be configured with multiple receivers which provide the ECeptor user with additional direction information. As an example, the signal strength from a pair of receivers with narrow reception patterns can be compared and converted to left/right information passed to the ECeptor user. The direction information can be passed as audio, or a modification to the normal output (progressively higher pitched voice annunciation depending on angular position to the left, a normal voice on center, with a progressively lower pitched voice annunciation depending on angular position to the right). The direction information may also be provided on a tactile sensor, wherein a moving ridge or depression corresponds to the angular position of the Eidu in relation to the beam direction. Alternately, for sighted users using a Translate ECeptor a visual indication on the ECeptor can provide direction information.

Various types of Eidus can provide a match to the environmental situation. Preprogrammed Eidus can be provided for common functions, wherein the data is contained in read only memory (ROM) within the Eidu. Programmable Eidus can be loaded with the environmental information to be disseminated. The programmable Eidus can be attached to signage or store fronts so that Eidu users can find the proper business or office within a business complex or a high rise. A simple PC, or even PDA interface allows programming a non-volotile storage area within the Eidu.

Menu Eidus can provide extended menu type information. On receipt of a normal “Ping” the menu Eidu responds with a normal “Pong” response followed by a trailing “*” or an equivalent notation which indicates that the Eidu contains additional information. The user presses another button on the ECeptor which causes it to generate a Ping coded with a menu request code. The “Pong” from the Eidu can contain a non-interactive menu, for example a menu for a men's bathroom may describe the layout in relation to the door. For example: “Two sinks directly to the right, followed by a wall, then two urinals, a small toilet stall, and a handicapped toilet stall”. A large menu may need to be broken up into smaller pieces, wherein the user presses the button sequentially to get the next piece of information. Signals back and forth from ECeptor and Eidu then Ping Pong, back and forth until all desired information has been obtained. A Menu Eidu may also be interactive wherein menu levels are provided to the user. The user responds to select a menu item which direct the menu Eidu to generate the next level of menu or set of information. This form of menuing is similar to a voice message system in operation.

Eidus can also be used for conveying information that changes regularly. Such Eidus would generally be in connection with a computer or other electronic hardware capable of refreshing the data within the Eidu. An example of this would be an arrival schedule at an airport. Again the initial response to a Ping would convey limited information, such as “Arrival Schedule” wherein the user could activate the ECeptor when pointed at the schedule to get the schedule information.

To allow the user to find specific and often needed facilities the ECeptor is configured with additional user inputs, or buttons, that when activated cause the generation of Pings that are encoded so that only certain types of Eidus will respond. One example of this is a bathroom button on the ECeptor. When pressed the ECeptor Ping will elicit responses only from bathroom Eidus. When Pinged for response certain bathroom Eidu units are set to generate a higher power output so that the bathroom may be found from farther away. The ECeptor may be set for the particular person using it, wherein the Ping is encoded to only get responses from “Men's bathrooms” or alternately “Women's bathrooms”. Another example of this coding is the classification of Eidu Pongs in relation to the service rendored or danger being signaled.

It must be recognized the the ECeptor can be configured for various users with a variety of needs, and that the Eidus can be provided to yield various environmental information from a variety of sources. In t should also be recognized that the ECeptor device can be incorporated into other devices, such as canes and electronic distance sensing canes. The described system and method for communicating indirect information about the surrounding environment provides a number of advantages.

Light Energized Eidu:

To increase the selectivity of Eidus, for instance if many are available, the Eidu may be configured with a photoresponsive material layer, photocell, or similar element. These materials are described elsewhere within the present invention. In response to a predetermined change in lighting the Eidu generates an RF signal (or alternatively an infrared signal) containing the information for the user. The power generated from a solar cell may even be used to charge a capacitor that provides power for the Eidu wherein no external power is required. It will be appreciated that this photogenerative material may be manufactured with the Eido in a number of ways, such as the use of Heterolamellar photoelectrochemical films and devices as described in U.S. Pat. No. 5,695,890 to Thompson et al. issued Dec. 9, 1997, which is included herein by reference. Other forms of photoresponsive material may be alternatively utilized. The eceptor may be configured with an LED or laser light source for triggering the Eido into action.

The Eido is optionally configured to detect patterns within the received light, for example a predetermined preamble to distinguish optical noise from signals, followed by an indentifier, and optional parametric information. The Eido may then respond to the optical energy received by generating a transmission (e.g. RF or infrared) that is directed toward the given user. The Eido may alter the frequency of the output for a given user, but preferably it just encodes an ID response back so that only the transmitting unit will respond to the data received. This allows the use of Eidos in a crowded environment with many users. The user may also communicate to the Eido a parameter, such as the type or extent of information desired.

It is contemplated that a very inexpensive polymeric Eido may be produced that incorporates a heterolamellar surface layer that provides charging power to an embedded capacitor, wherein upon receiving sufficient light the Eido is triggered into an ON state (optionally registering data within the impinging light beam) wherein data may be communicated back to the user.

26. Visually Cueing Individuals to Destinations

Providing Visual Directions within Environment to Lead Particular Individuals to a Destination. A system and method for providing recognition and physical direction

To generate directions that lead an individual which is moving as a pedestrian, pushing a cart, controlling a vehicle, or using other means of conveyance toward a destination.

The present system utilizes a network of distributed displays and detectors connected to a computer system to sense the position of specific individuals, or conveyances, and to guide them incrementally through one or more destinations, and/or tasks.

The location of the individual may be readily detected by imaging systems, communication means, changes in position from a known location (i.e. nonspecific location sensors, such as pressure sensing, or optical sensing with movement information tracked so that unique identity is maintained), and so forth.

Two preferred methods are imaging systems that collect images from which image recognition algorithms extract information as to the identity of the individuals and their location in the store, and communication devices, such as RFID transponder devices.

The indicators may be provided on a number of surfaces, such as programmable signs, the floor, the ceiling, the walls, and so forth, in the surroundings of the individual. These may be formed with any display technology, such as LED lights, LCD displays, laser projected signs, and so forth, however, the use of electronic ink panels is generally preferred within many applications of the present invention for its low cost, robust structure, negligible static power consumption, and ease of fabricating large displays.

The display should indicate which person is being directed as a number of individuals may be at the same location awaiting continued direction information, therefore, any form of text, or recognizable colors, symbols, icons, and so forth may be used to represent different individuals. The use of a graphic display allows a number of different elements to be created for display. For example, the initials of the individual may be used for indicating that the direction is intended for them and not another party, similarly a selected icon—such as playing pieces found in the game of Monopoly® {top hat, shoe, dog, battleship, thimble, etc.} may be chosen for the user, or be user selected. The selection of individual may be according to color coding of the display elements. One method of readily achieving this is by providing a series of parallel movement indicators along the display (such as mounted to a floor) in different colors, wherein each user follows a specific color, which may be further refined with a different displayed elements.

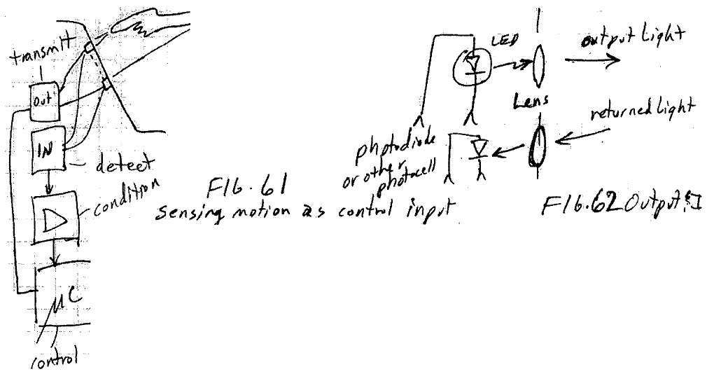

FIG. 54 depicts an electronic ink label strip, such as for placement along the edges of the aisles within a grocery store. Three different forms of arrow are shown, chevron, star, and arrow, each having two additional indicators. Using this simple iconic patterns at least 24 persons could be uniquely provided with direction indications. The use of three stripes of different colors ups that number to over 72. Furthermore it will be appreciated that elements on one colored strip may be shown with elements on another strip, wherein the number of combinations rises rapidly. Different “colors” of electronic ink (different combinations of the colors within the ink e.g. black&white, red&white, blue&white, black&yellow, red&yellow, blue&yellow, and so forth) may be applied to different stripes or to different elements along the same strip. Therefore, it will be appreciated that the display elements may be adapted to provide unique directions for each individual according to the next destination.

For example, in a grocery store the user could be led through the store following strips of elnk on the sides of the isles which point in the direction of the destination, such as for retrieving a particular article. The destinations may be selected based on a “manifest” that is provided to the computer, such as in the form of a shopping list selected on-line, or uploaded from a user controlled device, such as PDA, to the computer system of the establishment. The computer then determines the locations of each items and plots a least resistance path for user to collect each item. The user just follows the path, and when the destination is reached the elnk points up to the shelf and may display additional information such as shelf number, product name and so forth. After picking the product the individual is then led to their next destination and so forth.

It will be appreciated that this system is also applicable to moving items in a warehouse, or the stocking of shelves, wherein an individual, or operator of a conveyance, such as a forklift, is directed to the correct locations based on the manifest. The directions for what is to be performed at each location may be communicated to the user via the mounted indicators, or a combination of indicators and other annunciators associated with the individual, such as an audio message played over an earpiece to the individual.

FIG. 55 exemplifies a system with a computer to which a network of position detectors and a display strip, and/or multiple displays are connected. The detectors are connected over a network, such as a conventional IP network, however, an embedded system bus similar to CAN, I²C, or other non-layered protocol bus can execute the simple control necessary with less overhead and at significantly less cost per node. A series of transceivers are positioned at intervals along the paths within an area being controlled. Although any form of device for registering the position of the individuals may be utilized, such as cameras and varius forms of sensing and communication, the figured depicts a transceiver configured to send challenges to passive RFID devices, such as on a card held by an individual, connected within a tag on a cart, on a vehicle or tag for a vehicle, or connected in some other manner to an individual being given directions. The challenge is preferably in the form of either an RF transmission, or magnetic signal, either of which needs to be received with a sufficient intensity to trigger the RFID. Often RFID systems utilize an RFID tag with an inductive loop that generates power to the RFID upon receiving sufficient mag flux, wherein a capacitor is charge to power an RF or magnetic response to the challenge. In the present system the response includes an identifier for the particular unit any may include any additional information desired. The response to the challenge lets nearby detectors register the position of that RFID. Preferably, the transceivers also detect the signal intensity which should be passed along with the identifier to the computer which can relate the absolute intensity of the signal at a particular detector and the relative signal intensity in relation to what has been received by other units. The computer can then determine the position of the individual in relation to the detectors; all things being equal an equal signal level from two sequential detectors would indicate the user is midway between the detectors. However, it will be appreciated that the orientation of the RFID relative to obstructions, such as the individual or conveyance, can complicate the determination of position, wherein the computer can take in historical information in relation to how the signals were effected as the user passed other sensors and so forth, to render a more accurrate aproximation of location. The computer then erases old segment markings and activates new segments sufficiently in front of the user to mark their way toward the destination. Once the destination is reached then a different form of direction signal is indicated toward he location on the shelf where the item may be found.

The system is shown with a few options, such as a camera for registering user image for use with camera based detectors, and a user interface for communicating with the user. A paper based scanner is also shown wherein a user (generally who has has an identity on the system and a card or other identifier which may be registered by the system) can insert a paper shopping list with items marked for purchase and for which they want quik-path routing information through the store as they shop. Additionally, detectors are shown which are wireless in hard to reach locations. A display controller is shown for controlling the display, or a collection of displays, and it will be appreciated that mixed display technologies may be utilized. Furthermore, a microphone is connected to a node of the network with a push to talk (PTT) button, wherein a patron may ask where a particular item in the store is to be found, and the system will use speech to text conversion and then parse the query and give a verbal response and can at the users discretion lead then to the location of the desired item using the distributed display.

It should be appreciated that active RFID systems may be utilized, however, as these rely on batteries, solar cells, or the like they are more costly. Furthermore, as mentioned previously other forms of detection may be utilized that provide identification of the individual. In some applications, the number of individuals may be only one or their use temporally or spatially displaced wherein the system may only need to register the presence of the individual. This scenario is similar to that described in the relation description herein entitled “RFID Controlled Lighting”.

Additional Aspects:

+Shopper card carried by patrons having an RFID tag that is sensed by tranceivers within the grocery store. Using a kiosk, or other form of interface, the user can elect to shop according to their latest recorded shopping list. The system then can direct them according to their shopping list. The user position is readily recognized without the need for a complex sign in process.

+Shopping lists are also supported on the present system. The user may print out a preselected, or custom selected, shopping list from a web site, or pick up a blank shopping list form from the grocery store. Alternatively, the grocery store can use information gathered about purchases by the consumer to automatically generate a shopping list, which can be sent to the patrons, such as part of a promotional literature sent out. The list indicates items and has a checkbox area for indicating number, along with any sizing or other selection criterion. These lists can be inserted into a scanning device as the patron enters the store, wherein their list is scanned into the computer and associated in some manner with the individual (by image, RF tag, shopping cart RF tag, and so forth), wherein the user is shown an identifier, (or a card with the identifier is printed out for them), and they may proceed to shop following the indicators along a least resistance routing algorithm based on path length and optionally congestion and other factors affecting the time and effort of the patron in moving through the store.

+Data mining—It should be readily appreciated that a huge amount of data can be collected about the likes and dislikes of the patrons, which may be utilized to aid the store in directing more meaningful coupons, specials, and so forth to the patron.

+Camera may be additionally configured to evaluate actions of individuals for detecting if help is needed, such as falls, breakage, shoplifting, opening of packaging, fighting, and so forth. In this way the system generates automated alerts to store personnel as to location and possible problem to affects a remedy.

27. BoilMinder

Sense the state of items being cooked on a stovetop and control the action of the appliance accordingly. For example, the stove heat may be reduced if a liquid is nearing the point of boiling over.

The BOILMINDER stove senses the state of the items cooking in the pans, pots and such. It senses the amount the pot {i.e. food receptacle such as pots, pans, grills, dutch ovens, and so forth) placed on the burner is boiling, and/or the burning of the items being heated therein, and can adjust the power output to prevent boilover or to hold a certain level of simmering.

A number of embodiments exist for the present invention, the following are the preferred methods at this time.

Acoustical Sensing.

An acoustical transducer is utilized for sensing the state of the food within the pot or pan on the stove. The acoustical transducer may comprise audio transducers, vibration sensors, and similar sensors that are responsive to vibrations such as of the boiling of liquids, and/or the sizzling or similar vibrations that may be in the audio spectrum in response to food being heated.

The acoustical signature of boiling, or “sizzling” such as in a skillet or similar that is being sauteed or is burning, is detected and the output of the stove is modulated accordingly.

One preferred acoustical transducer is a directional microphone that is directed to pick up the activity occurring within the on stove food receptacle, such as the pot or pan. The microphone may be attached to a position on a range hood, a high portion of the stove, or a similarly elevated portion of the stove, wherein the microphone can selectively discern the sounds emanating from a particular food receptacle.

Alternatively, the microphone may be attached to a cook top surface and adapted for picking up sounds relating to a particular burner. For example, a number of microphones may be utilized disbursed at selected locations on the cooktop wherein the congruence or difference signal between the microphones is utilized to discern individual burner elements.

The cooking receptacles may be adapted for redirecting acoustical energy in combination with the invention, to increase accuracy. For example, a lid may be configured for redirecting sounds arising from the food in the cooking receptacle from the interior of the lid and out through one or more openings to the acoustic sensors, which for example may be positioned on or about the cooking surface.

Alternatively, the microphone may be incorporated as an acoustical transducer within a module that is floating or otherwise retained in or on the perimeter of a cooking pot, and which communicates the audio information to a processing element for discerning the condition of the food associated with a particular burner, so that the burner intensity may be properly modulated. The communication may be performed, such as using as RF communication link between the module having the microphone and the stovetop.

Pressure Sensing/(Accelerometers)

The high frequency pressure fluctuations of the food receptacle on a burner surface is registered by a pressure or acceleration sensor and processed, such as by a digital signal processor, neural network, or similar element, and correlated with the state of the food being heated within the food receptacle. The term pressure sensing will be referred to herein to refer the use of a pressure transducer or an acceleration sensor, which may provide similar heated food state registration. For example, the pressure fluctuations associated with boiling of a liquid within the receptacle may be registered, wherein the signal processor can determine the state of the food being heated, such as rate of boiler {simmer, medium boil, full boil, nearing boilover point}, or in foods being fried, sauteed, and so forth wherein limited liquid or oils are present the signal processor can determine the state of the food being heated {e.g. slow saute, medium saute, fast saute, medium frying, fast frying, scorching, burning, and so forth}.

It will be appreciated that while boiling, sauteeing, or frying foods, minor pressure fluctations arise as bubbles are formed and which pop. The intensity of the bubble formation and popping can be mapped into a state for the given food item being cooked.

Pressure sensors may be placed so as to be mechanically coupled to the cook surface, wherein pressure fluctations within the food receptacle are transmitted through the receptacle and cook surface to the pressure sensor. Preferable multiple pressure sensors are located about one or more elements to increase correlation accuracy. The pressure sensors may located on the mounting legs of burner elements, or otherwise positioned to register the pressure variations/vibrations therein.

Similar to the above, that signals from the pressure sensors are received by a signal processing element which correlates the pressure information into food cooking state information which is then processed in relation to the desired cooking state as specified by the user and the heat output of the heating element modulated to maintain a desired level (saute, slow boil, fast boil, etc.) or prevent an undesired outcome (scorching, burning, boiling over, etc.).

Pressure Sensing in Combination with Acoustical

The above pressure sensing and acoustical sensing may be utilized in combination, to obtain greater accuracy.

Infrared Sensing:

An infrared sensor/remote thermometer may be utilized in combination with signal processing elements and controller for obtaining heat information about one or more receptacles on the cook surface. Preferably, the infrared sensor or remote thermometer is utilized in combination with one or more of the above sensing mechanisms to improve the correlation of the state of food being heated in relation to the desires of the user.

It will be appreciated that when a sufficient quantity of liquid, such as water or frying oil, is lost from a pan the process of burning may increase readily—as the evaporation or waters or oils no longer cools the pan and stabilizes the temp. As the water boils off the pan begins to heat quickly. If a passive infra-red sensor is utilized, such as receiving a collimated beam from a specific region of the stove top, such as received through a tube aimed at one or more heights corresponding to pan height, then the temp profile of the pan could be measured which would allow the controller to determine roughly when the pan was burning.

Reflection Sensing:

Optical energy may be directed into a open food heating receptacle on a stovetop, or other heating surface, wherein the reflected light energy is registered to detect the state of the food being heated. For example, light reflected from water prior to reaching the boiling point is generally a static reflection intensity signal, wherein as the water progressively reaches greater boiling intensity, the reflections become increasingly modulated according the rate and size of bubbles bursting at the surface. Preferably, the signal processing element is conditioned to disregard periodic user interaction, for example stirring, and it will be appreciated that signal discontinuties associated with stirring and other interaction are indicative of same.

Chemical Sensing:

Additionally/alternatively chemical sensors may be connected to a digital signal processing element for discerning the state of the foods being heated. The fumes from the cooked article may be directed to the chemical sensor, such as located within a range hood, or other location, wherein the chemical composition is checked for chemical signs associated with providing the proper heating profile, or an incorrect heating profile. It will be appreciated that common chemical reactions are associated with foods that are burning and that these may be sensed within the chemical sensor and communicated to the monitoring unit.

For example, when food that is being sauteed begins “burning” there is a chemical signature containing charcoal like carbon based residues, and similar indicators. Upon detection of these by the system, the system can sound alerts, and/or modulate the heat output of the unit to prevent further burning. Although, with the use of a sophisticated chemical sensor the type of food being cooked may be discerned and so an accurate estimation of the chemical signature when being burned is obtainable. However, it is contemplated that a user control may be included within the controller for registering user input as to the type of food being heated, so that simple chemical element sensing may be utilized.

Smoke Detection:

Food that is burning is accompanied by an increase in smoke output. A smoke sensor may be utilized separately, or in combination with the chemical sensing and other forms of sensors described to determine the state of the foods being heated. The smoke sensor may positioned within the range hood, or similar location in which smoke could be detected. The smoke detection, as with the chemical detection, may be provided within a separate system, such as the range hood, which communicates to the heating element control system for modulating the output of the heating elements, and/or generating warnings and other similar indications.

Sensor Communication:

Any of the above may be configured as wired or wireless devices. A wireless device may be adapted with its own power source, a separate source, or configured to draw response energy from a signal being received (i.e. passive RFID) such as inductive, or RF.

For example, a wireless transponder may be implemented within a “floater” module that may contain sensing electronics, such as acoustic transducer and/or pressure sensor, and any related sensors such as thermometers, that communicates with a remote receiver for registering the sensor signal and communicating it to a signal processing element.

Advantages:

Keeps stoves cleaner.

Keeps from overcooking food.

Safer, we may forget to turn it off, but the stove won't.

Can provide simmer functions so that less supervision needed.

Can be used with any type of pan.

Can be implemented on gas and electric stoves.

Uncomplicated for any user

28. NonContact Kitch n Controls

Controlling stoves, ovens, and so forth requires contact with dials, buttons and so forth. However, the hands of a cook are often covered with portions of their creations, for instance flour or dough, and it is very messy to be touching the controls.

The present invention provides a method and system by which the user can control aspects of a stove, or other appliance without the need to touch any controls.

Stove and oven control, as well as other appliances, may be facilitated without the current necessity of interacting with physical controls, which can lead to messes if the hands of the individual are wet, covered in foodstuffs, and so forth.

The present invention provides for motion sensing control of a stove or oven, and less preferably voice sensitive control.

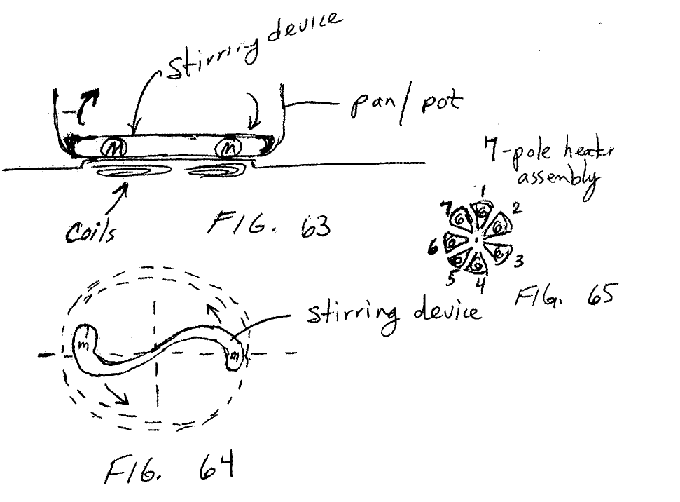

FIG. 61 and FIG. 62 illustrate a motion sensing device incorporated within the stove/oven controls that senses the position and movement of the user, such as their hands, wherein the operation of the device is changed to respond thereto. The user can move according to a preselected pattern to control the actions of the stove/oven. FIG. 61 depicts an optical transmitter and receiver for detecting motions for controlling the stove, these signals are conditioned and processed by the microcontroller. FIG. 62 illustrates a detail voew of an LED transmitter and receiver for registering user control of the devices. For example subscribing a clockwise circle causes the set heat setting or temperature to increase, while a subscribing a counterclockwise direction causes the temperature or heat setting to decrease. Similar the unit may be activated by the detection of an upward movement, and deactivated by sensing a downward movement. It will be appreciated that the positioning of the users hands, feet or other body part may be sensed according to any desired pattern. The movements may be sensed by using CCDs, photo element arrays, or single photoresponsive elements adapted to sense the movement at the proper distance and location in relation to the cook top.

A voice activated control unit may be utilized in concert with an activation and deactivation control, and less preferably by an unusual keyword that would not find its way into normal conversation. The unit preferably validates all commands by outputting what command has been heard and requiring the user to verify the action, such as by saying “Yes” or “No”.

To assure that the unit does not respond inappropriately to voice commands, such as responding to sounds while the user is not cooking, or otherwise not in a position to give voice commands, the unit preferably allows for engaging and disengaging voice command control using a mechanical input, or sensed input. For example the voice capability may be activated by pressing a button on the console, wherein the voice control preferably remains active (as preferably indicated by a light or other indicator) for a predetermined period of time (i.e. one hour). Alternately other controls may be utilized for activating and deactivating the voice commands, such as foot controls, and motion sensing devices.

The voice command may be configured to operate in response to the setting of the power/temperature control knob. For instance the voice control aspects may be deactivated unless at least one burner or oven has been switched on.

In addition, the voice control may be configured to ignore “commands” unless an individual is sensed as being located at a particular location (i.e. proximal to the device) or other specific criterion. For example an inductive, or optical sensor can detect if individuals are nearby. These precautions can provide a safety that voice commands will not be inadvertantly executed by the cooking unit which could cause food to burn, or for the stove/oven to be operated when not directed by the user.

29. Stovetop Automatic Stirring

To allow for automatic stirring of the contents within a food heating receptacle, such as pot or pan used on the stovetop.

A set of magnetic coils are incorporated within a heating surface element, and whose field output is modulated to control the movement of a stirring element retained within a food receptacle.

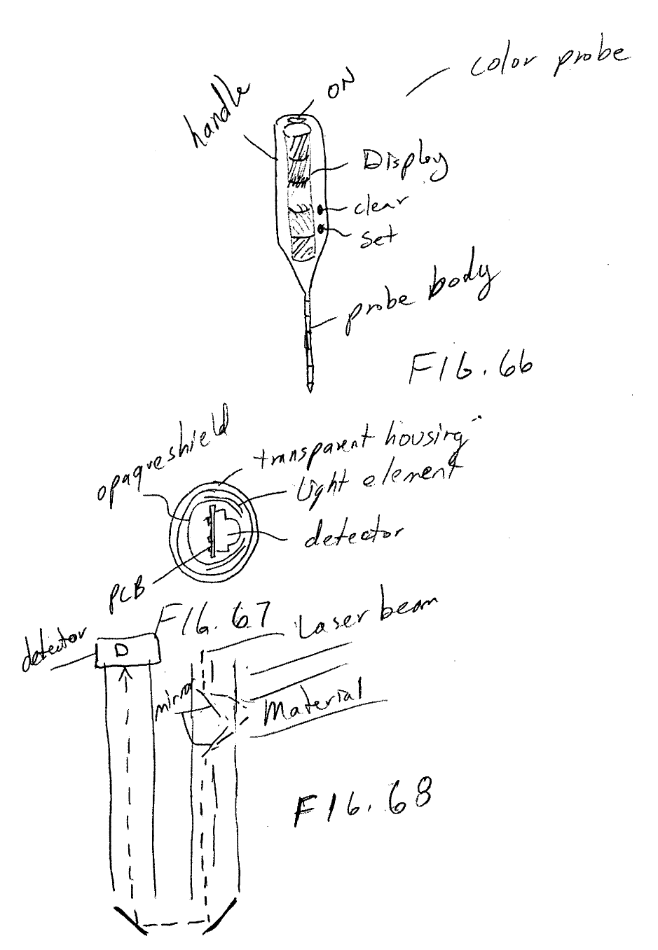

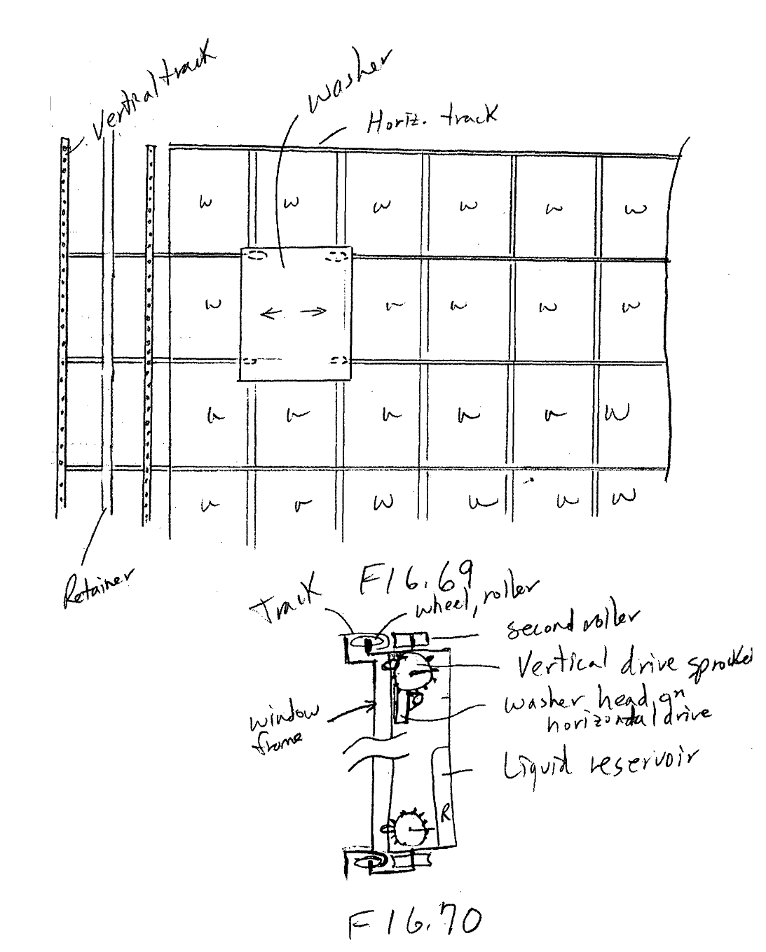

FIG. 63 is shown by way of example wherein the heating element itself comprises a plurality of coils that generates both heat and magnetic output. The stove controller may modulate the intensity, and speed of output from the coils to control both the heat output and the power coupled to a stirring element. A simple stirring element may be produced from a magnetic material having two polar ends which is configured to rotate within a given food receptacle being heated, as shown in FIG. 64, a top view of the heating element by itself is shown in FIG. 65. It will be appreciated that the food heating receptacle should preferably comprise non-ferrous materials so as not to disburse the magnetic fields being generated.

The stirring element may perform simple stirring or be used in a similar manner to a spatula for shifting or turning non-liquid foods. The food receptacle (pan/pot) may be configured for retaining the stirring element to allow for movement, such as a central pivot upon which the stirring element pivots when stirring or scraping the material from the bottom of the receptacle.

The stirring element is preferable configured to span a significant portion of the food receptacle, (such as radially, or diametrically) so that the food ingredients, which are typically significantly more viscous than water or similar liquids that do not contain foodstuffs.

30. Sensor Cooking Probes

Included by reference, patent application entitled “A System and Methods of Maintaining Consumer Privacy During Electronic Transactions” Ser. No. 10/066,495 filed Feb. 2, 2002 and provisional application entitled “Display Systems and Methods Utilizing Electronic Ink” serial No. 60/267,115 filed Feb. 7, 2001, and the “elnk display”, “USLED”, and “OFXHD” technologies described elsewhere herein.

To allow the monitoring the interior of items being cooked, without the need to cut into them and attempt to see what is going on. The device allows for viewing color along a given span, or other transitions such as temperature, or moisture, changes along the span. The device is particularly well suited for registering color transitions along the length of the probe as inserted within meats which are being grilled, or otherwise prepared.

A probe having a very fine probe end for insertion within items being cooked to register their color, and optionally/alternatively additional metrics about the item.

FIG. 66 depicts a simple color probe having a handle with a display. A probe extends from the handle for being inserted into something, in particular a food items whose interior color is to be checked. The circuit may be configured to provide continuous display of the color being read when the unit is being powered. An optional set and clear button can allow readings to be held by pressing set and cleared thereafter by pressing clear. Preferably the circular cross-section of the probe is from approximately 1/16″ diameter to 5/16″ diameter.

The unit generates a light source from the exterior of the probe tip and registers the reflected intensity and wavelength (color) of the reflected light. The registered colors are then displayed on the color display. It will be appreciated that a lower cost display may be utilized if the colors are limited, such as a read meat tester may only need to display shades of red, and gray/brown respectively, wherein an electronic ink display may be created with either different activation thresholds of the colors, and the use of varying electrode spacing to control the intensity. (These being described elsewhere in this discussion of electronic ink enhancements within this patent document.)

It will be appreciated that a number of ways exist for registering the the color and shade of the material surrounding the probe. The following describes two economical methods, although many others could be alternatively utilized without departing from the teachings of the present invention.

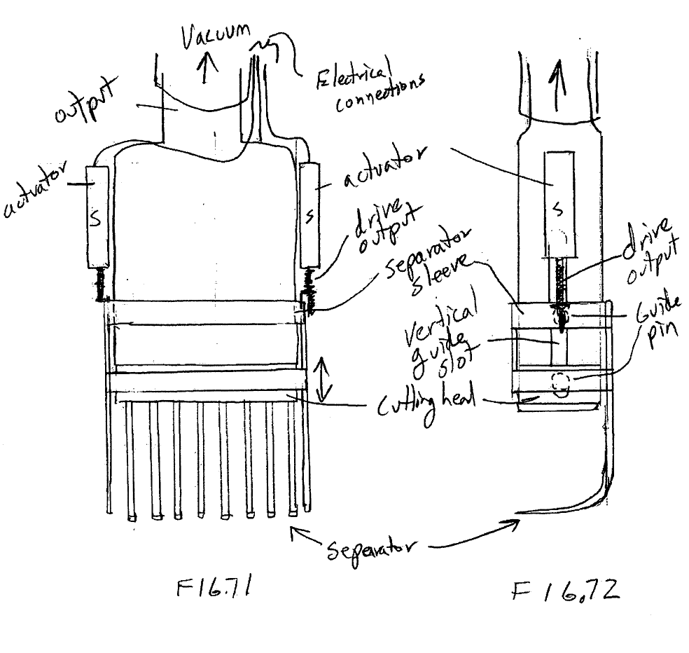

FIG. 67 depicts a cross section of a probe having a small circuit board (or similar material containing traces) to which are mounted small surface mount detectors. A light blocking (opaque) partial cylinder surrounds the detectors with a small slit through which light may be received by the detector. The light is generated by plates or a tube surrounding the opaque portion, and a protective transparent tube surrounds the entire probe. The light may be generated by the user of electroluminescent materials in strips along the interior of the device, utilizing light pipe techniques wherein a light generated in the handle is directed along the exterior which is adapted to allow quantities of light to escape in the desired direction per unit of length. The detectors may be sequentially read from a controller, such as using an I²C type bus, or a D-FF chain or other mechanism for muxing the data from each detector onto the bus. These may be connected using Universal Synchronous/Sequential LED techniques as described elsewherein herein with the USLED applications being included by reference.

The controller interprets the readings from the detectors as to color and display the readings on the display. The display is shown with markings along its length which correspond with those on the exterior of the probe, so that the display may be correlated thereto.

FIG. 68 is a side view of another technique for registering the color along the length of the probe and only requires the use of a single white light laser source and a single detector. An optical addressing channel is formed, a light pipe with embedded MEMs mirrors. The linear mirror array may be individually activated by the controller. Shown are the use of tri-state mirrors, with white laser light being reflected off a first mirror set to state 1, while the next mirror is set to state 2, for directing the optical reflections from the mirror toward the end of the light pipe wherein they are directed by mirrors, or a curving fiber, up to a detector. This embodiment allows all the active electronics, except the MEMs OAC to be contained with the handle device.

It will be appreciated that the above may also be practiced using a single mirror to direct the light and direct the reflections. It will be noted that the mirror reflecting the light will also be picking up reflections which are directed back toward the light source. The detector can easily be configured to register the light passing only in the direction of the reflection. The detector is preferably a full color detector, although it may comprise a series of detector elements, such as R, G, B, wherein the color is registered as a combination of the colors. The controller thus sequences down the mirrors, generates the light momentarily, registers the color from the detector, and then continues the process with the next mirror and so forth. The colors and intensity are then displayed on the unit, such as on the handle as shown.

It will be appreciated that the present device may be utilized in a number of situations in which the color of an item is to be registered.

Furthermore, the mechanism of FIG. 67 may be enhanced by the addition of other forms of sensors, such as temperature, humidity and so forth, wherein a profile of changes can be detected by the probe without the need to otherwise dig into the item.

31. Quiet Sprinkler System

To reduce the noise output of sprinkler systems. Sprinklers under the present invention are activated in a multistage process, the line is first filled at a low flow rate/pressure, and then the full flow/pressure is introduced to drive sprinkler output conventionally.

The system may be implemented in a number of alternative ways according to the present invention.

Controller/valve—The sprinkler controller may configured to output two (or more) different signals to a valve unit that responds to these outputs by establishing flow rates or pressures. For example, a voltage output of a first polarity may signal the valve to enter a low pressure (low flow) mode in which the amount of flow being output is restricted. After the line has filled, such as after a prescribed time (or user selected time) has elapsed, the controller then reverses the voltage which is responded to by the valve by switching to a full output mode. It should be appreciated that the multi flow control may be controlled using any convenient signals on separate control lines or superimposed on a conventional pair of signal wires.

The switch from low flow to high flow may be in response to an elapsed time, or in response to a pressure buildup in the line which will occur automatically as air is displaced with water and that water being flowing from the sprinkler head. Thereby the pressure may be sensed in the line for determining when to switch from low to high flow.

Valve—the valve itself may incorporate a two stage mode and provide its own timing, or pressure sensing. The valve upon receiving an activation voltage may activate a first flow valve and then after a period of time or a pressure buildup activate a second flow valve, or open the first flow valve.

Aspects of Invention:

+Automatically sensing sprinkler line breakages, loss of sprinkler heads, and other situations which can lead to excessive water waste. Incorporating a pressure sensor within the lines allows the units to automatically sense line breakages, missing sprinkler heads and so forth; wherein water flow output may be stopped and the condition preferably signaled, such as a visual or audio indicator. When line decreases below a predetermined value, or a value in relation in nominal pressure setting which is sustained and not a pressure transient on the line, then the valve closes and prevents water loss. The unit may preferably attempt to reestablish the flow and test if the same loss of pressure is exhibited.

32. Automated Window Washer

Provide for the autonomous cleaning of windows within multi-story buildings. The present system allows windows to be easily cleaned within a high-rise building. The unit comprises a drive mechanism capable of traversing a track arrangment on the building, a washing assembly, a position sensor, a controller, and a power source. The unit traverses the track to position itself on another window, or window section to be cleaned, wherein the washer assembly sprays cleaners and preferably uses mechanical operated sponges, squeegees, and the like to remove dirt and the water film from the window. Preferably the washer optically determines the tough spots to clean, using the camera coupled to image processing software, then it sprays a cleaner on the window and deploys a wiping device, such as sponge which is used to displace dirt on the window, and may be directed to spend extra time, or extra passes, cleaning locations where a tough spot was located. The window is then preferably sprayed again and then squeegeed to remove the liquid. The robo washer then moves to another window section.

The tracks may be layed out in a number of configurations depending on the application. Following are a few examples provided by way of example:

Grid of both vertical and horizontal tracks, wherein device can move vertically or horizontally to position it self on a window.

Horizontal tracks with limited vertical paths, such as at a corner wherein the device can transition from one floor to another.

vertical tracks with limited horizontal pathways, such as at ground level for transitioning to another vertical path.

The optimum orientation of the tracks will depend on the design of the building, as the tracks layout may be constrained.

A separate robotic washer unit may be deployed for each section of the building, or a single washer may be moved manually from one section to another after lowering it to the lowest floor.

A single robotic washer is not necessary for each section, if a traversal route is provided at least on one floor, so that the washer can move from one section to another. One interesting design is to architect the building with rounded corners (glass may still be in flat sections within the curve), wherein the robotic washer is able to traverse the periphery of the entire building and can wash the windows floor by floor. Preferably a section is eastablished for the unit to safely traverse vertically between floors.

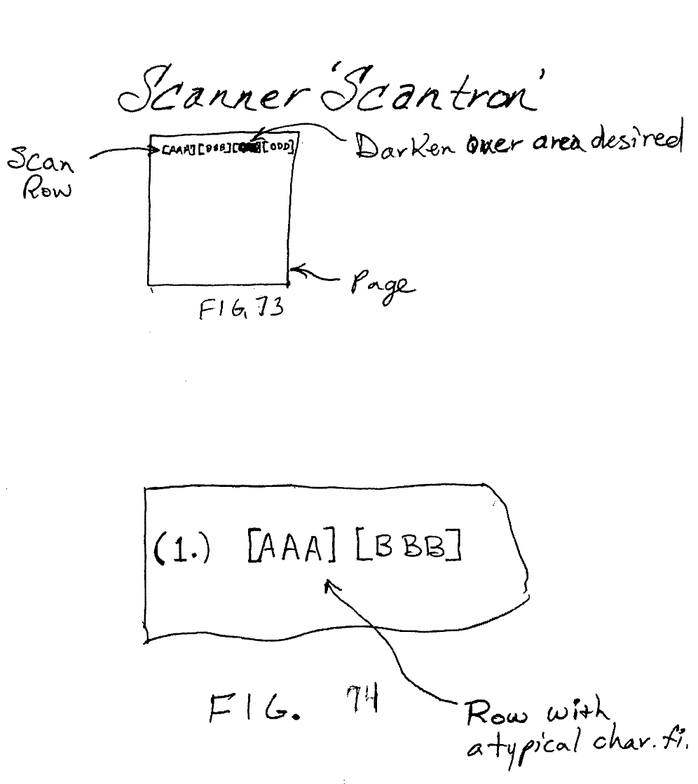

FIG. 69 illustrates a grid of windows on a high rise with a set of horizontal tracks between each window. Once engaged over the windows the robowasher, in this particular embodiment, is limited to traversing the windows in a horizontal direction which limits the hazards from vertical movement. To ascend or descend the unit moves to the far left away from the windows and rolls over and engages a vertical track wherein sprocket wheels are deployed and with the window section not obstructing removal of the horizontal drive rollers the rollers are disengaged and the unit vertically traverses the track.

FIG. 70 depicts a cross section view of a robo washer device showing the rollers engaging the track with a second set of roller opposing the first to provide securement, while the drive sprockets are visible for driving the vertical direction. It will be appreciated that the track arrangment curves downwardly and remains close to the window wherein it does not provide a ledge or a location wherein debris will be caught. Furthermore, the invention preferably provides for locking in at least one set of wheels while over the window, so that under no circumstances may be unit disengage from the window and thereby pose a hazard to persons within the windows or underneath the unit. It is seen in the diagram how the exterior of the window frame locks in the upper round drive roller—it cannot disengage until the unit traverses to the vertical track section. The vertical section may be accompanied with a retainer, or vertical enclosure wherein unit movement is constrained for safety purposes, along the vertical direction which may be

Additional Aspects:

Communication unit—the system preferably includes a communication unit wherein it may communicate its position and status information to a remote location, such as to maintenance employees for tracking the progress of cleaning.

Camera—the robowasher system is preferably equipped with a camera for communicating images of the washing process back to the remote location. This allows maintenance personnel to assure that the unit is doing a proper job of cleaning the glass.

Lighting—a lighting apparatus is preferably attached to said robowasher to enhance the detection of “spots” on the window, so that proper cleaning may be accomplished.

Image processing software—image processing software is preferably included within the system for processing images from the camera of the window sections. The image processing software utilizes digital signal processing techniques, neural net processing, or the like, for detecting locations of the window where dirt still remains. The washer assembly is then directed to attempt to clean the spots found.

Spot cleaning head—an optional spot cleaning head may be deployed, preferably on an articulated arm, for rubbing areas upon which a spot has been detected, so that a small spot may be cleaned without the need to clean the entire window section.

Obstruction sensor—the system prefererably utilizes sensors to detect any obstructions along it travel path, wherein it will generate an alert on said communication unit as to the obstruction. The robotic washer may then take alternate routing or perform other cleaning functions, or wait until new commands are received.

Track groove cleaner and sensor—the system preferably includes a track groove cleaner for dislodging light debris from the track and a sensor for determining if obstructions still remain in said track, or if voids exist in the track system. Therefore the robot washer cleans its own track during use and is prevented from traversing a section of track that is unsafe sensing if obstruction exist along the track. The groove cleaner may simply comprise a rotating bottle brush type mechanism, or other means of brushing or pushing off debris from the track. The sensor is preferably an optical sensor directed along the path of said track and senses reflections from obstructions along the path. The sensing of track continuity may be performed optically, or using a mechanical probe that extends along a section of the path and is deflected upon encountering voids in the track, or obstructions.

Sealing between window sections—to reduce overspray onto sections already cleaned the unit is optionally adapted with a seal, such as a rubber strip, that seals against the horizontal or vertical sill of a window so that overspray between sections does not occur.

33. Automatic Hair Cutting Device

To simplify the correct cutting of hair with minimal effort and expertise. The cutting head unit provides the ability to adjust the length of hair during the cut without removing the cutting head from the head of the “cuttee” (person who's hair is being cut). The cutting head is configured with a vacuum, as in commerically available hair cutting devices, such as marketed as the “Flo-Bee”. The air of the cuttee is therefore first drawn up through the separator and cutting blades, wherein the length of the remaining hair is determined by the length of the separator element utilized. The present invention allows the cutter to adjust the length of the cut without removing the cutting head from the head of the cuttee. Furthermore, additional embodiments are described which allow the unit to perform cuts that follow a predetermined transition pattern, so that the cuttee can be given a professional looking cut instead of a cut having each region with a fixed cut length which look rather odd. Two principle categories of embodiments are described.

A simple embodiment is described which allows for manual control of the cutting head height by the person operating the cutting head (the cuttee or another individual).

A more advanced embodiment is described wherein the length of the cut is modulated in response to the detected cutting head position and a predetermined hairstyle selected by the user and programmed into the cutting head.

A cutting head unit having a blade, in configured with a separator element whose distance in front of the cutting head can be adjusted without removing the cutting head from the head of the cuttee. The separator may be conigured in a number of styles, such as appearing similar to a comb, or otherwise structured to remain in contact with the surface of the head to wherein the distance between the separator and the cutting blades determines the length of the remaining hair at that location on the scalp.

Separator position may be manually adjusted using a mechanical assembly that converts user input motion into a modulation of the relative position of the separator, such as a trigger, or lever mechanism coupled to a slot mounted separator. Alternatively, the separator may be driven by an actuator, such as electric, pneumatic, windup, and so forth, in response to user control inputs. Driving the separator from using an actuator, such as a solenoid, or similar electric or other form of actuator can allow the user input for controlling the actuator to be more user friendly, since any user actions can be sensed and translated to separator position control.

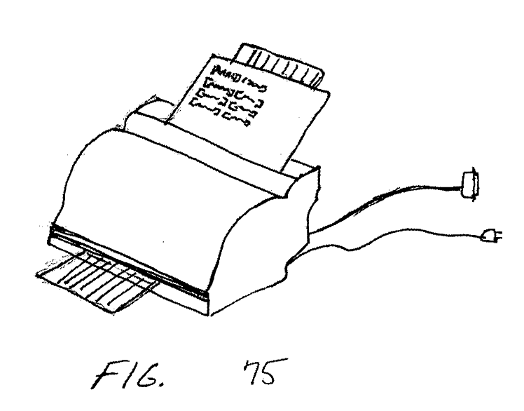

FIG. 71 and FIG. 72 depict an automated hair cutting unit with an electrically driven separator. A unit housing is shown having a connection to a vacuum at the top for aligning the hair and simplifying hair cleanup, as the hair that is cut within the cutting head passes through the device and is evacuated by vacuum connection. A separator is shown configured in an L-shaped arrangement, similar to a comb but with the tines curved. The separator may be may be formed in any convenient manner, such as tines in a U-Shape, two straight down opposing rows of tines, and so forth. The separator joins a separator sleeve which is slidably engaged on the housing and guided for accuracy and reduced drag along by guide pins riding in a vertical guide slot. The amount of hair to be left at a given location is determined by the position of the separator in relation to the cutting head and this distance is controlled by the actuator. The actuator shown is a miniature motor having a screw drive output which is threaded through a nut member on the separator sleeve. The electronics can then control the actuation of the both actuators to set a particular length even while the cutting head is moving along a given path over the head of the cuttee. It should be appreciated that any convenient actuator may be utilized, such as single actuators, stepping motor actuators, gear driven motors, solenoids, pneumatic actuators, mechanical escapements (e.g. windup actuators), other devices capable of positioning the separator, and combinations thereof.

If the separator position may be controlled by the actuator, then by adding a controller unit, the cutting head may be programmed to automatically cut transitions within a haircut. For example the cutting head senses when a cut begins and alters separator spacing according to a timed pattern corresponding to a type of cut to be performed. The user then can execute a given hair style, having varying length portions of the haircut, by performing a number of passes over the head following a set of predetermined programmed separator distances and transitions. A hairstyle may require the use of numerous programmed transitions, for example for the top, the sides, and the back. The top for example may set set to transition in a given pass from 1.5 inches at the start and transition linearly down to 0.75 inches within 2 seconds. The cutter attempts to maintain a given cutting head movement speed over the scalp with adjacent passes, if the same cut profile is to be maintained. For this type of programmed transition cutting, the unit is preferably configured to generate timing information to aid the user in controlling the speed of the cut across the scalp; for example, an optical, audio, or combination output may be generated in response to the amount of time elapsing from the start of a cut. It will be appreciated that the start of a new cut path may be determined in a number of ways, such as sensing a sudden increase in cutting head motor current prior to starting the pass, or optically sensing a new pass. The user may alternatively signal the start of the pass by pressing a button, or a button may be pressed prior to the unit performing its own detection to prevent false pass triggering.

An embodiment may be constructed of the invention which performs the transitions in height automatically in response to the position on the head of the cuttee. With this embodiment the user can select a desired hair style which is programmed into the cutting head, which automatically modulates the separator to transition the amount of hair left remaining in response to the programming. The position of the cutting head on the head may be determined in a number of ways, including using a frame in relation to which the cutting head is moved such that the mechanical relation between the cutting head and frame determine location. Alternatively, the cutting head may be configured with sensors to determine the angle of the cutting head, direction, and location on the head of the cuttee. This may be performed using tilt sensors, a compass, and preferably a motion sensing device such as a wheel, wherein changes from a predetermined starting position can be determined and the height adjusted accordingly. The size and shape of the user's head may be optionally mapped out to increase the accuracy of the patterned cutting provided by the cutter head. If the cost of accurate inertial navigation circuits is not prohibitive, these may be used to detect the movement of the cutting head, allowing the computer to track the motion of the cutting head over the scalp wherein the computer automatically adjusts separator distance in response to the programmed hairstyle.

The programming of the device is generally simple in that the program basically sets the height of the cut according to the position on the head, or the location (time) within a given pass with the cutting head. The bulk of the programming for a fully automated unit is contemplated to be resolving the position of the unit so that the proper map location may be accessed.

The controller within the cutting head may be programmed according to resident programs or these programs may be downloaded from a PC or similar device. For example, the user may connect the unit via a USB cable to a PC wherein from a a hair style application for the device they may select the desired hairstyle and parameters of the cut. It will be appreciated that the hairstyle, or program pass information, may be communicated for use by the unit in a number of alternative ways without departing from the teachings of the present invention. Additionally, it should be realized that the controller may be located within the cutting head or it may be remotely located. Furthermore, the controller may comprise an existing computer, such as a PDA, laptop, or PDA which is configured to communicate directions to the unit in response to sensor information and use commands received at the cutting head, or other user controls.

The embodiments described above may all be implemented by one of ordinary skill in the art without creative efforts.

34. Laser Engraved Book Edges

To add identification to books, and other compilations of pages, in an attractive manner that is not easily altered.

Laser etching the edges of said book. The edges could be engraved after purchase with the owners name and any desired decorating writing, indicias graphics and so forth. The edges may also be etched with information, such as manufacturer, copyright, along with decorative elements after the compilation of pages is assembled.

apparatus to adding unremovable identifiers to the edges of books:

Flood area impinged by laser with inert gas, such as nitrogen, to prevent charring, utilize the addition of additional gases, elements to impart colors and effects. Book is retained on a translation stage connected to a computer which also modulated the activation of the laser source (or optionally the intensity). The pattern for the cut is entered into the computer, or selected from a set of preset templates. The computer breaks down the pattern into a mapping for the laser and then the engraving process can commence (although the mapping may be on the fly, but riskier in case an error arises). The book is moved so that the portions of the book edges to be cut are passed in front of the laser and the laser is turned on and off to start and stop the cuts. The movement may be selected to follow a patterned scan, such as raster scanning, or a vector form of movement, or combinations thereof depending on the elements being rendered. The whole process can be performed within a gas filled chamber. Various forms of industrial laser may be utilized such as chemical laser and CO₂ lasers.

35. Survey Processing on a Conventional Scanner

To allow processing a series of surveys on a multipage scanner, or copy machine. Written surveys wherein the participant checks or marks off a section of the form to correspond with their answer are performed universally. Unfortunately unless one has an expensive dedicated machine to read the survey or a Scan-Tron, the data must be entered by hand. Therefore a need exists for a easy way to convert these checked off or blacked out areas into a set of data that may be manipulated, such as within a spreadsheet such as Excel.

Document scanners are prevalent today, they provide high resolution scans of the image. These scanners fall into two main categories, flatbed and sheet feed. In eitehr case once the image is scanned, one can perform Optical Character Recognition (OCR) on the image to convert portions of it to a text file.

Unfortunately none of these pieces of software has been found that is capable of reading in surveys and creating a data file based on the responses collected.

The invention is a set of software methods that can be used on scanned images of surveys wherein their collective information is gathered and saved as a data file for use by a spreadsheet. The user can drop a set of survey sheets that the survey and may also contain graphics, text, etc. The scanner reads in each survey, locates the section of the survey, interprets the codes encoded by the user and stores data on each survey into a file. As each new sheet is scanned the data is updated. Once all surveys are scanned the user can open one of the data files produced within a spreadsheet such as Excel and get response statistics, plot graphs etc.

Method of automatically processing written surveys that can be performed by anyone with a scanner and the inventive software methods.

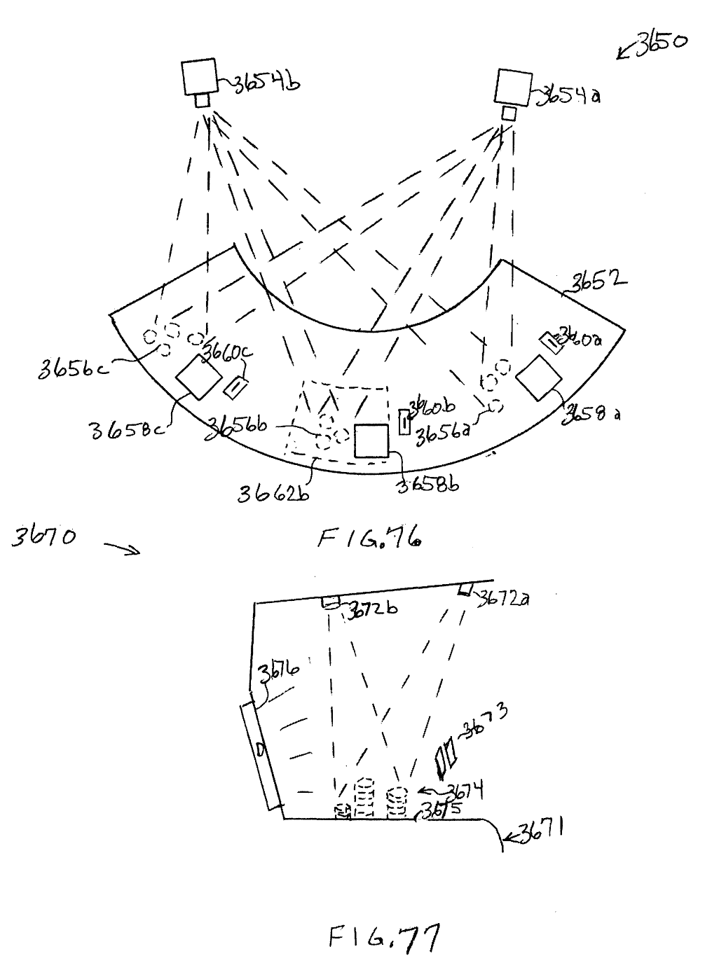

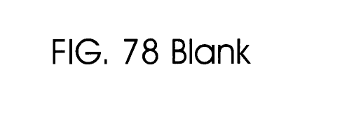

FIG. 73 shows a representative sheet of paper with a survey line to be scanned. A closeup of the survey line of FIG. 73 is shown in FIG. 74. A scanner is shown feeding a scanner page in FIG. 75.

The method of extracting the survey data can be performed in a number of ways.

Simplest which will work quickly with any system capable of OCR:

Load a survey sheet that has not been filled out into scanner.

Scan survey sheet.

Viewing the sheet, manually set the scanner area to match the survey.

Select the “Save as blank survey” choice. Scanner converts via OCR and shows result. Result should normally match up.

Result is verified, so select OK.

Select “Scan surveys”

User puts a stack of surveys on the scanner and they begin being scanned.

Survey section of each image is converted by OCR to a text file as they are being scanned.

User is prompted “Do additional surveys need to be loaded?”

User clicks on “No”

The text file is parsed in relation to the blank survey sheet. The missing altered fields are used to determine where respondent has placed a mark. Data is thereby tallied and collected into one or more files. The main file contains a line for each sheet scanned and the set of responses for each question.

User is prompted with “Select where to save file” and they choose a directory user can then import the data into Access, or Excel etc for using the survey data.

Novel Features:

Use of a scanner as a device for processing surveys.

Use of standard characters from any word processor as the survey fields and making the survey section recognizable by the scanner.

Providing a means wherein various types of answers may be handled.

Collecting data on sequention pages within the software that processes the scanned images.

RAMIFICATIONS:

Methods may be used within any computer system.

Methods may be implemented completely within the scanner.

Any form of user input marking can be interpreted.

Forms with single or multiple selections can be handled.

Errors are processed and noted for manual determination.

36. HoloGaming To increase the entertainment value and reduce losses associated with gaming, particularly those games in which chips are utilized for wagering.

Rather than using actual chips, the present system allows for the use of holographic chips which may be used for wagering. Furthermore, in games that do not require the parties to retain their cards in secrecy the system can generate images for the card being dealt to each party, wherein the cards, or a dealer become unnecessary.

This system follows with the desire of casinos to use payment cards for retaining gambling winnings, and for tracking the playing of each patron. However, this has been difficult on table based games in which proprietary casino tokens (chips) are utilized for wagering and collecting winnings. Typically, in these games the user manipulates tokens to enter a bet and collects their winnings in the form of tokens. The present invention allows the patron to bet using virtual tokens which may be visually depicted holographically if desired, in this way the patron retains the “feel” of the token based game while the casino eliminates the problem with token “shrinkage”, while increasing their ability to track the action on token based games.

Holographic images are displayed on the gaming surface to represent the tokens, and alternatively other physical aspects of the game such as cards, playing pieces, or whatever. Patron control of the action is provided by a patron interface which receives input from the user as to the action which is translated into the holographic images.

It will be appreciated that a number of new systems have been devices recently that simplify the generation of holographic images. The present system utilizes holographic imagers connected to a computerized gaming system, either for a separate game or for a series of games. The control of wagering and gaming is known in the art.

By way of example and not of limitation, the patron inserts their player card into a slot wherein the patron interface can convert any portion of their current monetary value into chips. The user can select the amount of chips to buy, and preferably the denominations, such as by entering numbers on a keypad and pressing denomination keys, or pressing denomination keys multiple times, or any other convenient selection method. Once purchased, the holographic projection system projects the chips in a given location on a gaming surface. The user may then perform betting operations with the patron interface, which may comprise denomination buttons that can be pressed to bet (a clear, or undo, is preferably provided to correct mistaken entries prior to the game commencing). In the case of a table based games such as blackjack or poker, the table itself may be configured with a patron interface (patron console) at each position, with a set of controls to indicate what they want to do, such as how much and how to wager. This may also to utilized to indicate their playing desires, for example if cards are displayed holographically, then the user can select whether to hold, split, double, hit, take insurance, and so forth during playing. In this way physical cards need not even be used. A machine therefore may be implemented which incorporates the present invention and makes it appear to the user similar to playing at a gaming table. The system can be preferably configured to display other players and action as desired by the user, or to have a holographic image dealer that may be for example a celebrity that banters while they play. In certain games, such as craps, wherein the user places bets at locations on the table, the patron interface may contain a similar grid allowing the patron to select a location and then strike chip denominations to add those chips to the location, or similar method of selecting a remote location and a wager amount. Alternatively, the user may be provided with a pointer devices, such as attached by a cord to the gaming table, wherein the user can point to the location where they want to place their bet which is registered by the computer (such as by a reflection of a coded transmission being registered), which is accompanied by a wager selection, such as by keystrokes or other selection methods.

The holographic system can provide a number of entertaining features as well. For example, when the user wins the hologram may display dancing chips or various images of riches, such as gold showering the patron. These images can be very memorable, and could substantially increase player entertainment value, customer retention, and create a physiological trigger that further stimulates the patrons gaming inclination. A holographic play adviser can be summoned, or shown confidentially on a separate 2D display. The player can preferably order their drink selections from the patron interface, food, or other available amenities.

FIG. 76 depicts a gaming station 3650 having a playing surface 3652 with holographic projection device 3654a, 3654b, which is projecting token stacks 3656a, 3656b, 3656c, for three patrons. A patron interface 3658a, 3658b, 3658c, is also shown along with a card slot for the patron to insert their player card for use in buying chips and collecting winnings. Although a table is shown configured for blackjack, it will be appreciated that the system may be applied to any gaming device requires the manipulation of tokens, cards, or other gaming apparatus.

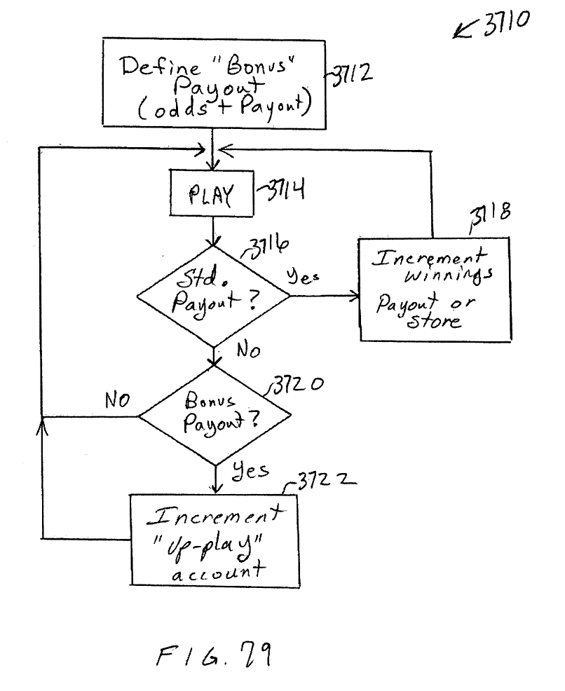

FIG. 77 depicts a gaming machine 3670 having a player position 3671 and holographic projection devices 3672a, 3672b, (connected to a computer system), which are shown projecting floating cards 3673, a stack of chips 3674. The user can preferably control the action through a patron interface such as a flat panel display with a menuing system. The dealer may be projected holographically or shown on a separate display 3676, in addition the system may display other elements of the gaming environment.

Holographic gaming—wherein the user can manipulate virtual chips and see holographic elements associated with the game.

37. UP-Playing Promo

To encourage casino patrons to utilize games of chance providing higher denominations. The gaming machine is configured to award special “bonus” payouts which credit their gaming card with monetary credits which must be utilized on select machines or denominations. For example a patron on a nickel videopoker machine may be incented by a bonus payout win that pays them a given number of credits on a quarter poker machine. Likewise a quarter machine may provide bonus payouts for use on dollar machines and so forth. The “bonus” payouts may also encourage patrons to use other types of gaming machines, with the concept being that patrons that have learned to enjoy a greater number of machines will return more often and increase their level of gaming.

A number of features may be provided with the “bonus” incentives such as:

+incent can not be exchanged for cash it must be played, that is why it is a special bonus.

(winning of course from bonus may be cashed) If it was part of the payout for the listed odds then the restrictions would not be right and perhaps even illegal.

+incent toward higher denomination play.

+incent toward machines with better house odds.

+incent toward diverse machines, or machines not played as often.

+unusual incentives may be provided as well, such as: drinks ordered through the machine (incentive to get then accustomed to doing so), casino goodies: free lodging, shows, massages, dinner, t-shirt, glasses, and so forth. All casino “goodies” given away can be written off as promotional giveaways (advertising), making the deal sweater. Patrons want to be special!!! Give them something unique, something they'll remember—make the bonus payout an experience. A spirit of a patron on a losing streak may be down and they may not return—even small considerations such as a coffee cup, t-shirt, or even a free drink, could give them a lift.

+free and discount offers from a variety of establishments—these may be provided within the same bonus system or preferably within another tier of second level bonus offerings, the user can select to which level of bonus incentives they would like to participate when playing the game.

+advertising may be provided on the machine in association with the second level of bonus incentive (remember they can elect to turn these off at any time).

+user selected forms of incentive—a screen with categories and checkboxes can allow the user to select the types of incentives they want. In fact the patron could be asked to rank the desired incentives in order, wherein the machine would help their odds towards the desired incentives.

+any number of extra bonus incentives levels may be provided to the user with an assortment of offers.

+a small printer may be setup on each machine, or at the cashier. Each offer extended that the player has accepted on the machine is logged into their card (under their name in the database). The outside offers may then be printed out at the cashiers window, in-house offers could be printed as well but they are listed based on card number anyway.

+may require user to answer a few questions posited from the machine l'face to be granted bonus.

+Allows casinos to test up play forms of incentives to determine profiles of players most likely to “play-up”.

+incent expires if cash on card drops below a given threshold—why have them start playing the other machine if there is only the bonus cash to play with? By providing a range of unusual incentives these sorts of limits would perhaps seem too constrained—it is an extra payout that is above the normal odds for the machine anyway.

+

Embodiments:

On machines that are operated with a casino card, the bonus payout is either registered on the card, or of all systems are connected to central database then the bonus can be logged in the central database and accessed for the given user. The software of the machine is modified by either modifying the actual odds computional gaming portion of the game, or preferably by adding a back end gaming computation engine. It is preferred to add the bonus odds computation as a second stage, because implementation problems are eased, additional flexibility is provided as to how it is run, and it can be more fun. Furthermore, providing a bonus incentive makes little sense for a player that has won a hand, jackpot, etc.!! For example when the person loses a hand, then and only then is the bonus payout computation executed. To further stimulate the individual the bonus payouts can take the historical play of the patron into account (something the regular payout could never do). For instance, the odds of winning a bonus payout may increase based upon the number of losing hands, pulls, tries, that have been executed. Or the overall luck of the individual that day. It is really a shame to send someone home disappointed, and the casinos can lighten the gamblers day, with an incentive.

Computer gaming is based on generated random numbers, which can be mapped out to a set of bonuses having different probabilities. The bonus computation may be performed in a number of ways: (1) on firmware of the gaming machine itself, (2) on a separate module within the gaming machine that is tied into the machine for after play operations thereby perhaps easing the testing and certification processes, (3) within the central database if it is tied to the gaming machines. [Choice 3 may create excessing communication overhead, but may be applicable to field testing of various bonus programs on selected machines.] After a losing play, the machine immediately runs a bonus computation against a list of possible bonuses at different probability levels. If the computation hits any of the items then the user is alerted to the bonus in a similar manner than a regular win, however, more info on what has been won should be displayed. Preferably the user can then elect to accept or decline the offer. If bonus odds are flexible, such as based on historical data, then declined offers should increase the probability of hitting another bonus. This is similar to a user electing to put their winnings on the play line, instead of cashing them in.

When a bonus is won and accepted, then the bonus is logged to that card, such as on the magstripe of the card, but more preferably on a bonus record associated with that user ID in the database. In this way the use of the magstripe is unaffected, and the bonuses are tracked solely on the main database. For gaming systems tied into a central database, implementation requires adding records and fields to each user ID for bonus items, preferences, and history. Then altering the gaming machine software or hardware to perform the extra bonus computations and associated bonus selections, and bonus winning multimedia, or the interface with the central system if it is performing the computations.

When a card is first inserted in a machine, a query on the database for that user is made checking for any up-play credits that match that machine. If so then the credits can be used for plays on the machine but not cashed in directly. The other play related incents are preferably handled in a similar manner.

The casino determines a set of odds for a given set of bonus items and the system is programmed accordingly, or is preferably provided a list of possible bonus payouts and odds on the fly. Since these are extra they probably don't need to be listed on the machine. Preferably the selection of bonus payouts are tied to the main database of the casino wherein the level of payouts and the nature of them can be selected based on information within the database. For example, if a patron were staying at the casino then a bonus for a room may not make sense, if they had just eaten then a dinner bonus would be less preferred. The types of incentive offers may change—so the central database can provide a general list of bonuses that the odds are based upon or fully select items for the given patron. Since the actual gambling portion of the machine is not impacted the casino would have greater flexibility to offer these additional items. If the machine has user option selections, then the user should have the option not to be provided with bonus payouts (most would of course want to at least see what they'd get but by offering a choice the slim opportunity for anyone to be upset would be reduced further).

FIG. 79 depicts a flowchart 3710 of the bonus incentive methods as described herein. The casino defines the odds for the bonus payouts, these may be determined on a flat per machine basis, per machine on a category of user basis, or determined on the fly based on machine, user, historical information on user gaming, and other determiners. The user commences to play a machine with the bonus incentives engaged (preferably the machine allows them to elect whether they want to participate) as represented in block 3714. If play incentives are provided then the machine preferably checks if any incentives are pending that apply to this type of machine. The conventional gaming computation is performed as per block 3716. If they win then the standard winning multimedia is played and their winnings as listed on the machine and on the card are incremented as per block 3718, and they may execute another play at block 3714. If they do not win at the hand, round, pull, then execution drops into the bonus computation section of the program as per block 3720. This section may be implemented as a section of the program in a standard gaming machine or provided by optional hardware tied into the machine, if this simplifies the certification process for the gaming machine. Furthermore the bonus round computation in full or in part may be performed by an off line machine, such as central computer. For example to reduce the amount of changes to the machine, the bonus round may be performed as a simple odds computation that if it hits (a win of some level), then a communication is opened with the main database which can determine which of the incentives has been won. It may perform another random computation to determine which item has been won. It is preferably that the machine still provide announcements with multimedia about the bonus provided, and this information may be resident in the machine or received from the central computer, or combinations thereof.

If the bonus computation hits (wins) then the incentive is selected as per block 3722, such as an up-play incentive which is particularly suited for persons that have never or rarely tried gaming with larger denominations. The bonus is announced to the user and their account is incremented with the incentive, which is preferably noted in the database in association with their user ID. The user can then continue play.

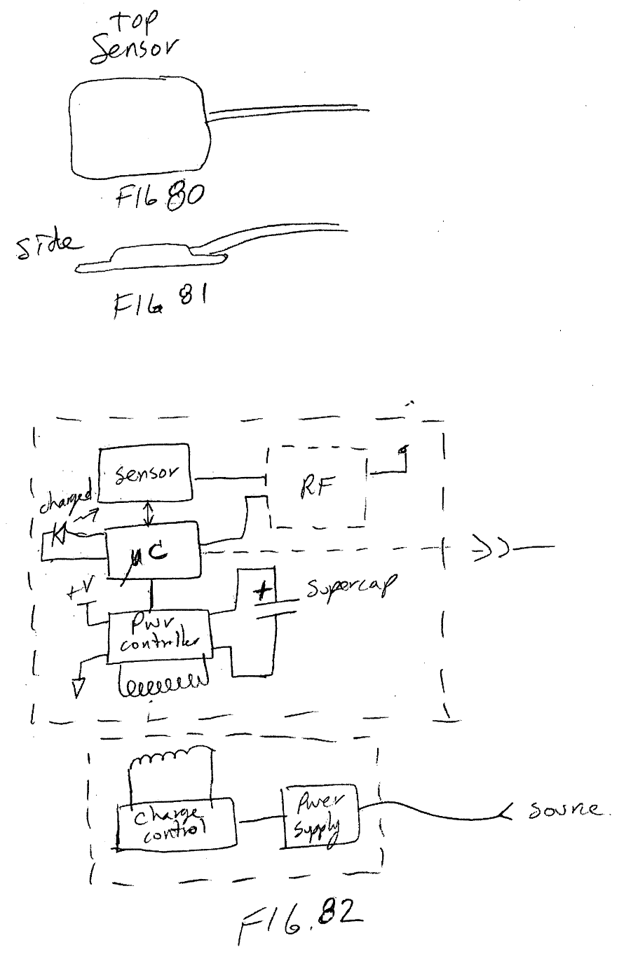

FIG. 80 depicts a flowchart 3730 of handling an up-play incentive. If a patronage card is inserted in the machine as represented by block 3732, then the bonus incentive account for the person is checked in the database at block 3736. If this is an up-play incentive, then the denomination value of the machine is compared with that of the up-play incentive, if the machine is not high enough (i.e. up-play won was to a dollar machine, but card inserted in a quarter machine) then the machine is played using standard deductions from the card as per block 3738. If an up-play is occuring, then the amount for the play is deducted from the up-play incentives as per block 3742 and the play commences at block 3744.

It will be appreciated that the aspects of the invention described may be implemented separately or in combinations thereof. Furthermore, one of ordinary skill in the art can implement this functionality in a number of alternative ways without departing from the teachings of the present invention.

38. Reception Sentry

Controlling/Monitoring/Greeting in a small office reception area when the receptionist is not immediately available.

At an office, each time the door was heard a client may have arrived at the office, or it could be an employee arriving/returning. On some occassions multiple parties would jump up and go to the door and at other times no one would check the door. Clients may be left waiting or other parties could be pilfering from the outer office; which in fact occurred approximately two weeks prior when a brass elephant was stolen under just such circumstance. The policy had been enacted to call out your name upone coming through the door so that no one would think you were a client or otherwise and come running to the door. The door had even been locked on occasions if no one was responding to the sound of the door opening. In a small business such as this multiple shifts of reception can not be maintained. Such problems are probably widespread.

I tried thinking of obvious solutions to the dilemna. There were no “off the shelf” solutions of which I had seen. Simple door bells used in retail establishments would do no more than the sound of the door as presently heard. After thought on the situation an idea formed whereby a door sense ciruit was coupled with an entry/exit procedure for employees when the receptionist was not at her station that would form the basis of a solution to the dilemna.

To provide a device that can provide electronic reception services for a business when the receptionist is not in the reception area. The device announces the entry of non-employees, greets the visitor/prospective client/visitor, advises other employed parties taking over in absence of the receptionist that a party is waiting in the reception area.

Additional features will be disclosed about optional equipment for the Reception Sentry.

An electronic device and method to provide reception area services when the receptionist is not available.

What was needed in this an apparatus that could detect not only entry and exit, but whether the entering/exiting person was an employee. Additionally the device should be able to be disabled when the receptionist returns. Also the device preferably provides a means to convey which party SHOULD handle the door, if multiple receptionists exist, or in case a receptionist has stepped out for a moment. While the client entering to an empty lobby would be comforted by being told the name of the company and that someone would there shortly. Optionally it would be helpful if one or more employees could see the party entering, wherein the risk of theft is reduced and the receptionist is not surprised upon reaching the lobby.

PERSON(S) ENTERING RECEPTION AREA SENSING MEANS:

Camera: A simple camera device such as CCD can be used to sense a wide area in the reception area. There are numerous variations:

PC Based Camera—Camera is connected to the PC and all the software for running the system are contained on the PC. If the images from the camera are to be used for surveillance the camera is of necessity of higher resolution than required for the reception area monitoring operation.

Embedded System Camera—The camera is integrated or in connection with the the electronics that make up the remainder of the system. The camera may be of low resoloution (i.e. on a par with simple imagers such as Nintendo brand Game Boy Camera).

Beam: How to handle different background lighting

Incident lighting—Sense the change in incident lighting that occurs when a person enters the Reception area.

Beam reflection—Use a collimated beam such as IR laser (with red laser targeting beam) reflected off of a reflector wherein a change in reflected light level is used to sense that a person has entered the reception area. Methods of use: (A) reflector placed on reception area door—when door opens the reflection is interrupted. (B) reflector on a surface such that person will cross beam upon entering reception area.

Direct Beam—Similar to the above yet the beam is separate from the apparatus of the Reception Sentry and is directed across the traffic footpath entering the reception area.

Door motion sensing. A device placed on or near the door to sense its motion. By way of example a transducer (passive or active) emits RF when the door is activated. The direction of door activation may be gauged in relation to a secondary sensor within the reception area, if that sensor (such as light sensor) is triggered prior to the door change then it assumed to be a party leaving, otherwise it is a party arriving, wherein the functions of the system are activated. EMPLOYEE SENSING MEANS:

Off-path Beam interruption: A second (or more) beam sense area that is out of the normal path a visitor would take after entering reception area. Generally this would be off to one side or above the normal path. An employee could wave an arm in that direction of perhaps use a different walking path to trigger the sensor.

Off-path Image Sensing: A portion of the camera image is of an area that is out of the “normal” sense area and path of a visitor. When the image in that regions changes abruptly soon after or subsequent to sensing a visitor, this will be taken to be an employee.

39. Wait Less with Weight

To increase the efficiency of elevators by prioritizing their movements based on the amount of weight they are carrying. Therefore elevators that are getting full are not held up as much as those that are empty.

Incorporate weight sensors on the elevator, or connect existing sensors for communicating the weight data to the controller which determines the scheduling of the elevators. The scheduling from current locations to destinations is to be handled in a priority queuing order, so that movements may be optimized to reduce user waiting. The weight value for a given elevator is added as one factor in the prioritization, wherein the higher the weight value the higher priority the current destinations for the elevator are raised and the less probable are the making of stops on the way to that location. Furthermore, if the weight is at or near the maximum, then no more stops to collect other individuals will be made. Also if the elevator has made a stop to take on new people at a requested floor, but the weight did not increase, then there must no be room on the elevator (person with conveyance, or large boxes, etc.) wherein no more stops are made until destination stops have been made and the weight has accordingly dropped.

39. Wirel ss Radiographic Sensor

To eliminate the wiring of conventional radiographic sensors such as utilized in dentistry.

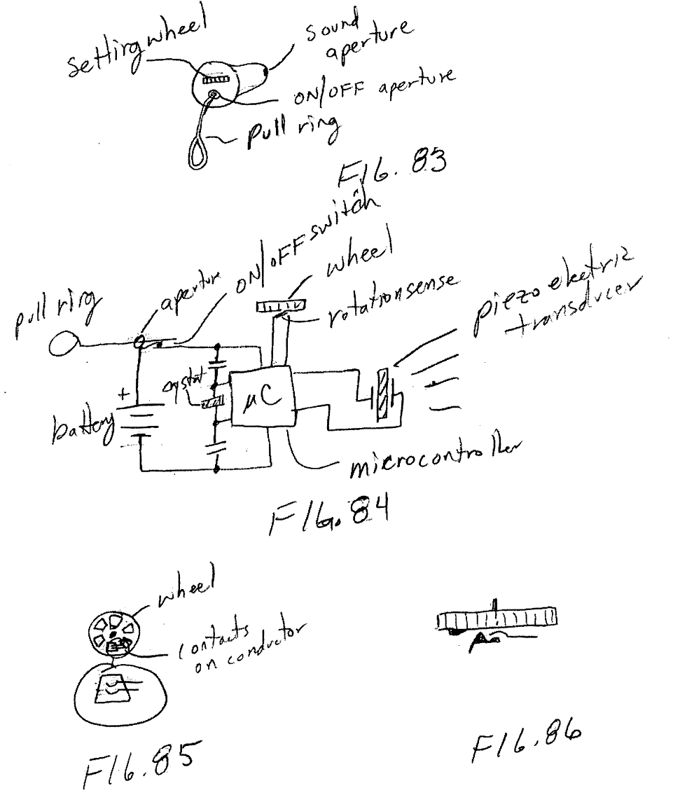

FIG. 80 is a top view and FIG. 81 is a side view of a sealed radiographic sensor. FIG. 82 illustrates a sample schematic showing the sensor, a microcontroller, an RF transmitter, or transceiver, and a power source. The RF transmitter is preferably adapted to upload captured radiographic data to a computer that is equipped with an RF receiver. The RF transmitter and receiver pair may utilize any desired protocols such as BlueTooth™ for communicating between the sensor and the computer capturing the image data.

The power source preferably comprises a supercapacitor that charges on a contactless charging system, for example utilizing an inductive coupled charging system. The radiographic sensor is positioned at a station when not in use wherein it receives charging through the case, such as by the electric energy generated from flux changes on an inductive loop.

The unit preferably provides a charge state indicator. When removed from the charger the indicator should change state to indicate the loss of charging. Preferably after being removed from the charger, the unit should perform a self test and indicate it condition (i.e. good or bad) so the technician does not waste any time with a malfunctioning unit.

The capture of image information may be triggered by a signal received on a receiver within the radiographic sensor, or by a signal pulse received through the inductive loop. Alternatively, the unit may sense trigger conditions on its own by sensing the radiation intensity using the sensor itself, or a separate sensor. Then the intensity reaches crosses a predetermined threshold, or other selected trigger condition, the sensor captures the image data and uploads it over the RF link to the receiver on the computer where the image is processed, stored, and displayed.

41. Externally Controlled Ear Alarm

Provide travelers with a personal alarm device, wherein they can be awakened without awaking other parties.

A small hearing aid style unit that can be programmed for a given time period, after which an alarm will sound. The unit may contain a set of simple controls for setting the time and shutting off the alarm, or be controlled using an external device.

The user programs the unit for a given time period, such as for a nap, then inserts the tip of the unit into the ear canal. After the given time has elapsed the unit begins generating an audio alert. Preferably, the alert starts out at a very low volume and successively builds, until the individual awakens.

To simplify falling asleep the unit may be configured to generate pleasant audio, or sound effects, such as ocean sounds recorded in an MP3 format, white noise generated using discrete circuits, or other forms of soothing audio.

A loop, tab, or string, preferably extends from the unit to allow the user to readily remove the unit from their ear when the alarm sounds. This also is indicative to flight crew members that the device is for blocking sound, while it facilitates removal of the device by a flight crew member should an emergency situation arise.

The structure of the unit is preferably adapted to attenuate sound reaching the eardrum, to make sleeping easier. A similarly shaped ear stopple is preferably provided, that may be used on the other ear to reduce the sound reaching the individual.

The alarm may be sold separately, with a simple light blocking sleep visor or shade, or with a flight forward comfort pillows for use with a lowered tray table as described elsewherein. The programming and power for the unit may be provided in a number of alternative ways, such as the following.

Self Contained Unit with Simple Controls:

The unit is provided with exterior controls to regulate timing and a battery power source. A set of controls may be provided using pushbuttons, dials, wheels, other conventional controls, and combinations therein. FIG. 1 exemplifies a unit with a pull-loop that also operates as an ON/OFF switch. When the end of the pull-loop is inserted within an aperture within the housing of the unit it causes power to be connected from the battery to the circuitry, wherein a loud beep is preferably emitted to indicate activation.

A thumbwheel selector allows selecting a desired time period. In this simple interface the rotation of the detented wheel is sensed, and it is considered to be at zero time when power is applied. The user then rotates the wheel through a desired number of detents, or simply guesses if a long time period is desired. Once stationary, such as for 2-3 seconds, after being rotated the current setting the unit indicates that the current time setting is set for. The time setting may be indicated in a number of alternative ways, for example as an audio message “two hours twenty minutes”; as audio signals “Beeep, Beeep, Click, Click” which may also represent 2:20 with hours being long beeps and ten minute increments being clicks; as a displayed value, such as on an electronic ink display attached to the housing of the unit, wherein the actual time may be indicated on a small 3 digit display, or using indicators spots for the hours and minutes; additionally small LEDs may be utilized which are pulsed for hours and minutes. For example a single RED/GREEN LED may be pulsed twice red and twice green to signify a setting of 2:20. It will be appreciated that the time may be set and indicated using a variety of mechanisms without departing from the teachings found herein.

Power for the unit may be provided in a number of ways, such as with batteries or capacitors. If batteries are used they are preferably small coin cells retained within the unit, for example a single 3V lithium coin cell, or two small alkaline cells. It will be appreciated that considered the low time of use and limited current draw, that the use of primary batteries is preferred for this configuration. Capacitors, and rechargable batteries may be alternatively utilized within the present invention, however, they require an external charging source, which may be plugged into the unit, or coupled to the unit inductively.

Circuitry may be provided using a simple 8 pin surface mount microcontroller chip operating from a watch crystal timebase, or similar crystal timebase. Controller chips such as PIC 8-14 bit microcontrollers are available from Microchip® Inc in Chandler Ariz. The wheel can register the making and breaking of contacts as the wheel is rotated and the audio may be generated directly from the controller as the different beep sounds described above, as wheel as the alarm sound of increasing intensity.

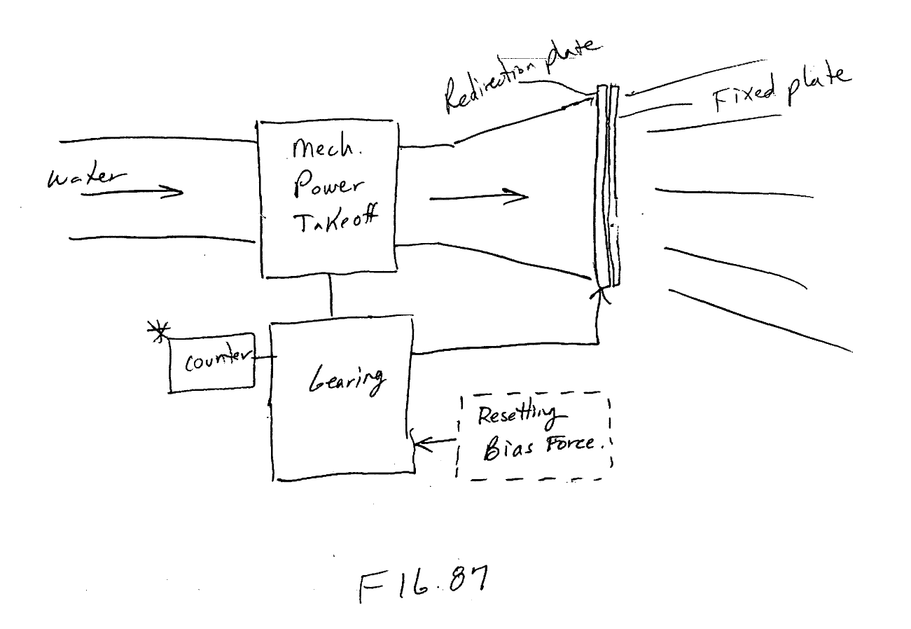

FIG. 83 exemplifies the device shown in a perspective view. The setting wheel and pull ring inserted within the ON/OFF aperture are apparent. The sound emitting aperture is proximal to the end of the device directed down the ear canal.

FIG. 84 depicts a simple microcontroller circuit using an 8 pin PIC microcontroller tied to crystal timebase, contacts driven by the rotating wheel, and an audio transducer depicted as a piezoelectric transducer.

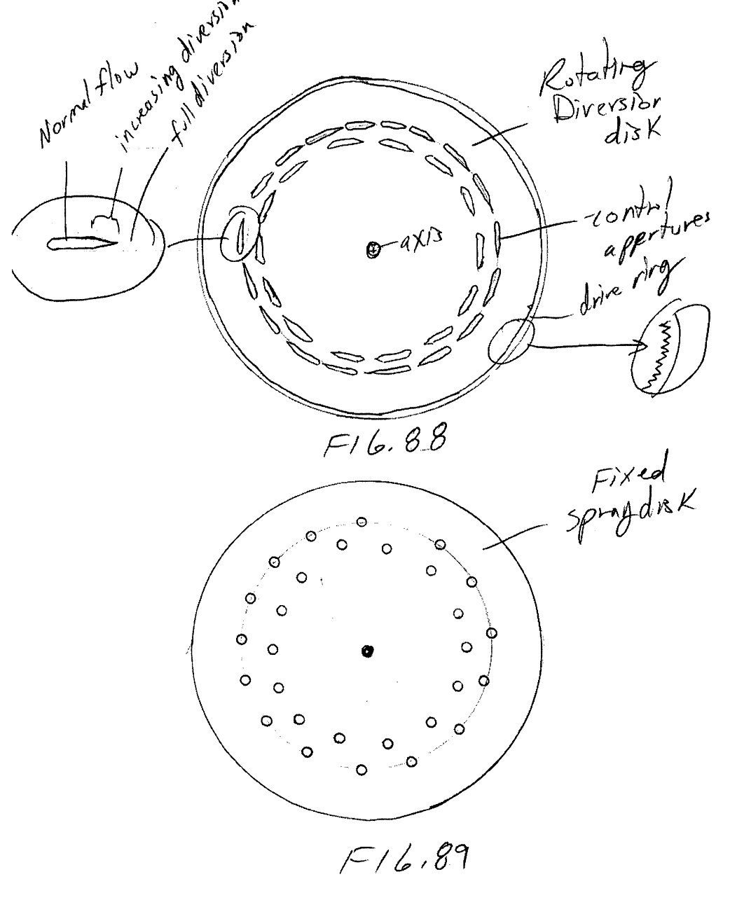

FIG. 85 and FIG. 86 exemplify a couple of simple wheel embodiments. In FIG. 3 the wheel input is formed with a rotating wheel disk having conductors on the facing of the disk, wherein a pair of contacts will alternatively be shorted to one another in the conductive regions and non-conductive as the contacts pass over an insulated sections of the wheel. FIG. 86 illustrates the use of a rotating wheel that has exterior structures instead of conductive pads. As the wheel rotates the protruding contacts change the state of a switch, herein shown as changing to a conductive state as the wheel passes over the exterior contact which is forced into contact with the stationary contact. These forms of inputs may be readily and inexpensively manufactured at very low cost.

Externally Programmed Unit:

The unit may be implemented as a device which is remotely programmed, and optionally remotely charged, by an external device, such as a PDA, phone, other device capable of remote communications, or a proprietary device for use with the unit. The user preferably enters the parameters for when to awaken, and any other desired control metrics into the remote device which either downloads information to set the alarm time, or actually sends a wake up signal to the device when the alarm time is reached. The unit may be coupled to the external device with an inductive loop through which both power and programming information may be received. The unit in this scenario could be configured with a capacitor power source that is charged by the signals received on the inductive loop, this is similar to the communication used by an of an RFID device wherein power and signal are received (and optionally transmitted) over a simple inductive loop.

It should be appreciated that a number of different embodiments may be implemented by one of ordinary skill in the art as modifications of the present teaching without creative efforts and without departing from the teachings herein.

42. Personal Alarm Feature for Cellphones/PDAs

Individuals often have the need for a sleep timer or other interval form of timing element for use in their daily activities.

Incorporation of one or more timer features within cellphones, PDAs, or similar personal devices, that allow for awakening the user after a preset interval (no need to set a specific alarm value just dial up a value, such as by tens of minutes).

Embodied as SW on a PDA, or Phone:

Software may be added to a phone or PDA wherein a user interface collects the time period to be set, such as entering a time period on a numerical keypad, or screen, or the use of one of more increment/decrement keys, wherein the amount of time may set sequentially. Once the time is entered, the timing period commences, preferably by periodically awakening the processor to increment the time value. When the time interval expires the unit generates an audio output, preferably distinguishable from non-related functions, such as phone ringing.

In this way the user gets extended functionality out of their existing PDA, or cellphone, and can take naps, or set other forms of reminders quickly and easily.

43. Pump Motor Protection Device

To prevent damage to spa motors and similar motors that are subject to be activated when insufficient liquid exists in the system to turn off the motor. These should also be used on pools with a longer delay to prevent pool motors from being damaged if system is too leaky.

Senses the difference between water flow (or other fluid) and that of air (no liquid) sensor can be inductive (coil around outside), pressure at the output of the pump above a sufficient threshold, pressure differential across pump (small channel across it with switch), mechanical (paddlewheel, lever, and so forth).

If the pump has not drawn liquid in a preset amount of time, then power to the pump is switched off, and a signal is indicated. When power is cycled, then unit resets and retries.

Unit connects to the power signal to the pump.

Options:

Signal if the unit has turned off the power.

Periodic retry of powering up the unit. (preferably still indicate if problem exists)

44. Hot Water h at r Use Controller

TimeOut Water heater controller—a timing device for a water heater that limits the uninterruptible duration of the hot water to limit those from taking excessively long showers. In addition the unit preferably provides a control unit (preferably RF coupled) that allows the “responsible party” to bypass the time limit on command.

This device controls the use of hot water at the hot water heater. If the use period is exceeded the unit stops, or “throttles back” the hot water use. User not to be controlled can override the device with a remote control to allow them to use the water for extended periods of time.

Outline Description:

A controller for a hot-water heater to limit excessive use of the limited hot water comprising:

a timer means;

a flow detection means coupled to said timer means which detects when hot water is being drawn from the hot water tank at above a given flow threshold (prevents trickles and washers etc. from triggering);

a flow control means connected to said timer means; and

wherein said timer means upon detecting that hot water flow has exceeded said flow threshold for a period of time exceeding a first timing interval, signals the flow control means to restrict the flow of hot water leaving said hot water heater for a period of time that is approximately equal to a second timeing interval.

wherein said timer means comprises an electronic timing circuit.

wherein said electronic timing circuit is configured with time setting inputs for said first and said second timing intervals.

wherein said electronic timing circuit receives operating power from a conventional power supply.

wherein the power supply is a wall mounted AC adapter.

wherein said electronic timing circuit receives operating power from a battery supply.

wherein said electronic timing circuit receives power from a generator which generates a charge voltage to a electrical power storage device

wherein said electrical power storage device comprises a capacitor, or a battery.

wherein said flow control means either reduces or terminates the flow of hot water when activated by said timing circuit.

wherein said flow control means is adapted to restrict the flow of hot water over a short interval to allow the person time to complete a given task and which prevent thermal shock to a person that may be showering.

further comprising a user activated override input on said timer which upon being activated overrides the first timing interval to allow for unrestricted hot water flow.

wherein the override input comprises an RF receiver coupled to said timer that upon receiving a proper signal from an associated RF transmitter overrides the first timing interval.

wherein the override signal is generated in response to a passive water flow location detection means so that unrestricted hot water flow is enabled to selected locations.

wherein the passive water flow detection means comprises an acoustic transducer coupled with a digital signal processing element which associates the acoustic signature of the hot water flow through the pipes with the locations within the structure to which the hot water is being supplied.

wherein the passive water flow detection means comprises a pressure transducer coupled to said timer which is adapted to register pressure fluctuations in the hot water flow; wherein the pressure transducer is used in combination with a water output valve, spigot, spray head, or equivalent that modulates pressure in the hot water according to a fixed pattern that is detectable by said pressure transducer which selectively overrides, or enforces, the first time period limit.

45. Shower Head Water Use Controller

A mechanical shower timer controller that operates on an individual shower head to restrict and redirect the water from the shower to discourage continued use after the preprogrammed interval has elapsed.

Often it is desireably to control the use of hot water, in particular the length of showers, to reduce waste in both energy (for hot water) and water. Although an electronic valve mechanism could be connected to the shower this is often undesirable as having electronics mixed with a water environment generally proves problematic and unreliable. Therefore, it is desired to provide a simple mechanical control of shower duration that automatically resets after a period of time has elapsed. Furthermore, it is an object of the invention to provide full flow for a period of time, and then to slowly divert the water until it just trickles from the shower head. A further object is to allow a person in charged to set the duration that the unit provides. The unit should be of a similar size and configuration as a standard shower head, so that conventional units may be easily replaced.

A self-contained unit within a shower-head, which begins to restrict all water flow after a first interval and continues restricting water flow until an endpoint is reached. Thereafter, it resets itself over a period of time. If water is used before the device is fully reset then it continues to restrict flow. After it fully resets, such as after 5 minutes, then it will again provide unrestricted flow for a period of time. The unit must not rely on orientation, as the shower head may be positioned arbitrarily.

The device does not rely on a valve to stop water flow, as it will be appreciated that a valve having a large open region that is subject to the full water pressure of up to about 100 psi requires a great deal of torque to operate. The present invention relies on the use of a diversion plate behind the normal flow output flow channels of the shower head (represented as holes in a mesh, although the diverter may be used with any form of water direction channels. The diverter shields the output holes, which increases the backpressure to slow the flow, but a reduced quantity of water still can flow from the shower head, however, at such reduced speed that it drizzles from the shower head to the drain below. The result being that showering no longer is enjoyable and the user it prompted to discontinue.

The redirection plate within the present invention is preferably configured so that it may be rotated through a first angle corresponding to a first period of time without disrupting the flow. During a subsequent second period of time the water increasingly diverted until it is all diverted. In this way the user is given a period to “finish up” without being completely cut off all at once.

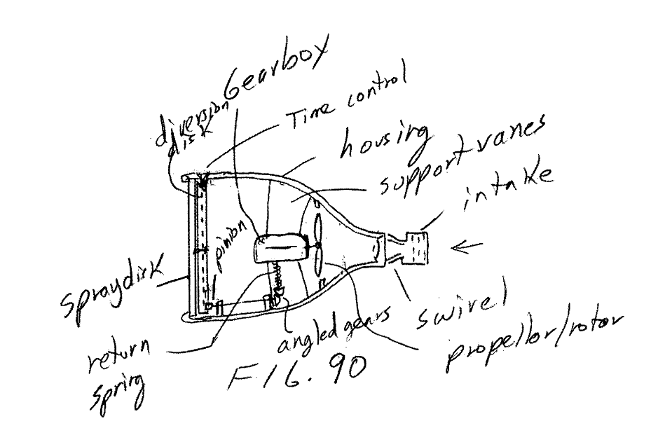

FIG. 87 depicts a schematic for the device wherein the flow of the water drives a mechanical power takeoff device, such as a turbine blade (propellor, rotor). The power from the rotating blade is slowed, such as through a gearing mechanism so that the diverter may be actuated over a period of minutes. The gearing drives the diverter in relation to a fixed plate. The diverter is shown behind a fixed plate used as the shower output. A resetting device then resets the state of the device after the flow has ceased for a period of time. The resetting mechanism is preferably a spring that is wound in response to the water flow through the shower head, and which upon turning off the water unwinds over a period of time, such as 1-4 minutes, so that another person may use the shower with full flow. An optional counter is shown on the unit which can track shower usage, such as the number of cycles that the shower controller has gone through. (This could monitor if someone was taking multiple showers, separated by a short period of time.)

It should be appreciated, however, that the diverter may be provided “upstream” of the final output spray head. Furthermore, water may be directed through channels to separate diverters prior to the streams reaching the output plate. For example, the use of four longitudinal chambers within the shower head each passing through a diverter/fixed output combination prior to the flow exiting toward a fixed plate output.

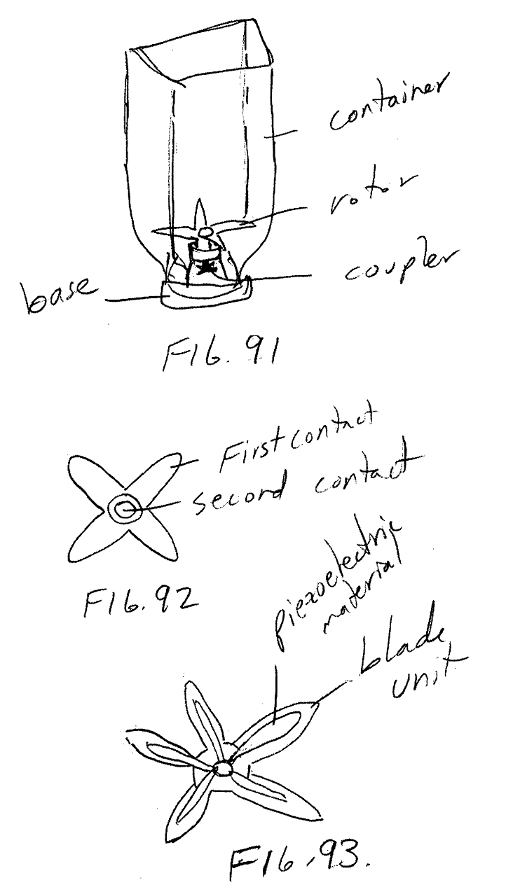

FIG. 88-FIG. 90 exemplify a shower head using the mechanical control and diverter as described. FIG. 88 depicts a diverter disk having a set of elongated apertures. It will be seen in the detail view that each aperture is configured with a normal flow region wherethrough normal flow speed of water may pass to the associated fixed disk, a tapered section which provides increasing levels of diversion (slows the flow) up to a no hole wherein full diversion occurs (a certain amount of water may be allowed to pass through the plates between the disks and out, but this is at low velocity, nullifying the pleasant effects of continuing to shower). A drive ring is shown on the perimeter of the diverter disk, although it may be driven by a center post or other mechanisms as desired. FIG. 89 shows a fixed disk to which the diverter is preferably attached.

FIG. 90 depicts a side partial cross section of a shower head according to the present invention. The shower head preferably appears conventional in appearance. Within the cavity of the shower head is a gear housing attached by support vanes to the interior of the cavity. Extending from the gear housing is a rotor (which may be shaped as a propellor, turbine, or similar) which is retained in a flow opening through which the water must pass. The flow of the water drives the rotor to operate the gearing within the unit. The gear housing need not be sealed as the water may aid lubrication of the gears. Rotor motion is geared down and an output is used to drive the diverter plate. The diagram shows a vertical shaft exiting the gear housing which connected through an angled gear to another angled gear which drives a second shaft having a pinion gear which is engaged in the periphery of the diverter plate. Therein as the rotor spins the diverter is very slowly advanced through the normal flow region and toward the diverted flow region.

A spring is shown connected to the output of the first shaft. This spring is configured to be wound in response to the movement of the diverter plate. When the flow ceases, then the energy of the spring is returned by driving the gearing in the reverse direction. The unwinding of the diverter is slowed by the air resistance of the rotor spinning within the chamber, as it will be appreciated that water will drain from the shower head and the rotor will be surrounded by air. The spring then returns the diverter to the correct initial position within 1-4 minutes, depending on the design. It should be appreciated that the unit may be less preferably configured with a manual reset wherein the user activates a mechanical control coupled to the diverter plate, or gearing, to reset the unit back to an operational state. This reset control may be located anywhere such as the face of the unit.

The unit may be optionally designed with a control that allows the “owner” to set the time prior to the unit beginning to divert the flow. For example, presume the unit times a shower at 10 minutes of normal flow with a 1 minute ramp down to full diversion. However, the owner may actually want the unit to only provide 3 minutes, 5 minutes of 7 minutes. Therefore, a control is shown on the side of the unit which may be rotatably adjusted. The screw has a head piece which acts to stop the rotation of the diverter at an desired position along the normal flow track, so that the unit cannot return all the way back to the full 10 minutes of shower us remaining. The head of the screw is preferably a special proprietary thread that can not be adjusted without a special tool. Alternatively, the control may be adjusted by using a magnetic tool on the housing, such to rotate a control therein. It will be appreciated that the diverter disk rotation may be stopped in a variety of ways.

Additional Aspects of the Invention:

Novel advantages of my preferred embodiment of temporal shower valve:

Incorporated with shower head—no replumbing necessary.

Small form factor suits typical shower heads.

No electrical power needed (no shock hazard).

No complex and expensive water shut off—it redirects the water.

Slowly reduces desired flow—provides warning & no shock.

Can not be immediately reset.

Can be adjusted for different times only by party with special tool.

No winding necessary for starting unit

No external levers etc. needed (preferred embodiment)

Rotating face to simplify timing, prevent resetting prior to delay with a cam. (hardware then has no need to reset “water redirector” automatically)

Does not require specific orientation to operate.

Low cost design.

May be constructed of plastic.

46. Suboscillation Blend r

To increase the efficiency of food blending. A sonic, or ultrasonic, transducer is coupled to blending rotor that spins within the blender. The vibrations are conveyed through the rotor to the items being blended, typically food items, wherein added motion of the particles nearby takes place so that the food is more readily blended.

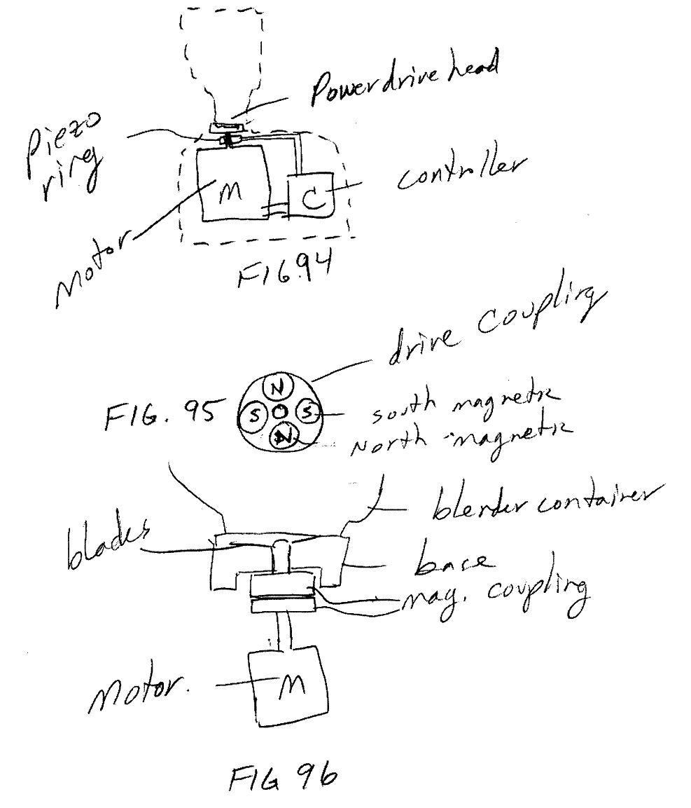

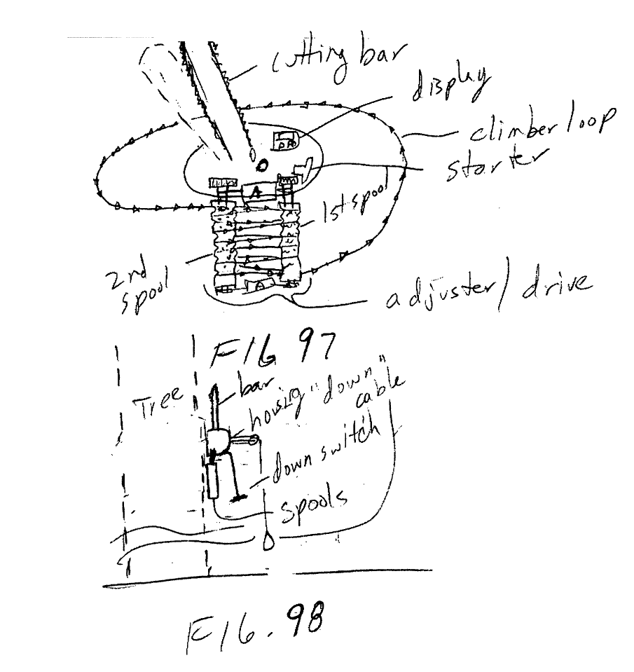

FIG. 91 depicts the blender container with a base within which the present invention is incorporated. Transducers are actually integrated on the blade unit itself, such as on the exterior, or preferably the blade is manufactured with a cavity into which the piezo electric material may be inserted and sealed. Contacts for the piezo electric material are shown through a generally conventional looking coupler in FIG. 92 having four extended arms. The arms being a first contact and a center rod (insulated from a cylindrical surrounding) being the second contact. FIG. 93 depicts the blades with the piezo material being coupled to the blade or the interior of the blades. The signals for driving the piezo electric material being received from a controller or electronic oscillator circuit within the blender.

Another method of implementing the invention is shown in FIG. 94 wherein a piezoelectric transducer is coupled to the shaft of the motor, the motor being preferably at least somewhat compliantly mounted. The vibrations from the piezo electric transducer being coupled up to the blade wherein the blade vibrates with the additional piezo electric energy.

It should be appreciated that the present invention may be implemented on blenders, food processors, and mixers (both portable and free standing), to increase the mixing that occurs within the container or bowl being blended or mixed.

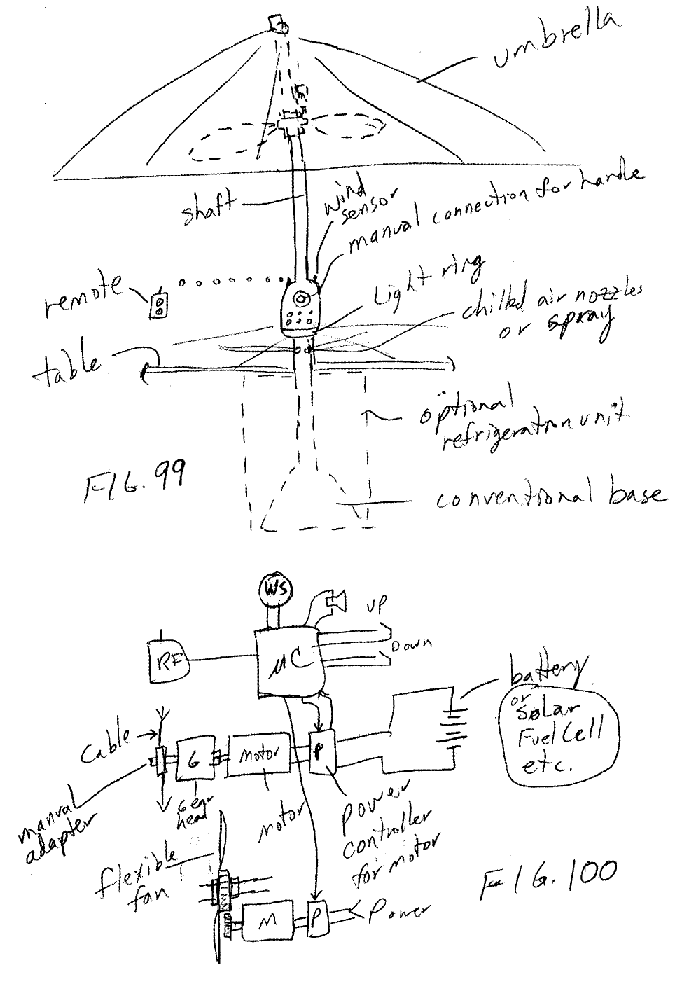

FIG. 95 and FIG. 96 depict an alternative coupling for a blender (conventional or as described herein). It will be appreciated that if a hard material is placed in the blender when it is operating, then the force of the motor may cause the blender container to be broken. In an attempt to reduce this risk, the coupling of the blender is often configured with a rubber piece to provide limited compliance and which may disengage if the blender strikes a hard object.

An aspect of the invention provide a magnetic coupler/clutch between the blender motor housing and the blender container. Strong magnets such as rare-earth magnets can provide plenty of coupling force between the motor and blades witin the container. When an object is struck the magnetic which couples the smooth magnetic plates to one another is overcome and the blade unit temporarily disengages, soon to reengage to allow normal use.

This form of magnetic clutch can be made with a smooth easy to clean exterior that is also aesthetically pleasing.

47. StaLock System

To prevent doors from being left unlocked. A two stage door lock that prevents maintenance personnel from leaving doors unlocked. Provides better security & reduces liability of the owner of a building, because it would reduce the possibility that the maintenance people left a door unlocked. The door is unlocked by two different sets of similar keys. A normal set is for the owners (leasees, or tenants) and allows the door to be fully unlocked. A second set of keys only allows the lock to be rotated so far under spring pressure so that the lock opens but springs back into a locked mode.

This is done by providing an extra pin which allows the key to turn all the way to the latching unlocked state only when this extra pin is properly met by the key.

48. No Clear Tree Cutting Device

To reduce the propensity to clear cut stands of trees. It will be appreciated that it is often difficult to fell a single tree in a forest as the branches will interfere with surrounding trees. However, it is too costly and dangerous to climb the tree and remove the offending branches. The present invention provides a device which scales the tree and removes the limbs on the way up the tree, then is scales back down the tree to ground level, and shuts off.

Lumberjacks can use a series of these devices to denude the limbs from trees to be cut, wherein they return at a later time to remove the device from the tree and and cut down the tree conventionally. It will be appreciated that this system is easier than removing the branches once the tree is felled.

The system is preferably configured with a laser output directed beneath the unit to warn anyone from passing undereath, preferably the laser output is nutated or otherwise oscillated to cover a given area and to attract more attention. Audio warnings at ground level may be generated by an alerting device which can optionally received status information from the cutting unit.

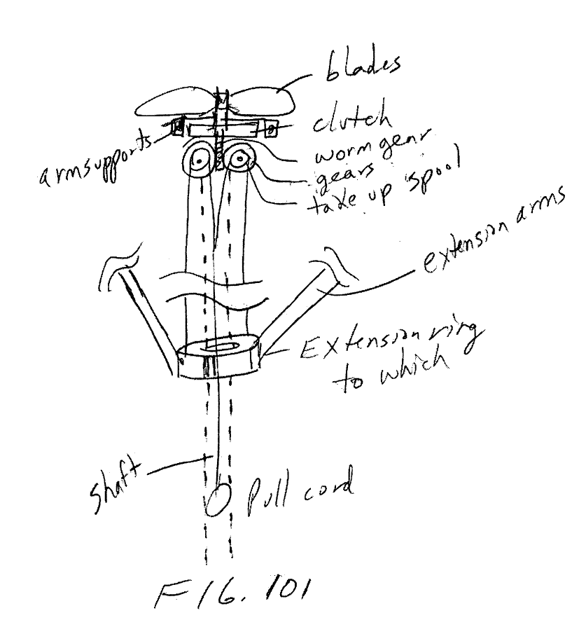

An embodiment of the device is shown in FIG. 97. The device is powered by a conventional chainsaw power plant and has a preferably articulated cutting bar, that is spring loaded towards an up position. The spool is driven forward until the cutting bar is pressed back towards a second position, at which time the drive is disengaged, to allow the unit time to cut the limb. The cutting bar is behind the unit while cutting wherein the branch can (at least generally) fall without striking the unit. As the branch is cut through the cutting bar returns to a substantially vertical position which reengages the traction drive to again scale the tree. Since the rollers automatically adjust for tensioning it will be appreciated that the unit can scale over the nub ends of the cut, left over by the cutter head. The cutting bar must be aligned close to the exterior of the tree, to eliminate the need to perform extra “nub” cutting afterward, and to allow the unit to more easily scale the tree. As the unit scales the tree the cutting bar removes any limbs positioned above and behind the unit as it circles around the tree trunk. Although the body of the unit is shown above the climbing spools for ease of representation it should be appreciated that the motor unit may be on the exterior, on the side, or even under the spools, while the bar must be maintained over and perhaps slightly behind the spools at a given distance from the face of the tree. It will be appreciated that the minimum length of the cutting bar is determined by not only the diameter of the limbs to be cut but by the distance the unit scales the tree with each pass. Therefore, a limb out of reach on pass N of the cutting bar, should not be in the way of the cable and climber system on pass N+1, in this way the limb cutting always occurs before the unit reaches the height of the limb.

The mechanism for scaling the tree utilizes a strong loop of cable preferably having regularly spaced “grabbers” along its length to enhance the retention forces of the cable against the tree. The ends of the cable are secured using a fastener, wherein the unit can be easily connected around the base of a tree and engaged. To accommodate trees of different sizes the size of loop extended around the tree is controlled by a set of tensioner/drive spools. These have slots for engaging the cable, and are preferably themselves configured with structures which extend between the cable tracks for grabbing the surface of the tree. When activated the unit slow tensions the cable by driving the two spools apart, such as mechanically driven by the motor through a gearing system that is clutched according to tension, wherein as the tree changes size the drive will automatically adjust to the proper size. Alternatively a mechanical biasing force, such as a spring, may be used to separate the spools to a given tension. A mechanism, however, should be provided to allow the user to close the spools for more easily removing the device from a tree, this may be a lever or other tool that allows latching the biasing device in a closed position.

It will be noted that as the cable is picked up at the right the unit moves counterclockwise and scales up the tree, with the cable preventing the unit from falling. When the limbs have been cut to a sufficient height, the unit scales back down to ground level. Determining the height at which to stop cutting may be determined in a number of ways, for example by tree diameter, or height from the ground. For example, the unit may be set for a given circumference, which is measured according to the spread that exists between the rollers. This may be predefined based on safety, for example, as the rollers reach their full extension, then the cutting it complete and the unit scales back down the tree. Unless a sensor is incorporated to sense the presence of the tree surface above the cable, the unit should not be used on trees whose tops abruptly stop while the tree still is at a large diameter.

The height may also be detected to determine how high to remove limbs, this is preferably used in combination with the minimum diameter limit for the sake of safety. The height may be determined by counting the number of spool rotations.

An emergency shut down and retrieval mechanism is shown in FIG. 98, wherein a cable hangs from the device which may be pulled upon once to cause the unit to begin scaling back down the tree. Pulling the cord additional times will cause the spools setting to be loosened, (in case the unit somehow gets stuck going over one spot). A hard tug on the cord preferably shuts down the engine. Also shown in FIG. 98 is a down switch which senses that the unit has returned to ground level, wherein it shuts down automatically after releasing cable tension.

The unit is preferably configured to automatically scale back down the tree if it encounters a problems, such as a portions of the tree that cannot be scaled, low fuel levels, erratic engine operation, a limb that can't be cut through in a given period of time, extending climbing time with no limbs encountered (probably slipping and staying on one place), cable frayage detected (optical sensing, a switch element through which cable passes that conforms to and senses grabbers but detects loose strands of cable they are known to be part of cable as a conductive pathway to cable exists) and other conditions that may warrant unit retrieval.

The device utilizes a microcontroller for regulating the climbing and cutting, while registering safety conditions and performing programmed control of the cutting operation, such as the detection of tree diameter, or distance climbed.

Additional Aspects:

+One or more auxilliary rotational power receptacles in the bottom of the unit that may be engaged with an extended pole having a powered rotating head with a mating plug. One receptacle may be provided for directly driving the spools toward a down position (remember all branches are out of the way so not to tough to walk around with pole in unit). If the unit senses that it is not descending properly, or senses an obstruction, then the cable tension is loosened during descent. Likewise if slippage is sensed, then the cable tension is automatically increased. An additional receptacle may be provided to provide power for an engine restart. It should be appreciated that typical professional chainsaw engines when well maintained are very reliable, wherein the need to retrieve a device in this manner should occur very infrequently. If the drive unit is inoperable then the unit may need to be retrieved by supporting the device on a rod and cutting the cable, or scaling the tree to above the unit, fastening a line to it, removing the cable from the unit (via connector) or cutting, and lowering the unit to the ground.

49. Remote and/or Wind Retracted Deck Umbrellas

To control umbrellas remotely so the user does not need to crank the unit up and down. In addition the unit is configured to preferably sense wind speed wherein the umbrella may be automatically closed. The deck umbrella provides a number of optional features to enhance the outdoor experience.

The basic remote unit provides for the raising and lowering of the unit using a remote control or a set of switches located on the unit. A power drive is connected to the umbrella which may utilized any convenient mechanism for controlling deployment, such as threaded shafts, chains, gearing, pulleys.

The power unit may be driven from batteries, a low-voltage power connection (i.e. used for outdoor lighting), a high voltage connection (i.e. 110VAC), fuel cells are the preferable power source as cost makes them cost effective because power consumption high but time between uses may be long wherein batteries can lose their power, a small solar panel is preferably provided if the power unit to be powered a rechargable battery so as to retain charge while idle. Solar power may now be generated from polymeric material, such that the exterior of the umbrella material may be overlayed with photoresponsive material to generate charging power for a battery or capacitor. Low power connections and solar can be used to charge battery in this low-duty cycle application.

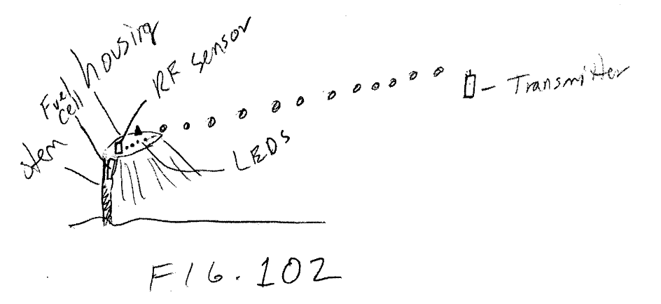

FIG. 99 shows the basic unit with a controller unit mounted above the table which has a number of manual controls. The user can raise and lower the umbrella by pressing the buttons on the unit, or on the optional remote. A remote may be desired in that raising and lowering the umbrella takes a few minutes wherein the person may want to engage it from within the house or building prior to retreating to the shade of an open umbrella.

The unit can also preferably sense excessive wind speed when the umbrella is in an up position, wherein the electronics engage, the unit preferably generates an audio warning and then the umbrella is automatically retracted to a down position to reduce harm to the umbrella or the electronics of the unit. A wind sensor is shown on the umbrella which can provide automatic closing of the umbrella upon detecting a sufficient wind speed over a period of time. A small semiconductor wind sensor is shown which uses twin heated elements, one exposed to the wind and one covered for detecting relative wind. If power use is at a premium, then a windmill style propeller may be utilized with a generator to sense relative wind and to provide the power to trigger the activation of the controller circuit.

In addition, a rain sensor is preferably provided on the control unit wherein the umbrella can retract to cover the housing if rain is being detected. A manual connection is shown to which a handle, or power tool, may be attached for driving the unit up and down should the motor fail, or the energy source be depleted.

The unit shown may have a number of options such as a flexible fan formed from sections of compliant foam. The foam prevents any injury and does not require hinges as it simple folds down as the umbrella folds down. A plastic “spine” may be attached within the foam section so that they are restored to a correct position upon raising the umbrella. Additionally, the unit is shown generating light for the table, these being preferably LED style lamps to conserve power (if operating from batteries, fuel cell, etc.).

Furthermore, getting exotic, an undertable refrigeration unit, which should be wired to power, or powered by a fuel cell. The refrigeration is a convenient amenity and it provides additional features for the unit, such as blowing cooling air on demand, wherein an air driven pump pressurizes the refrigeration unit through a first opening and cool air is extracted from a second opening which blow out of cooling ports within the shaft, or cooling stalks extending therefrom so that they may be directed by the user at the desired location, such as face or chest. Cooling liquids may be similarly sprayed from a reservoir of liquid within the refrigeration unit which is kept very cold, along with any desired beverages.

FIG. 100 shows a controller circuit block diagram with a microcontroller coupled to an RF receiver unit. The uC is connected to a power controller for a motor, such as a FET circuit, which regulates the power from the battery to the motor, including direction and optionally speed. The motor is coupled to a gearbox which drives the selected form of mechanism, shown as a cable style mechanism driven by a pulley with an auxilliary manual handle connection (which may also preferably be coupled to the output of a power tool having a head head output). The windspeed sensor is shown connected to the controller, as well as an audio output for generating warnings that the umbrella is being lowered. The flexible fan is also shown assembled about the shaft and driven by a motor.

Features:

Electric Remote Control

Operates manually if electrics fail

Senses wind and auto retracts (after warning)

Solar conversion (cells), or a windmill/generator on top to recharge batteries

Electric fan built in, but not restricting lowering of fan

Refrigerator base—can get a cold one

blows chilled air up through post and out umbrella

Lighted base—such as through glass

also a protruding center (into which umbrella is inserted) that has circumferential lighting such as LEDs.

A mechanically lowered umbrella:

A conventional umbrella may be configured for automatic lowering should the wind speed become excessive, thereby preventing damage to the umbrella a equipment nearby.

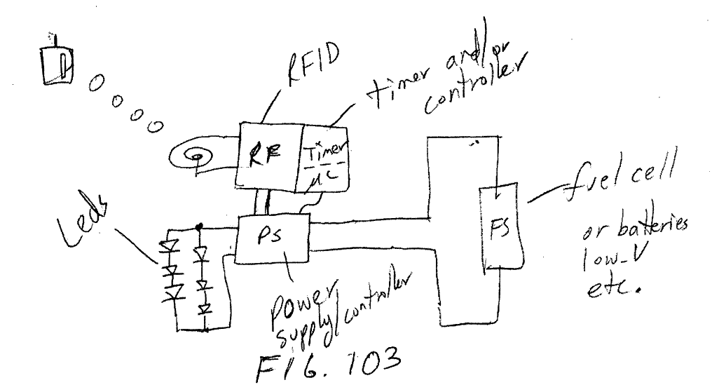

FIG. 101 depicts an embodiment of such an umbrella that provides a latching pullcord style of mechanism for extending the arms of the umbrella, which is similar to the way that venetian blinds are retracted and extended, and utilizes at least two cords. The wind controlled unit has a windmill or other element that is adapted for spinning in response to a sufficient wind. The windmill herein is shown driving a mechanical clutch that only engages the output shaft upon reaching a first threshold, at which time the power from the windmill is applied to a worm gear at the clutch output which drives at least two gears connected to spools for lowering the extension ring and thus the extension arms connected to the umbrella support arms connected to the fabric of the umbrella. It will be appreciated that once the clutch is engaged it remains engaged until the umbrella has been fully lowered, otherwise when the clutch engages, the added load of the gearing will slow the clutch input speed and cause it to immediately disengage, so it should either engage and remain engaged until the end of travel or be provided with sufficient hysterisis between clutch on and off, wherein the load will not trigger the clutch inactive until a low threshold speed is reached.

50. RFID Controlled Lighting

It is often desirable to control the use of lighting so that it will activate only when users are present. This can offer energy savings in any environment. In particular this is important when little power reserves are available or when the lighting is rarely utilized. One particular example of this is the use of outdoor lighting, which only need be activated in response to the presence of a user.

A passive RFID transponder tag is incorporated within lighting elements to control the activation of the lights in response to user presence within a given distance, as sensed by an RF, or inductive signaling unit retained by the user. The RFID unit may be powered or self powered and in response to a proper ID being detected it generates a signal to activate switches that control light state, such sa routing power across a conventional lighting switch to the light element. Further, the device preferably, allows a code to be detected from the unit which determines how long the light should remain activated. Generally, the lights would only remain on for a short period when the user is absent, such as five minutes, as determined by a timing circuit within the RFID. However the control unit may be set for any desired period of time, such as 30 minutes, 1 Hr., 2 Hrs, and so forth.

Although the present invention may be utilized with any form of lighting such as in houses or elsewhere it is particularly suited for use with outdoor lighting, in particular outdoor lighting that may not have power wired to it. The present invention will describe outdoor lighting that incorporates the control mechanisms described, however, it is to be appreciated that the mechanism may be utilized separately with other forms of lighting controls.

FIG. 102 depicts an outdoor light configured with the present system, wherein the proximity of a transmitter triggers the unit to light the pavement. The light is preferably powered by a fuel cell and has a compartment retaining a fuel cell that may be easily replaced when the energy is depleted.

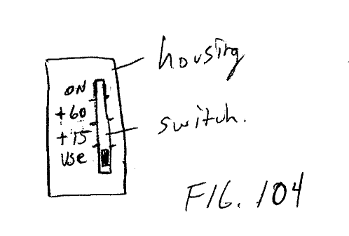

FIG. 103 depicts a schematic, wherein the inductive power or RF power which is picked up by the loop is converted to a signal which activates the power supply of the device which can also supply power for the timing circuit, or a controller (more sophisticated lighting control functions, such as intensity control and so forth). The power supply then supplies power to the lighting elements here shown as a grouping of white LEDs. The timer can deactivate the power supply after the alloted amount of time has elapsed. The RF detector section, or the microcontroller preferably contains a circuit for matching ID codes and function codes, wherein the unit can register more sophisticated commands such as controlling the intensity of lighting and so forth.

FIG. 104 shows a controller unit that the user may keep in their pocket as they walk around their house. The controller unit generates signals to control any nearby lighting and retain it in the ON state for the selected time period {Use=temporary (i.e. 5 minutes), 15 minutes, 60 minutes, or “ON”}. The value of ON allows the lights to be kept on until the user sets the controller for a different value and walks near the units having the RFID tags.

1. In a keyboard having a plurality of keys that upon being pressed past a selection threshold generate a keystroke for entry into the current application, wherein the improvement comprises:
means of sensing intermediate key pressure which is less than that required to generate a selection; and
programming in the application for generating feedback as to which key is subject to the intermediate pressure, wherein the user can change hand positioning to find the desired key before entering a keystroke.

2. The improvement as recited in claim 1, wherein said means comprises a contact, or sensor, that generates a signal to the computer in response to detecting an intermediate level of keymotion, or pressure.

3. The improvement as recited in claim 1, wherein said feedback comprises a displaying the character with different viewing properties than an entered key.

4. The improvement as recited in claim 3, wherein if preselected key is pressed a normal keystroke is registered, gut if released, the preselection feedback disappears as well, or is replaced by the user preselecting another key by applying an intermediate level of pressure.

5. In a fan configured for personal cooling having a plularity of blades rotating at moderate speeds, the improvement comprising:
attaching a removable filter to the blades of the fan;
wherein said removable filters are configured to entrain air through the edge of the filter to trap particulates in the air.

6. The improvement as recited in claim 5, wherein the blades are in excess of 1 foot in length.

7. The improvement as recited in claim 5, wherein the fan has between 2 and 6 blades to which filters may be attached.
claims 8-20 not defined.

21. A system for accurately controlling HVAC systems, comprising:
a temperature sensor;
remote thermal contribution sensing devices;
a controller receiving input from the temperature sensor and the remote thermal contribution sensing devices;
said controller adapted with programming for,
determining a thermocline from the temperature sensor to the thermal contribution sensing unit;
adjusting the HVAC output so that the user set temperature is adjusted for the thermocline.

22. A system as recited in claim 21, wherein the remote thermal contribution sensing devices comprise radiation detection units, such as pyroelectric detectors, that detect infrared radiation which determines the amount of heat contribution from a given area.

23. A system as recited in claim 21, wherein the remote thermal contribution sensing devices comprise remote temperature sensors that generate temperature signals.

24. A system as recited in claim 23, wherein the remote sensors communicate via RF with said controller.

25. A counting apparatus for registering multiple categories of items in response to a touch direction applied thereto, comprising:
a force responsive tip element adapted for sensing the direction of force applied thereto;
a counter operably coupled to said force responsive tip element adapted for sequential counting of each touch of said tip element in a predetermined number of directions; and
an annunciator for announcing the sequential counts according to each of said predetermined number of directions.

26. A apparatus for registering the height of an individual and annunciating that height, comprising:
a compliant strip of material;
means for sensing position along said strip of material;
means for annunciating a height value;
computer processor operative coupled to said means for sensing ans said means of annunciating height and configured with programming for,
registering the location along said strip wherein sufficient level of said contact pressure has occurred,
converting the location data to a height value,
converting the height value to a signal for said means of annunciating height,
outputting said height value to said means for annunciating.

27. A system for directing the movement of an individuals, comprising:
means for detecting the presence of a particular individual;
means for displaying direction indications along the route of said particular individual; and
a computer connected to means for detection and means for displaying and adapted with programming readable from a computer readable media for execution on said computer for,
interfacing with said individual to determine a destination,
maintaining location information about said particular individual based on said means for detecting;
determining a next direction toward said destination,
generating an indication of direction proximal to said individual toward said destination.

28. A system as recited in claim 27, wherein said means for detecting the presence of a particular individual comprises:
a network of detectors capable of detecting an individual within sufficient proximity to said detectors; and
an identification feature within said detectors adapted to uniquely register the presence of a particular individual;
wherein said detectors are connected to said computer.

29. A system as recited in claim 28, wherein said detectors comprise: imaging systems adapted for capturing images, or image streams, of said individuals;
said imaging systems being connected to said computer;
programming executable on said computer for,
recognizing a particular individual from said captured images and image streams,
determining the location of said individual from said captured images and image streams.

30. A system as recited in claim 28, wherein said detectors comprise:
radio frequency communication devices adapted for communicating with a radio frequency device associated with said individual;
wherein said radio frequency communication devices are responsive to the distance between said individual and said detector so that the locations of said individual in relation to said detectors may be generally determined.

31. A system for controlling burner intensity on a stove, or similar, cooking element, comprising:
a transducer adapted for registering the cooking state of food elements being heated within receptacles by a specific heating element;
a signal processing element operably coupled to said transducer and adapted to discern the state of said food elements in response to the quantity being registered by said transducer;
a controller operably coupled to said signal processing element for receiving information on the state of said food elements;
an input device in communication with said controller into which a user can select the desired state that said food elements are to attain or be retained at;
a power control element operably coupled to said controller and adapted for modulating the power output of said specific heating element; and
wherein said controller generates at least one signal to said power control element that is responsive to the difference between the desired state as entered by said user and said state of said food elements as registered by said transducer;
whereby the power output of said burner is modulated so as to match the user input with the state of said food elements registered by said transducer.

32. A system as recited in claim 31, wherein said transducer comprises:
an acoustical transducer as selected from the group of acoustical transducer elements consisting of audio transducers, microphones, vibration sensors, or similar vibration and audio responsive elements;
wherein said acoustical transducer is retained in a position to receive acoustical signals from said receptacles;
said acoustical transducer having a sufficiently directional input to discern the sound of foods being heated by a specific heating element; and wherein said acoustical transducer is connected to said signal processing element.

33. A system as recited in claim 32, wherein said acoustical transducer is connected to said signal processing element by a wired, or wireless communication channel.

34. A system as recited in claim 33, wherein said wireless communication channel comprises an RF transmitter configured to transmit acoustical information to said signal processing element.

35. A system as recited in claim 33, wherein said acoustical transducer is retained above said receptacle and directed so as to receive acoustical in relation to the state of said food in said receptacle.

36. A system as recited in claim 33, wherein said acoustical transducer is positioned proximal to said cooking element for registering the sounds associated with the state of the food being heated at said particular cooking element.

37. A system as recited in claim 36:
wherein a plurality of said acoustical transducers are positioned proximal to said cooking elements and produce an output signal to said signal processing element;
wherein the congruence, or difference, of the signals received by said signal processing element provides for the discernment of the state of food heating with each specific heater element.

38. A system as recited in claim 33, further comprising a module within which said acoustical transducer, an acoustical transducer, or a vibration sensor, is located that communicates a signal to said signal processing element.

39. A system as recited in claim 38, wherein said signal is communicated over a wired or wireless communication link with said signal processing element.

40. A system as recited in claim 31, wherein said transducer comprises a pressure transducer.

41. An apparatus for cleaning windows in multi-story buildings, comprising:
a drive mechanism adapted for traversing a set of tracks joined to a multistory building adjacent the windows of said building;
washer assembly attached to said drive mechanism and adapted for cleaning said windows;
means for sensing position along said tracks;
a controller operable connected to said means for sensing position, said washer assembly, and said drive mechanism, wherein said controller is adapted with programming for,
determining the position of said drive mechanism along said track from input received from said means for sensing position along said track,
activating said drive mechanism until said washer assembly is positioned in relation to a window, or a portion thereof, to be washed next,
activating said washer assembly to wash all or a portion of a given window,
determining which window or portion is to be washed next, repeating the above steps for all windows to be washed;
at least one power source configured to power the drive mechanism, washer assembly, means for sensing, and said controller.

42. An apparatus as recited in claim 41, wherein said drive mechanism is adapted for engaging said tracks on opposing sides, vertically or horizontally, of windows on said building.

43. An apparatus as recited in claim 42, wherein said drive mechanism is adapted so that said engagement is a slidable engagement wherein one or more roller wheels is retained within a track section.

44. An apparatus as recited in claim 43, wherein roller wheels are retained on opposing sides of a track section.

45. An apparatus as recited in claim 44, wherein at least one roller wheel per track is mechanically locked into said track and unable to disengage except at predetermined locations.

46. An apparatus as recited in claim 41, wherein said tracks are primarily oriented horizontally along the side of the building with at least one vertical path for traversing between horizontal sections.

47. An apparatus as recited in claim 41, wherein said tracks are primarily oriented vertically along the side of the building with at least one horizontal path for traversing between vertical sections.

48. An apparatus as recited in claim 41, wherein both vertical and horizontal tracks are deployed.

49. An apparatus as recited in claim 41, wherein said power source comprises a battery source.

50. An apparatus as recited in claim 49, wherein said battery source is automatically connected to a battery charging device when at one or more charge positions along said track.

51. An apparatus as recited in claim 41, wherein said power source is derived from a power connection on said multistory building.

52. An apparatus as recited in claim 51, wherein said power connection is integrated within said tracks.

53. An apparatus as recited in claim 41, wherein washer assembly comprises:
a spray head adapted to dispense liquid cleaning solutions;
a wiper head adapted to wipe away the liquid and associated dirt from the window; and
a motorized positioner for moving said wiper head and optionally said spray head.

54. An apparatus as recited in claim 41, further comprising:
data storage associated with said controller and programming for,
retaining a map of said track on said building,
retaining a programmed cleaning path,
following said map of said track to execute said programmed cleaning path.
